(19) United States
(12) Patent Application Publication
(10) Pub. No.: US 2013/0279254 A1
(43) Pub. Date: Oct. 24, 2013

(54) SEMICONDUCTOR MEMORY STORAGE APPARATUS HAVING CHARGE STORAGE LAYER AND CONTROL GATE

(71) Applicant: KABUSHIKI KAISHA TOSHIBA, Tokyo (JP)

(72) Inventors: Yoshihiko KAMATA, Yokohama-shi (JP); Koji TABATA, Yokohama-shi (JP); Mitsuhiro KOGA, Miura-gun (JP); Tomoyuki HAMANO, Yokohama-shi (JP); Yuko YOKOTA, Kamakura-shi (JP)

(21) Appl. No.: 13/839,219

(22) Filed: Mar. 15, 2013

(30) Foreign Application Priority Data
Apr. 23, 2012 (JP) 2012-097807

(51) Int. Cl. G11C 29/04

(52) U.S. Cl. CPC G11C 29/04
USPC 365/185.09

(57) ABSTRACT

According to one embodiment, a semiconductor memory storage apparatus includes an array, a sense amplifier, and a controller. The array includes a memory cell. The sense amplifier includes a first latch and a second latch. The first latch and the second latch are capable of storing a data read out from the memory cell. The controller performs a first operation, a second operation, and a third operation. In the first operation, the controller transfers an inverted data in the first latch to the first node and transfers the data in the second latch. In the second operation, the controller transfers the data in the first latch to the first node and transfers an inverted data in the second latch.

### CROSS-REFERENCE TO RELATED APPLICATIONS

This application is based upon and claims the benefit of priority from Japanese Patent Application No. 2012-097807, filed Apr. 23, 2012, the entire contents of which are incorporated herein by reference.

### FIELD

Embodiments described herein relate generally to an XOR computable sense amplifier.

### BACKGROUND

There is a sense amplifier which reads out, for example, multivalued data from a memory cell. A plurality of latches includes the sense amplifier for holding the multivalued data.

The sense amplifier confirms a read error based on the read data by using a plurality of latches.

### BRIEF DESCRIPTION OF THE DRAWINGS

FIG. 1 is an example of a whole structure of a semiconductor memory storage apparatus according to a first embodiment;

FIG. 2 is a circuit diagram of a memory cell array according to the first embodiment, and a block diagram of a sequencer, a page buffer and a sense amplifier;

FIG. 3 is a circuit diagram of the sense amplifier according to the first embodiment;

FIG. 4 is a block diagram of the sequencer according to the first embodiment;

FIG. 5 is a flow chart showing a reading operation according to the first embodiment;

FIGS. 6A, 7A, 8A, 9A, 10A, 11A, 12A and 13A are conceptual diagrams showing an operation according to the first embodiment, and conceptual diagrams showing a reading operation of a sense unit;

FIGS. 6B, 7B, 8B, 9B, 10B, 11B, 12B and 13B are conceptual diagrams showing the operation according to the first embodiment, and conceptual diagrams showing a potential level of each of nodes within the sense unit;

FIGS. 6C, 7C, 8C, 9C, 100, 11C and 12C are conceptual diagrams showing the operation according to the first embodiment, and time charts of signals output from a controller;

FIGS. 13C and 13D are conceptual diagrams showing the operation according to the first embodiment, and time charts of the signals output from the controller;

FIGS. 14A, 14B and 14C are conceptual diagrams showing the operation according to the first embodiment, in which FIG. 14A is a conceptual diagram showing a potential level of each of the nodes within the sense unit in the case that values of SDL and XDL are set to 1 and 1, FIG. 14B is a conceptual diagram showing a potential level of each of the nodes within the sense unit in the case that the values of SDL and XDL are set to 1 and 0, and FIG. 14C is a conceptual diagram showing a potential level of each of the nodes within the sense unit in the case that the values of SDL and XDL are set to 1 and 1;

FIG. 15 is a block diagram of a sequencer according to a third embodiment;

FIGS. 16A, 17A, 18A, 19A, 20A and 21A are conceptual diagrams showing an operation according to the third embodiment, and are conceptual diagrams showing a reading operation of a sense unit;

FIGS. 16B, 17B, 18B, 19B, 20B and 21B are conceptual diagrams showing the an operation according to the third embodiment, and conceptual diagrams showing a potential level of each of nodes within the sense unit;

FIGS. 16C, 17C, 18C, 19C, 20C and 21C are conceptual diagrams showing an operation according to the third embodiment, and time charts of signals output from a controller;

FIG. 22 is a conceptual diagram simply showing sense amplifier.

FIGS. 23A, 24A, 25A, 26A, 27A and 28A are conceptual diagrams showing an operation according to a fourth embodiment, and are conceptual diagrams showing a reading operation of a sense unit;

FIGS. 23B, 24B, 25B, 26B, 27B and 28B are conceptual diagrams showing the computing operation according to the fourth embodiment, and conceptual diagrams showing a potential level of each of nodes within the sense unit;

FIGS. 23C, 24C, 25C, 26C, 27C and 28C are conceptual diagrams showing the computing operation according to the fourth embodiment, and time charts of signals output from a controller;

FIGS. 29A, 30A, 31A, 32A, 33A and 34A are conceptual diagrams showing an operation according to a fifth embodiment, and are conceptual diagrams showing a reading operation of a sense unit;

FIGS. 29B, 30B, 31B, 32B, 33B and 34B are conceptual diagrams showing the computing operation according to the fifth embodiment, and conceptual diagrams showing a potential level of each of nodes within the sense unit;

FIGS. 29C, 30C, 31C, 32C, 33C and 34C are conceptual diagrams showing the computing operation according to the fifth embodiment, and time charts of signals output from a controller;

FIGS. 35A, 36A, 37A, 38A, 39A and 40A are conceptual diagrams showing an operation according to a sixth embodiment, and are conceptual diagrams showing a reading operation of a sense unit;

FIGS. 35B, 36B, 37B, 38B, 39B and 40B are conceptual diagrams showing the computing operation according to the sixth embodiment, and conceptual diagrams showing a potential level of each of nodes within the sense unit;

FIGS. 35C, 36C1, 36C2, 37C, 38C, 39C and 40C are conceptual diagrams showing the computing operation according to the sixth embodiment, and time charts of signals output from a controller; and

FIGS. 41A and 41B are time charts showing an operation, in which FIG. 41A is the time chart according to a comparative embodiment, and FIG. 41B is the time chart according to the sixth embodiment.

### DETAILED DESCRIPTION

A description will be given below of the present embodiment with reference to the accompanying drawings. In the description, common reference numerals are attached to common reference portions over all the drawings. The drawings are pattern drawings, and it should be kept in mind that the drawings are different from reality as regards the relationship between thicknesses and plane dimensions, and ratios of thicknesses of layers. Accordingly, specific thicknesses and dimensions should be determined by taking into consideration the following description. Further, it goes without saying that different parts in the mutual dimensional relationships and ratios are included within the drawings.

In general, according to one embodiment, a semiconductor memory storage apparatus includes a memory cell array, a sense amplifier, and a controller. The memory cell array includes a memory cell. The sense amplifier includes a first latch and a second latch. The first latch and the second latch are capable of storing a data read out from the memory cell. The controller performs a first operation, a second operation, and a third operation. The controller performs the first operation and the second operation by using the data read out from the memory cell and data supplied from outside. The controller outputs a first result in the first operation. The controller outputs a second result in the second operation, thereafter performing a third operation based on a first result and a second result. In the first operation, the controller transfers an inverted data in the first latch to the first node and transfers the data in the second latch. In the second operation, the controller transfers the data in the first latch to the first node and transfers an inverted data in the second latch.

### First Embodiment

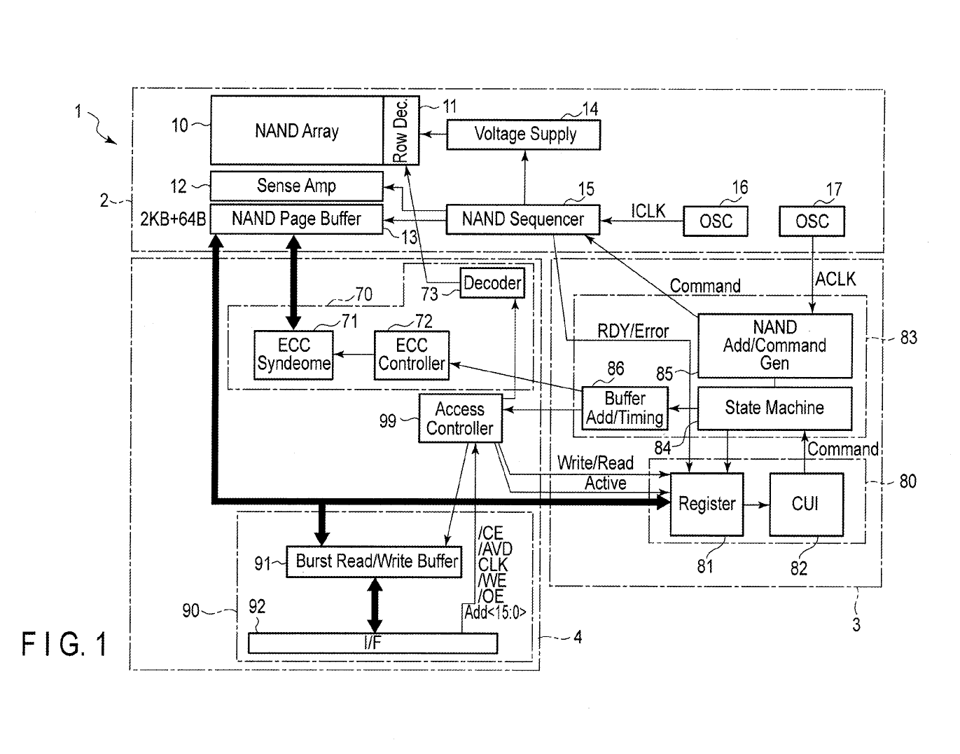

A semiconductor apparatus according to a first embodiment executes an XOR operation in relation to read data by using a detector (DTCT mentioned later) used at a verifying time in addition to SDL and XDL provided in a sense amplifier, the sense amplifier reading binarized data (“0” or “1”). Accordingly, it is possible to confirm whether or not any read error exists in the read data. In the present embodiment, the data carrying out the XOR operation with the read data, for example, the data at the other end is data held by a memory cell array mentioned later, or data transferred from a host (not shown), and the data is a known value (hereinafter, the data is called as “expected value”). A description will be given below of an example of a whole structure of a semiconductor memory storage apparatus according to the first embodiment with reference to FIG. 1.

### 1. <Example of Whole Structure>

A description will be given of an example of a whole structure of the semiconductor memory storage apparatus according to the first embodiment. The semiconductor memory storage apparatus includes a NAND flash memory, an ECC circuit, and a controller controlling them, as a specific structure example. In other words, in the following description, the structure provided with the NAND flash memory, the ECC and the controller is defined as the semiconductor memory storage apparatus.

As shown, a semiconductor memory storage apparatus 1 according to the present embodiment is provided roughly with a NAND flash memory 2, a controller 3 and an input and output portion 4. The NAND flash memory 2, the controller 3 and the input and output portion 4 are formed on the same semiconductor substrate, and are integrated as one chip. A description will be given below of details of each of the blocks.

### <NAND Flash Memory 2>

The NAND flash memory 2 serves as a main storage portion of the semiconductor memory storage apparatus 1. As shown in FIG. 1, the NAND flash memory 2 includes a memory cell array (NAND Array in FIG. 1) 10, a row decoder (Row Dec in FIG. 1) 11, a sense amplifier (Sense Amp in FIG. 1) 12, a page buffer (NAND Page Buffer in FIG. 1) 13, a voltage generator (Voltage Supply in FIG. 1) 14, a sequencer (NAND Sequencer in FIG. 1) 15, and oscillators (OSC in FIG. 1) 16 and 17.

### 1.1 <Memory Cell Array 10>

The memory cell array 10 has a function of holding data from an external portion, and outputting the held data to the external portion. Further, the memory cell array 10 according to the present embodiment holds the expected value as mentioned above.

A detailed structure of the memory cell array 10 will be mentioned later.

### 1.2 <Row Decoder 11>

The row decoder 11 selects a word line and a select gate line at a time of programming, reading and deleting the data. The row decoder 11 applies a necessary voltage (voltage VPGM, voltage VPAA, voltage Vcgr, voltage Vread and voltage Vera) to the word line and the select gate line.

### 1.3 <Sense Amplifier 12>

The sense amplifier 12 carries out an XOR operation by using the expected value with regard to the data obtained by detecting and amplifying current flowing in a bit line BL, and thereafter transfers it to the page buffer 13. Further, the sense amplifier 12 writes the write data transferred from the page buffer 13 in a memory cell MC via the bit line BL. In other words, the sense amplifier 12 according to the present embodiment carries out the XOR operation with regard to the read data, and determines whether or not the read data is erroneously read. The reading operation and the writing operation by the sense amplifier 12 are carried out entirely with regard to all the bit lines BL. A detailed structure of the sense amplifier 12 will be mentioned later.

### 1.4 <Page Buffer 13>

The page buffer 13 may hold page size data, temporarily holds data given from the input and output portion 4 at the program operating time of the data, and transfers the data to the sense amplifier 12. On the other hand, the page buffer 13 temporarily holds the data which is read by the sense amplifier 12 and is transferred, at the reading operation time, carries out a correcting process by the ECC circuit, and thereafter transfers the corrected data to the input and output portion 4.

### 1.5 <Voltage Generator 14>

The voltage generator 14 generates voltages (voltage VPGM, voltage VPASS, voltage Vcgr, voltage Vread and voltage Vera) which are necessary for programming, reading and deleting the data, by raising and lowering the voltage applied from the external portion. Next, the voltage generator 14 supplies the generated voltage, for example, to the row decoder 11. Accordingly, the voltage generated by the voltage generator 14 is applied to the word line WL via the row decoder 11.

### 1.6 <Sequencer 15>

The sequencer 15 executes a whole operation of the NAND flash memory 2. In other words, when receiving a program command (Program), a load command (Load) or a delete command (not shown) from the controller 3, the sequencer 15 executes a sequence for executing the programming, the reading and the deleting of the data in response thereto. The sequencer 15 controls the operations of the sense amplifier 12, the voltage generator 14 and the page buffer 13 in accordance with the sequence. A detailed structure of the sequencer 15 will be mentioned later.

### 1.7 <Oscillator 16>

The oscillator 16 generates an internal clock ICLK. In other words, the oscillator 16 serves as a clock generator. The oscillator 16 supplies the generated internal clock ICLK to the sequencer 15. The sequencer 15 operates in synchrony with the internal clock ICLK.

### 1.8 <Oscillator 17>

The oscillator 17 generates an internal clock ACLK. In other words, the oscillator 17 serves as a clock generator. The oscillator 17 supplies the generated internal clock ACLK to the controller 3 and the input and output portion 4. The internal clock ACLK is a clock which is a standard for the operations of the controller 3 and the input and output portion 4.

### 1.1.1 <Details of Memory Cell Array 10>

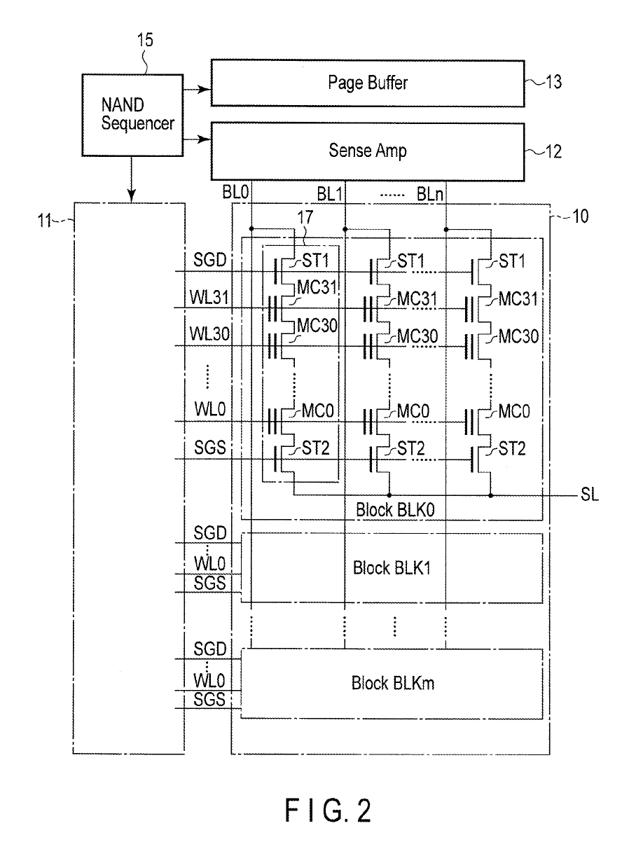

Next, a description will be given of a detailed structure of the memory cell array 10 within the NAND flash memory 2 by using FIG. 2. FIG. 2 is a circuit diagram of the memory cell array 10, and a block diagram of the row decoder 11, the sense amplifier 12 and the page buffer 13.

As shown in FIG. 2, the memory cell array 10 includes (m+1) (m being a natural number equal to or more than 2) blocks BLK0 to BLKm. Hereinafter, in the case that the blocks BLK0 to BLKm are not classified, they are simply called blocks BLK. Each of the blocks BLK includes (n+1) (n+1 being a natural number equal to or more than 2) memory cell units 17.

Each of the memory cell units 17 includes, for example, thirty two memory cells MC0 to MC31, and selection transistors ST1 and ST2. Hereinafter, in the case that the memory cells MC0 to MC31 are not classified, they are simply called memory cells MC. The memory cell MC includes a laminated gate structure having a charge storage layer (for example, a floating gate) which is formed on the semiconductor substrate via a gate insulation film, and a control gate which is formed on the charge storage layer via a gate insulation film. The number of the memory cells MC is not limited to 32, but may be set to 8, 16, 64, 128 or 256, and the number is not limited. Further, the memory cells MC may be constructed as a MONOS (Metal Oxide Nitride Oxide Silicon) structure which uses an insulation film such as a nitride film as a charge storage layer, and employs a method of trapping electrons in the nitride film.

The memory cells MC have sources and drains in common between the adjacent ones. The memory cells MC are arranged between the selection transistors ST1 and ST2 so that current paths are connected in series. The drain in one end side of the series connected memory cell MC is connected to the source of the selection transistor ST1, and the source in the other end side is connected to the drain of the selection transistor ST2.

The control gates of the memory cells MC in the same line are connected in common to any one of the word lines WL0 to WL31. Further, the gates of the selector transistors ST1 and ST2 in the same line are connected in common to the select gate lines SGD and SGS. For simplifying the description, the word lines WL0 to WL31 may be hereinafter called simply the word line WL.

Further, the drain of the selection transistor ST1 is connected to any of the bit lines BL0 to BLn. The bit lines BL0 to BLn connect a plurality of memory cell units 17 in common between a plurality of blocks BLK. The bit lines BL0 to BLn are called simply the bit line BL in the case that they are not classified.

The source of the selection transistor ST2 is connected to the source line SL. The source line SL is used in common within the memory cell array 10.

In the structure mentioned above, the data is entirely written in or read out of a plurality of memory cells MC which are connected to the same word line WL, and the unit is called a page. Further, the deletion of the data is carried out in block BLK units. In other words, the data of the memory cells included in the same block is entirely deleted.

Each of the memory cells MC may hold 1 bit data (any one of “0” data and “1” data), for example, in correspondence to a change of threshold voltage of the transistor according to the quantity of the electrons charged in the charge storage layer. Data of 2 bits or more may be held in each of the memory cells MC by segmentalizing the control of the threshold voltage. For example, when the charge is stored in the charge storage layer, the memory cell MC holds the “0” data, and when the charge escapes and is set to the deleted state, the memory cell MC holds the “1” data.

Further, in each of the blocks BLK, the partial memory cell units 17 are used for holding the information (parity) for correcting errors, and the remaining memory cell units 17 are used for holding the user data.

Further, any block ELK (for example, the block BLKm in the present embodiment) is used for holding the system information of the NAND flash memory 2. An example of the system information is bad block information, bad column information and the expected value mentioned above. The bad block information is the information of the block BLK which is made unusable due to some bad, for example, a block address. Hereinafter, the block BLKm may be called a ROM fuse block.

Further, the bad column information is the information of the column which is made unusable, for example, a column address. Further, in the case of the bad column, a value of a signal GOOD mentioned later is set to the “L” level.

Further, the expected value is the data for inspecting whether or not any read error exists in the read data, which has, for example, “0” or “1” data. The expected value is the known data for carrying out the XOR operation with the read data. Further, the expected value is constituted, for example, a value expecting the value read out of the memory cell MC.

The expected value is read by the sense amplifier 12, for example, collectively for one page at the reading time, and is stored in XDL mentioned later.

### 1.1.2 <Details of Structure of Sense Amplifier 12>

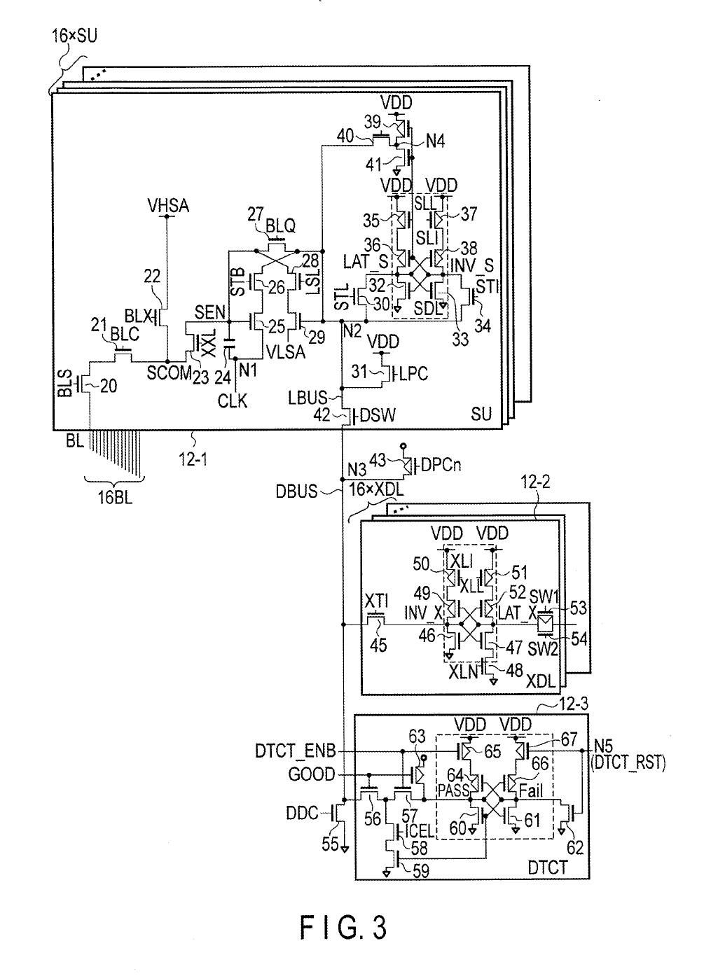

Next, a description will be given of The structure of the sense amplifier 12 with reference to FIG. 3. As shown in FIG. 3, the sense amplifier 12 is provided, for example, sixteen sense units 12-1 ₁ to 12-1 ₁₆ (SA in FIG. 3), sixteen latch units 12-2 ₁ to 12-2 ₁₆ (XDL in FIG. 3), and a detector 12-3 (DTCT in FIG. 3). In other words, the sense amplifier 12 includes one detector 12-3 in relation to sixteen sense units 12-1 ₁ to 12-1 ₁₆. In the case that the sense units 12-1 ₁ to 12-1 ₁₆ are not classified, they are simply called the sense unit 12-1, and in the case that the latch units 12-2 ₁ to 12-2 ₁₆ are not classified, they are simply called the latch unit 12-2. A structure of the sense unit 12-1 will be described.

### 1.1.2.1 <Sense Unit 12-1>

The sense unit 12-1 includes n-channel type MOS transistors 20 to 23, 25 to 34 and 40 to 42, a capacitor element 24 and p-channel type MOS transistors 35 to 39. In the following description, a threshold potential of the MOS transistor is expressed by attaching a reference numeral of the MOS transistor to a threshold potential Vth of the MOS transistor. For example, the threshold potential of the MOS transistor 21 is set to Vth21.

One end of a current path of the MOS transistor 20 is connected to the bit line BL, and a signal BLS controlled by the sequencer 15 is supplied to the gate. The signal BLS is set to the “H” level at a time of the reading operation and the writing operation, and is a signal which may connect the bit line BL and the sense unit 12-1.

In the same manner as the signal BLS supplied to the gate of the MOS transistor 20, a signal supplied to the gate of each of the MOS transistors which construct the sense unit 12-1 and are described below is controlled by the sequencer 15.

One end of a current path of the MOS transistor 21 is connected to the other end of the current path of the MOS transistor 21, the other end thereof is connected to SCOM, and a signal BLC is supplied to the gate. The signal BLC is a signal for clamping the bit line BL to a predetermined potential. If a signal BLC=(Vblc+Vth21) is given to the MOS transistor 21, the potential of the bit line BL comes to voltage Vblc.

One end of a current path of the MOS transistor 22 is connected to SCOM, voltage VHSA (=voltage VDD) is supplied to the other end, and a signal BLX (for example, voltage (Vblc+CELLSRC+Vth22+BLC2BLX) is supplied to the gate. Accordingly, the potential of SCOM is set to voltage (Vblc+BLC2BLX) at a time of reading “1” data in the present embodiment.

The voltage BLC2BLX is a guard band voltage for securely transferring the voltage VHSA to SCOM, and is a voltage for raising a current drive force of the MOS transistor 23 above that of the MOS transistor 22. For example, in the case of signal BLX<signal BLC, the voltage supplied to the bit line BL is rate controlled to the signal BLX. In order to prevent this, the voltage of the signal BLX is set to a voltage which is higher than the voltage BLC.

One end of a current path of the MOS transistor 23 is connected to the node SCOM, the other end is connected to SEN (a detector), and a signal XXL (Vblc+Vth23+BLC2BLX+BLX2XXL) is supplied to the gate. A voltage which is voltage BLX2XXL larger than the MOS transistor 22 is supplied to the gate of the MOS transistor 23. The voltage BLX2XXL means a guard band voltage for transferring the charge stored in SEN to SCOM.

Here, a voltage relationship signal BLC<signal BLX<signal XXL is established among the signal BLC, the signal BLX and the signal XXL. In other words, the current driving force of the MOS transistor 23 is larger than that of the MOS transistor 22. This is because the potential of the node SEN is circulated in the bit line BL by priority by making the current circulated by the MOS transistor 22 larger than the current circulated by the MOS transistor 23, at a time of sensing “1” data.

A description will now be given of a structure thereof. A clock CLK (=voltage (Vblc+BLC2BLX)) having a node N1 is supplied to one electrode of the capacitor element 24, and the other electrode is connected to a node SEN. The clock CLK has a function for boosting a potential of the node SEN. One end of a current path of the MOS transistor 25 is connected to a node N1, and a signal SEN is supplied to the gate. In other words, the MOS transistor 25 is turned on and off in correspondence with the potential of the node SEN. One end of a current path of the MOS transistor 26 is connected to the other end of the MOS transistor 25, the other end of the current path is connected to a node N2, and a signal STB is supplied to the gate. One end of a current path of the MOS transistor 27 is connected to the node SEN, the other end of the current path is connected to the node N2, and a signal BLQ (=voltage (VDD+Vth27+Vα) is supplied to the gate. The voltage Vα means a voltage (guard band voltage) which is added for securely transferring the voltage VDD transferred from a MOS transistor 31 mentioned later to the node SEN. Relevant to voltage Vα in a signal LPC described below, the voltage Vα serves as a guard band.

One end of a current path of the MOS transistor 28 is connected to the node SEN, and a signal LSL is supplied to the gate. Further, one end of a current path of the MOS transistor 29 is connected to the other end of the current path of the MOS transistor 28, the other end of the current path is grounded (voltage VLSA), and the gate is connected to the node N2. The MOS transistors 28 and 29 are transistors for XOR operation mentioned later.

One end of a current path of the MOS transistor 30 is connected to the node N2, the other end is connected to a node LAT_S, and a signal STL is supplied to the gate.

The voltage VDD is supplied to one end of a current path of the MOS transistor 31, the other end is connected to the node N2, and a signal LPC (=voltage (VDD+Vth31+Vα)) is supplied to the gate. In other words, if the signal LPC is set to the “H” level, the voltage VDD is transferred to SEN by the MOS transistor 31 via the node N2, and the MOS transistor 27. A wiring to which the node N2 is connected is called LBUS.

Further, in the XOR computing operation mentioned later, the wiring LBUS is set to the “H” level by setting the signal LPC to the “H” level at the data transfer time.

One end of a current path of the MOS transistor 32 is connected to a node LAT_S, the other end of the current path is grounded, and the gate is connected to a node INV_S. One end of a current path of the MOS transistor 33 is connected to a node INV_S, the other end of the current path is grounded, and the gate is connected to the node LAT_S. One end of a current path of the MOS transistor 34 is connected to the node INV_S, the other end of the current path is connected to the node N2, and a signal STI is supplied to the gate. The voltage VDD is supplied to one end of a current path of the MOS transistor 35, and a signal SLL is supplied to the gate. One end of a current path of the MOS transistor 36 is connected to the other end of the current path of the MOS transistor 35, the other end of the current path is connected to the node LAT_S, and the gate is connected to the node INV_S. The voltage VDD is supplied to one end of a current path of the MOS transistor 37, and a signal SLI is supplied to the gate. One end of a current path of the MOS transistor 38 is connected to the other end of a current path of the MOS transistor 37, the other end of the current path is connected to the node INV_S, and the gate is connected to the node LAT_S. In other words, the MOS transistors 32, 33, 36 and 38 construct the latch circuit SDL, and the latch circuit SDL holds the data of the node LAT_S.

Further, the voltage VDD is supplied to one end of a current path of the MOS transistor 39, the other end of the current path is connected to a node N4, and the node INV_S is supplied to the gate. One end of a current path of the MOS transistor 41 is connected in common to the other end of the current path of the MOS transistor 39 in the node N4, and the other end of the current path is grounded. Further, one end of a current path of the MOS transistor 40 is connected to the node N4, and the other end of the current path is connected to the node N2. The MOS transistors 39 to 41 have a function of previously charging the bit line BL to a predetermined voltage, at a time of writing the data.

Further, one end of a current path of the MOS transistor 42 is connected to the node N2, the other end of the current path is connected to DBUS (ground potential as occasion demands), and a signal DSW is supplied to the gate. The MOS transistor 42 is provided in the sense unit 12-1, and if the signal DSW is set to the “H” level, the corresponding sense unit 12-1 and latch unit 12-2 are electrically connected.

### 1.1.2.2 <Latch Unit 12-2 (XDL)>

The latch unit 12-2 holds the read data which is read out of the sense unit 12-1, and the write data which is transferred to the sense amplifier 12. In other words, the latch unit 12-2 has a function of temporarily holding the data which the sense unit 12-1 reads, and temporarily holding the data which is written into the memory cell MC. In addition, the latch unit 12-2 holds the expected value which the sense unit 12-1 reads, at a time of carrying out the XOR operation. A description will be given below of a structure of the latch unit 12-2.

The latch unit 12-2 includes n-channel type MOS transistors 45 to 48 and 54, and p-channel type MOS transistors 49-53.

One end of a current path of the MOS transistor 45 is connected to a node N3, the other end thereof is connected to INV_X, and a signal XTI controlled by the sequencer 15 is supplied to the gate. In the same manner as the signal XTI supplied to the gate of the MOS transistor 45, each of signals supplied to a gate of each of the MOS transistors which construct the latch unit 12-2 and are described below is controlled by the sequencer 15.

The description will be continued below. One end of a current path of the MOS transistor 46 is connected to INV_X, the other end is grounded, and the gate is connected to LST_X. One end of a current path of the MOS transistor 49 is connected to INV_X, and the gate is connected to LAT_X. Further, one end of a current path of the MOS transistor 47 is connected to LAT_X, and the gate is connected to INV_X. Further, one end of a current path of the MOS transistor 48 is connected to the other end of the MOS transistor 47, the other end is grounded, and a signal XLN is supplied to the gate. One end of a current path of the MOS transistor 52 is connected to LAT_X, and the gate is connected to INV_X. A voltage VDD is supplied to one end of a current path of the MOS transistor 50, the other end thereof is connected to the other end of the current path of the MOS transistor 49, and a signal XLI is supplied to the gate. A voltage VDD is supplied to one end of a current path of the MOS transistor 51, the other end thereof is connected to the other end of the current path of the MOS transistor 52, and a signal XLL is supplied to the gate. In other words, the MOS transistors 46, 47, 49 and 52 construct XDL. The latch circuit XDL holds the data of the node LAT_X.

Further, one end of a current path of the MOS transistor 53 is connected to LAT_X, a switch SW1 is supplied to the gate, and the other end thereof is connected to the page buffer 13. Further, one end of a current path of the MOS transistor 54 is connected to LAT_X, a switch SW2 is supplied to the gate, and the other end thereof is connected to the page buffer 13. The switch SW1 is an inverted signal to the switch SW2; for example, in the case that the switch SW1 is at the “H” level, the switch SW2 is set to the “L” level. In other words, the MOS transistors 53 and 54 serve as a switch which inputs and outputs data in relation to the page buffer 13.

### 1.1.2.3 <Detector 12-3>

Next, a description will be given of the detector 12-3. The detector 12-3 checks up on whether or not any read error exists in the data read by the sense unit 12-1. Specifically, the detector 12-3 carries out an XOR operation with expected value about the data read out by the sense unit 12-1 ₁. As a result, the detector 12-3 determines whether or not any read error exists. Next, the result is transferred to and stored in the sense unit 12-1 ₁. Thereafter, the detector 12-3 determines whether or not any read error exists about the data read by the sense unit 12-1 ₂. Next, the result is transferred to and stored in the sense unit 12-1 ₂. Thereafter, the operation is repeated to a sense unit 12-1 ₁₆. A description will be given below of a structure of the detector.

The detector 12-3 includes n-channel type MOS transistors 55 to 62, and p-channel type MOS transistors 63 to 67.

One end of a current path of the MOS transistor 55 is connected to the node N3, the other end is grounded, and a signal DDC controlled by the sequencer 15 is supplied to the gate. In the same manner as the signal DDC supplied to the gate of the MOS transistor 55, a signal supplied to the gate of each of the MOS transistors constructing the detector 12-3 is controlled by the sequencer 15.

One end of a current path of the MOS transistor 56 is connected to the node N3, and a signal GOOD is supplied to the gate. As mentioned above, the signal GOOD is a signal indicating whether the bad column exists.

One end of a current path of the MOS transistor 57 is connected to the other end of the MOS transistor 56, and a signal DTCT_ENB is supplied to the gate. One end of a current path of the MOS transistor 58 is connected to the other end of the current path of the MOS transistor 56 and one end of the current path of the MOS transistor 57, and a signal ICEL is supplied to the gate. Further, one end of a current path of the MOS transistor 59 is connected to the other end of the current path of the MOS transistor 58, the gate is connected to the gate of the MOS transistor 60, and the other end is grounded.

One end of a current path of the MOS transistor 60 is connected PASS, the other end is grounded, and the gate is connected to FAIL. One end of a current path of the MOS transistor 64 is connected to PASS, and the gate is connected to FAIL. Further, voltage VDD is supplied to one end of a current path of the MOS transistor 65, the other end is connected to the other end of the current path of the MOS transistor 64, and a signal DTCT_ENB is supplied to the gate. One end of a current path of the MOS transistor 61 is connected to FAIL, the other end is grounded, and PASS is connected to the gate. One end of a current path of the MOS transistor 66 is connected to FAIL, and the gate is connected to PASS. Further, voltage VDD is supplied to one end of a current path of the MOS transistor 67, the other end thereof is connected to the other end of the current path of the MOS transistor 66, and the gate is connected in common to the gate of the MOS transistor 62 by a node N5. A reset signal (DTCT_RST) is supplied to the node N5 from the sequencer 15. In other words, the potential of the node N5 is set to the “H” level at a time of resetting the potential of FAIL.

Further, one end of the current path of the MOS transistor 62 is connected to FAIL and the other end is grounded. As a result of the XOR operation, if the voltage level of PASS is set to “L”, a result of detection determines FAIL (=read error).

Further, one end of a current path of a MOS transistor 43 is connected to the node N3, the voltage VDD is supplied to the other end, and a signal DPCn is supplied to the gate. The MOS transistor 43 is set to an on state each time data is transferred between SEN and the latch unit 12-2, and has a function of charging a wiring DBUS.

Further, in the present embodiment, the first latch 12-2 is arranged within the sense amplifier 12; however, the first latch 12-2 may be arranged within the page buffer 13.

### 1.9 <Sequencer 15>

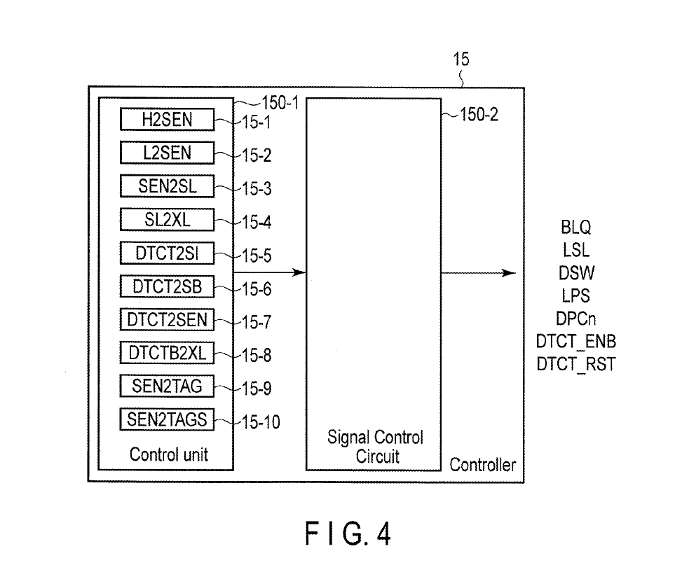

Next, a description will be given of a structure of the sequencer 15 with reference to FIG. 4. The sequencer 15 includes a control unit 150-1 and a signal control circuit 150-2. An operation of the sense amplifier 12 is controlled by the control unit 150-1 and the signal control circuit 150-2.

1.9.1 <Control unit 150-1>

The control unit 150-1 includes H2SEN15-1, L2SEN15-2, SEN2SL15-3, SL2XL15-4, DTCT2SL15-5, DTCT2SB15-6, DTCT2SEN15-7, DTCTB2XL15-8, SEN2TAG15-9 and SEN2TAGS15-10.

H2SEN15-1 sets SEN to the “H” level, that is, has a function of charging SEN. Specifically, it controls so as to set the signal LPC and the signal BLQ to the “H” level in relation to the signal control circuit 150-2.

L2SEN15-1 sets SEN to the “L” level, that is, has a function of setting SEN to the ground potential. Specifically, it controls so as to set the signal BLQ, the signal DSW and the signal DDC to the “H” level in relation to the signal control circuit 150-2.

SEN2SL15-3 has a function of transferring the voltage level of SEN to SDL. In other words, it controls so as to set each of the signal LPC, the signal BLQ and the signal INV_S to the “H” level in relation to the signal control circuit 150-2.

SL2XL15-4 has a function of transferring the value of SDL to the latch unit 12-2. In other words, it controls so as to set each of the signal STL (or the signal STI), the signal LPC, the signal DSW and the signal XTI to the “H” level and set the signal DPCn to the “L” level in relation to the signal control circuit 150-2.

DTCT2SL15-5 has a function of transferring the stored data of the detector 12-3 to SDL. In other words, it controls so as to set each of the signal DTCT_ENB, the signal GOOD, the signal DSW, the signal LPC, the signal STL and the signal SLL to the “H” level and set the signal DPCn to the “L” level in relation to the signal control circuit 150-2.

DTCT2SB15-6 has a function of transferring the stored data (the inverted data) of the detector 12-3 to SDL. In other words, it controls so as to set each of the signal SLI, the signal STI, the signal LPC, the signal DSW, the signal GOOD and the signal DTCT_ENB to the “H” level and set the signal DPCn to the “L” level in relation to the signal control circuit 150-2.

DTCT2SEN15-7 has a function of transferring the stored data of the detector 12-3 to SEN. In other words, it controls so as to set each of the signal DTCT_ENB, the signal GOOD, the signal DSW, the signal LPC and the signal BLQ to the “H” level and set the signal DPCn to the “L” level.

DTCTB2XL15-8 has a function of transferring the stored data of the detector 12-3 to the latch unit 12-2. In other words, it controls so as to set each of the signal DTCT_ENB, the signal GOOD, the signal XTI and the signal XLI to the “H” level and set the signal DPCn to the “L” level.

SEN2TAG15-9 has a function of transferring the voltage level of SEN to the detector 12-3. Specifically, it has a function of transferring the results of an OR operation mentioned below. In other words, it controls so as to set each of the signal STB, the signal LPC, the signal DSW, the signal DTCT_ENB and the signal DTCT_RST to the “H” level and set the signal DPCn to the “L” level.

SEN2TAGS15-10 has a function of transferring the voltage level of SEN to the detector 12-3. Specifically, it has a function of transferring the results of a NAND operation mentioned below. In other words, it controls so as to set each of the signal STB, the signal LPC, the signal DSW and the signal DTCT_ENB to the “H” level and set the signal DPCn to the “L” level. In the present embodiment, since an AND operation of the OR operation and the NAND operation is carried out about the read data, SEN2TAGS15-10 does not control a voltage level of the signal DTCT_RST.

### 1.9.2 <Signal Control Circuit 150-2>

The signal control circuit 150-2 outputs any of the “H” level and “L” level of the signal BLQ, the signal LSL, the signal DSW, the signal LPC, the signal DPCn, the signal DTCT_ENB and the signal DTCT_RST to the sense amplifier 12 in response to the control from the controller 150-1.

### <Controller Portion 3>

Next, turning back to FIG. 1, a description will be given of the controller 3. The controller 3 controls the operations of the NAND flash memory 2 and the input and output portion 4. In other words, the controller has a function of controlling the overall operation of the semiconductor memory storage apparatus 1. As illustrated, the controller 3 includes an internal register 80 (Internal register in FIG. 1) and a semiconductor memory storage apparatus state machine 83.

### 2.1 <Internal Register 80>

The internal register 80 includes a register 81 (Register in FIG. 1) and a command user interface (CUI in FIG. 1) 82.

### 2.1.1 <Register 81>

The register 81 is a register for setting and holding the operation state of the semiconductor memory storage apparatus 1. In other words, the register 81 sets an operation state of a function in response to a command given from an access controller 99. More specifically, the register 81 sets the operation state of the function in response to a register write command or a register read command of the register 81.

In other words, in the register 81, for example, a load command is set at the data loading time, and a program command is set at the data programming time. In this case, the register write command or the register read command means a write command or a read command (Write/Read) applied to the register 81 from the access controller 99.

Further, the load means an operation for reading the data from the NAND flash memory 2 so as to output to the output portion 4, the program means an operation in which the data from the output portion 4 is transferred to the page buffer 13 and written in the memory cell array 10 of the NAND flash memory 2, and the delete means an operation for deleting the data in the NAND flash memory 2.

Further, the register 81 may comprehend the operation state of the NAND flash memory 2 based on a ready signal and an error signal (RDY/Error in FIG. 1) which are given from the NAND sequencer 15.

### 2.1.2 <Command User Interface 82>

The command user interface 82 recognizes a fact that a function execution command is given to the semiconductor memory storage apparatus 1 based on a predetermined command being set in the register 81. Thereafter, the command user interface issues an internal command signal (Command) so as to output to a state machine 84.

### 2.2 <Semiconductor Memory Apparatus State Machine 83>

The semiconductor memory storage apparatus state machine 83 includes a state machine (state machine in FIG. 1) 64, an address/command generator (NAND Add/Command Gen in FIG. 1) 65, and an address/timing generator (Buffer Add/Timing in FIG. 1) 66.

### 2.1.2 <State Machine 84>

The state machine 84 controls a sequence operation in an internal portion of the semiconductor memory storage apparatus 1 based on the internal command signal given from the command user interface 82. The state machine 84 supports many functions; for example, load, program and delete, and the operations of the NAND flash memory 2 and the input and output portion 4 are controlled so as to execute the functions. The state machine 84 controls them while being synchronized with an internal clock ACLK generated by the oscillator 17.

### 2.1.3 <Address/Command Generator 85>

An address/command generator 85 controls the operation of the NAND flash memory 2 based on the control of the state machine 84. More specifically, the address/command generator 85 generates addresses and commands (Program/Load/Erase, Command in FIG. 1) so as to output to the NAND flash memory 2. The address/command generator 85 outputs the addresses and the commands while being synchronized with the internal clock ACLK generated by the oscillator 17.

### 2.1.4 <Address/Timing Generator 86>

An address/timing generator 86 controls the operation of the input and output portion 4 based on the control of the state machine 84. More specifically, the address/timing generator 86 issues addresses and commands which are necessary in the input and output portion 4 and outputs to the access controller 99 and an ECC controller 72.

### <Input and Output Portion 4>

Next, a description will be given of the input and output portion 4. The input and output portion 4 includes an ECC portion 70, an interface portion 90 (PAD mentioned later) and the access controller 99.

In the semiconductor memory storage apparatus 1 according to the present embodiment, the NAND flash memory 2 serves as a main storage portion. Accordingly, when the sequencer 15 receives a load command from the address/command generator 85, and reads the data to the external portion from the NAND flash memory 2, the data read out of the memory cell array 10 of the NAND flash memory 2 is first of all transferred to the interface portion 90 of the input and output portion 4 via the page buffer 12. As a result, the data is output to a host device (not shown).

On the other hand, when the sequencer 15 receives a program command from the address/command generator 85, and stores the data in the NAND flash memory 2, the data given from the host device is first of all transferred to the page buffer 12 via the interface portion 90 and is written in the memory cell array 10.

Further, an operation in which the data read out of the memory cell array 10 is transferred to the interface portion 90 is called a data “read”.

Further, an operation in which the data to be stored in the NAND flash memory 2 is transferred to the input and output portion 4 is called a data “write”. Further, an operation in which the data within the page buffer 13 is written in the memory cell array 10 is called a data “program”.

A description will be given of a structure of each of the ECC portion 70, the interface portion 90 and the access controller 99.

### 3.1 <ECC Portion 70>

The ECC portion 70 carries out an error detection and an error correction of the data, and a generation of parity (hereinafter, they may be collectively called an ECC process). In other words, the ECC portion 70 carries out the error detection and correction in relation to the data which is read out of the NAND flash memory 2, at the data loading time. On the other hand, the ECC portion 70 carries out the parity generation in relation to the data to be programmed, and stores the generated parity in the memory cell unit 17, at the data programming time. The ECC portion 70 includes an ECC analyzing portion 71, an ECC controller 72 and an ECC decoder 73.

### 3.1.1 <ECC Analyzing Portion 71>

The ECC analyzing portion 71 carries out the ECC process by using the data held in the page buffer 13. The ECC analyzing portion 71 employs, for example, 1-bit correction method using a hamming code. The ECC analyzing portion 71 generates a syndrome by using the parity held by the memory cell unit 17 at the data loading time, thereby carrying out the error detection. When an error is found, the ECC analyzing portion 71 corrects the error. On the other hand, the ECC analyzing portion generates the parity at the data programming time, and stores it in the memory cell unit 17.

### 3.1.3 <ECC Controller>

The ECC controller 72 controls the ECC analyzing portion 71.

### 3.1.2 <ECC Decoder 73>

The ECC decoder 73 specifies a position of the error in the case that the error is determined in the ECC analyzing portion 71, reads the corresponding data out of the page buffer 13 and corrects the data, at the data loading time. Further, the ECC decoder 73 transfers the parity generated by the ECC analyzing portion 71 to the page buffer 13, at the data programming time.

### <Access Controller 99>

The access controller 99 receives control signals and addresses from an interface 92. The access controller 99 controls the controller 3 and the input and output portion 4 so as to execute an operation which satisfies a request of the host device. More specifically, the access controller 99 controls the NAND flash memory 2, a burst buffer 91, the decoder 73 and the controller 3 in response to the request of the host device.

For example, the access controller 99 puts the register 81 into an active state in response to the request of the host device, and sets the command (Write/Read) to the register 81. Further, the access controller 99 instructs the page buffer 13 to read the data out of the memory cell array 10. Further, the access controller 99 transfers the address input from the external portion to the decoder 73.

### 4.1 <Interface Portion 90>

The interface portion 90 includes the burst buffer 91 and the interface (I/F) 92.

The user interface 92 may be connected to a host device (user) in an external portion of the memory system 1, and executes input and output operations of various signals such as the data, the control signal and the address Add in relation to the host device. One example of the control signal includes a chip enable signal/CE making the whole of the semiconductor memory storage apparatus 1 enabled, an address valid signal/AVD for latching the address, a clock CLK for a burst read, a write enable signal/WE making a writing operation enabled, and an output enable signal/OE making a data output to an external portion enabled.

The user interface 92 is connected to the burst buffer 91 by a data input and output bus. The data input and output bus is, for example, 2 bytes. Further, the user interface 92 transfers the control signal relating to the read request, the load request and the program request of the data from the host device to the access controller 99. Further, the user interface 92 transfers the data given from the host device to the burst buffer 91 at the data writing time.

The burst buffer 91 may transfer the data in relation to the page buffer 13 and the controller 4 based on the buffer/register data bus. A bus width of the buffer/register data bus is, for example, equal to the user data bus 7. Further, the burst buffer 91 temporarily holds the data given from the host device via the user interface 92, or the data given from the page buffer 13.

### 2. <Read Operation>

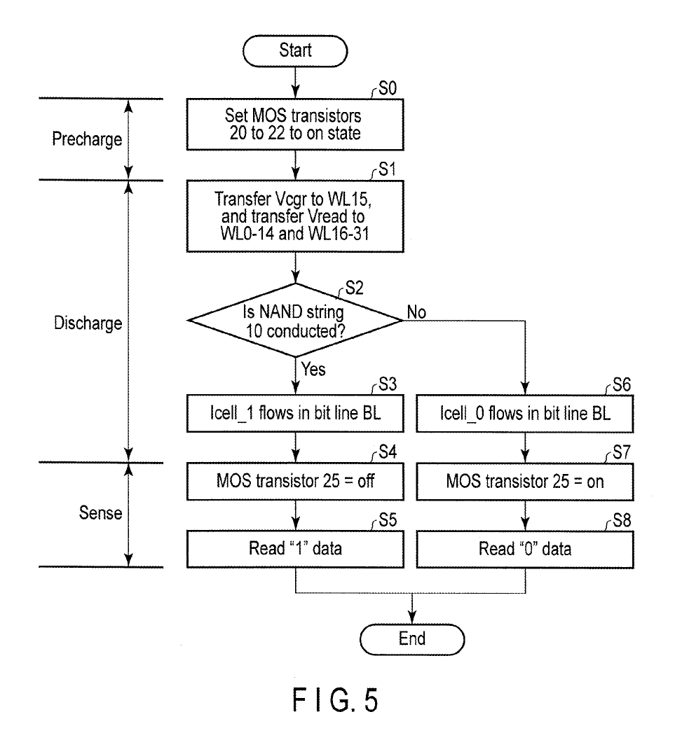

Next, a description will be given of a reading operation by the sense amplifier 12 with reference to FIGS. 1, 2, 3 and 5. FIG. 5 is a flow chart showing the reading operation of the sense amplifier 12. Here, for example, word line 15 WL is selected, and the other word lines WL are non-selected.

### 2.1 <Precharge>

First of all, the MOS transistors 20, 21 and 22 in FIG. 3 are set to an on state (S0 in FIG. 5), and a voltage VDD is supplied to the bit line BL. Accordingly, the potential of the bit line BL is charged to the voltage VDD.

### 2.2 <Discharge>

Next, a voltage Vcgr is supplied to the selected word line WL15 by the voltage generator 14 as shown in FIGS. 1 and 2, and a voltage Vread is supplied to the non-selected word lines WL0 to WL14 and WL16 to 31 (S1 in FIG. 5).

Here, if a memory cell MC connected to the selected word line WL0 comes to an on state, the memory cell unit 17 is conducted (YES in S2, FIG. 5), and a current Icell_1 flows to a source line SL from the bit line BL (S3 in FIG. 5).

On the other hand, if the memory cell MC is in an off state, the memory cell unit 17 is not conducted (NO in S2, FIG. 5). In other words, a current Icell_0 flows to the source line SL from the bit line BL (S6 in FIG. 5); however, since the current Icell_0 is small, the bit line BL maintains the voltage VDD. In the case that the currents Icell_0 and Icell_1 are not classified, they are called simply Icell.

### 2.3 <Sense>

Thereafter, a value of SEN shown in FIG. 3 changes based on the current Icell flowing in the bit line BL. In other words, since the potential of SEN is lowered based on the conduction of the memory cell unit 17 and the flow of Icell_1 through the bit line BL, the MOS transistor 25 is set to an off state (S4 in FIG. 5). Accordingly, since the MOS transistor 25 is in an off state even by setting a signal STB and a signal STL to an on state, “1” data is stored in SDL (S5 in FIG. 5).

On the contrary, since the potential of SEN maintains an initial value in the case that the memory cell unit 17 is made nonconductive and Icell_0 flows through the bit line BL (S6 in FIG. 5), the MOS transistor 25 is set to an on state (S7 in FIG. 5). As a result, since LAT_S is set to the ground potential by setting the signal STB and the signal STL to the on state, “0” data is stored in SDL (S8).

The precharge, discharge and sense operations are carried out at a time of reading the expected value. In other words, the expected value read to SEN is stored in the latch unit 12-2 via the wiring LBUS and the wiring DBUS.

### 3. <XOR Computing and Detecting Operations>

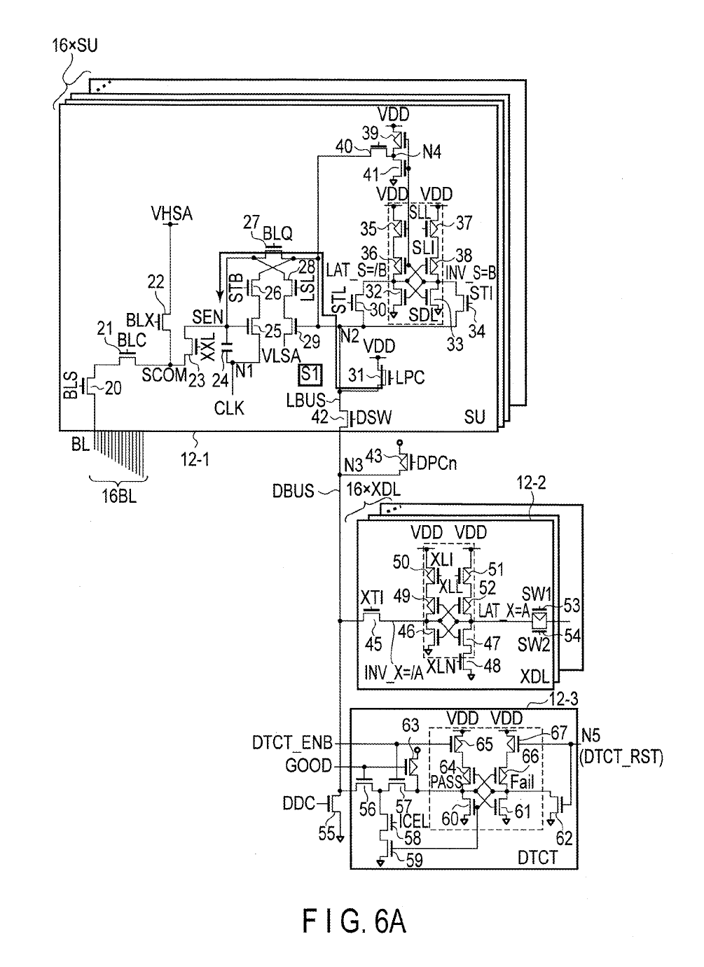

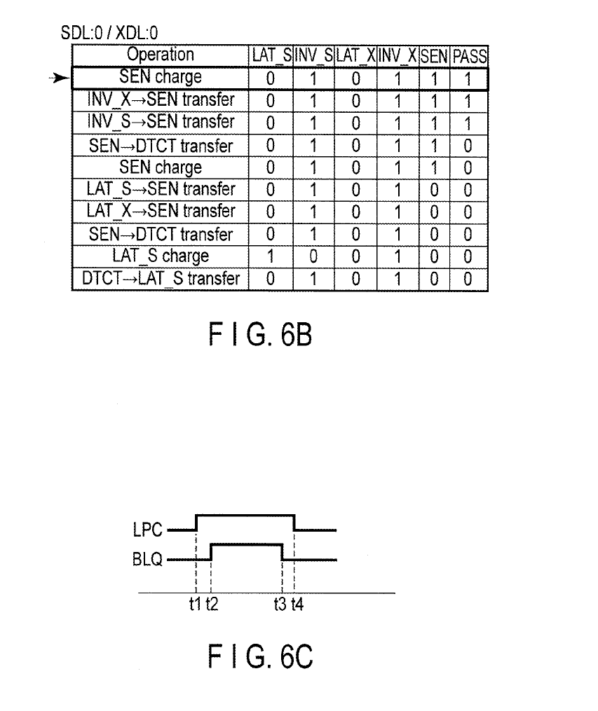

Next, a description will be given of an operation of the read data by the sense amplifier 12 with reference to FIGS. 6A to 6C to FIGS. 13A to 13C.

FIGS. 6A to 13A are conceptual diagrams of the sense unit 12-1 which carries out the XOR operation.

Here, the data held by the latch unit 12-2 is set to A and the data held by SDL is set to B.

FIGS. 6B to 13B are graphs showing the potential of each of the nodes of the sense unit 12-1, and shows a state change of each of the nodes, for example, in the case that the held data A and B of SDL and XDL are set to “0 (L level)”.

Further, FIGS. 6C to 13C are conceptual diagrams showing a potential change of a signal supplied to each of the MOS transistors constructing the sense unit 12-1 by a control unit 150-1.

Further, as mentioned above, the XOR computing operation means that the results computed by using the data held by SDL and the latch circuit 12-1 ₁ are stored in the detector 12-3, and determines whether or not any read error exists in the read data.

When the determination of the data read by the sense unit 12-1 ₁ is finished, the detector 12-3 performs detection on other sense units 12-1 ₂ to 12-1 ₁₆, one by one, in the same manner. A description will be given below of the computing and detection operations in each of the steps.

Step 1: SEN is charged as shown in FIG. 6A. Specifically, a signal LPC is set to the “H” level at time t, a signal BLQ is next set to the “H” level at time t2 and the voltage VDD is transferred to SEN as shown in FIG. 6C. Accordingly, as shown in FIG. 6B, the potential of SEN is set to the “H” level (“1”). Further, the signal DTCTRST=“H” level is set and Fail is set to the “L” level (PASS=“H” level (“1”)).

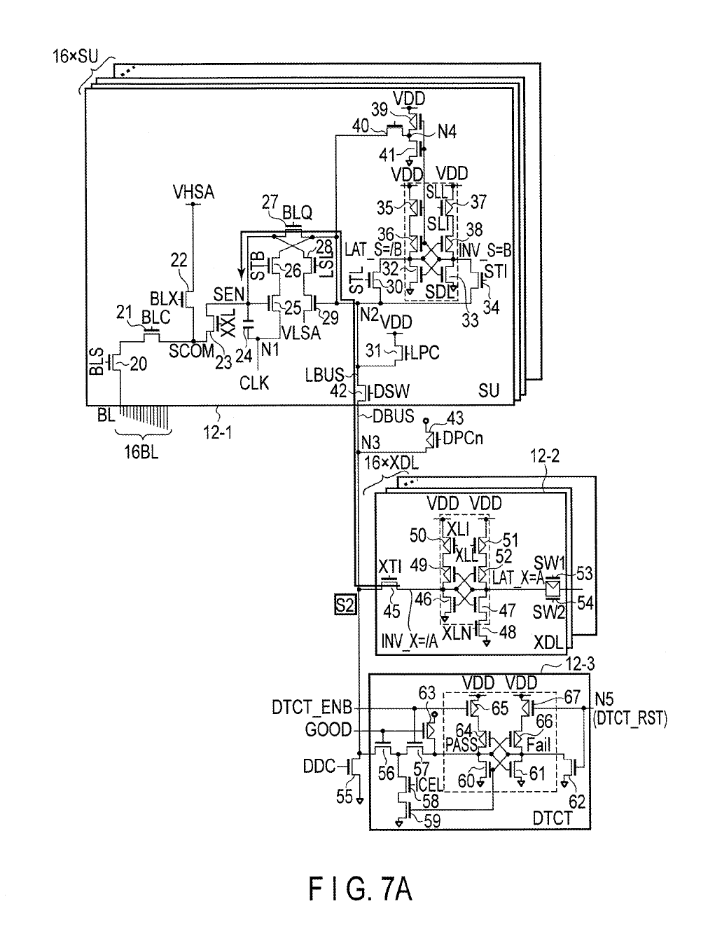

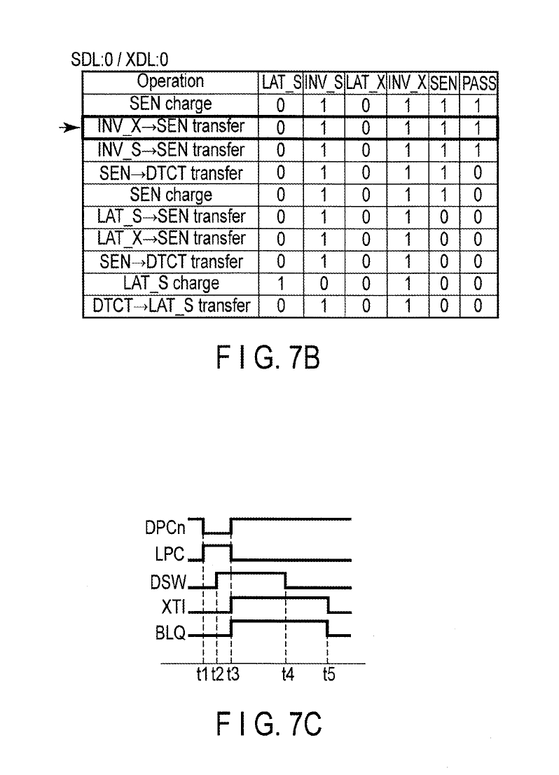

Step 2: Next, the stored data (inverted data, /A) of the latch unit 12-1 is transferred to SEN as shown in FIG. 7A. Specifically, a signal DPCn and a signal LPC are set to the “H” level at time t1, a signal DSW is set to the “H” level at time t2, respectively, and a wiring LBUS and a wiring DBUS are set to the “H” level.

Next, a value of INV_X is transferred to SEN by setting each of a signal XTI and a signal BLQ to the “H” level at time t3. Accordingly, as shown in FIG. 7B, for example, in the case of /A=“1”, the potential of SEN is set to the “H” level (“1”).

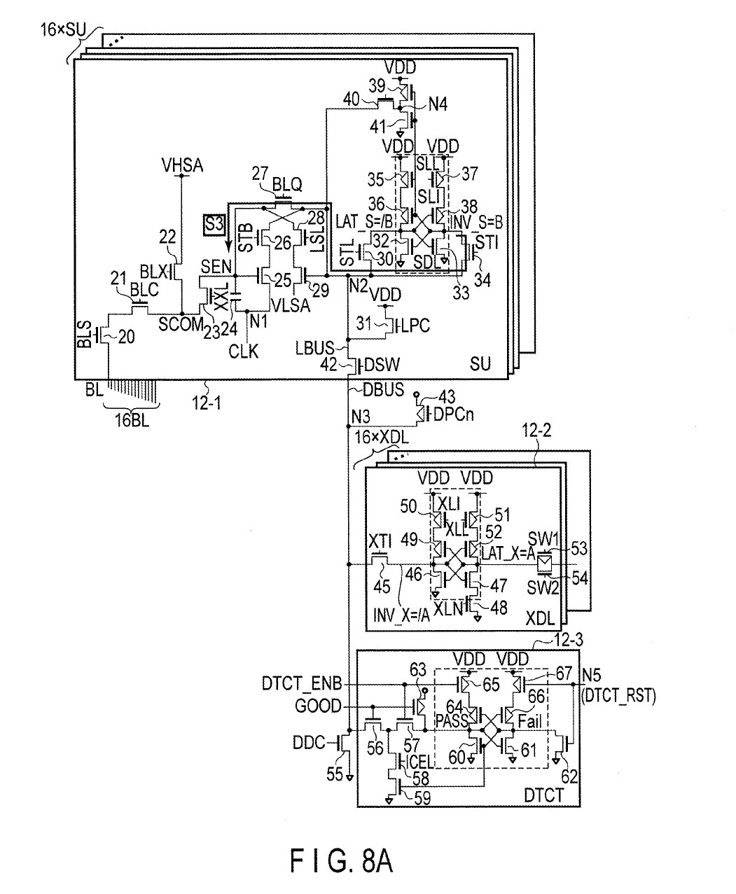

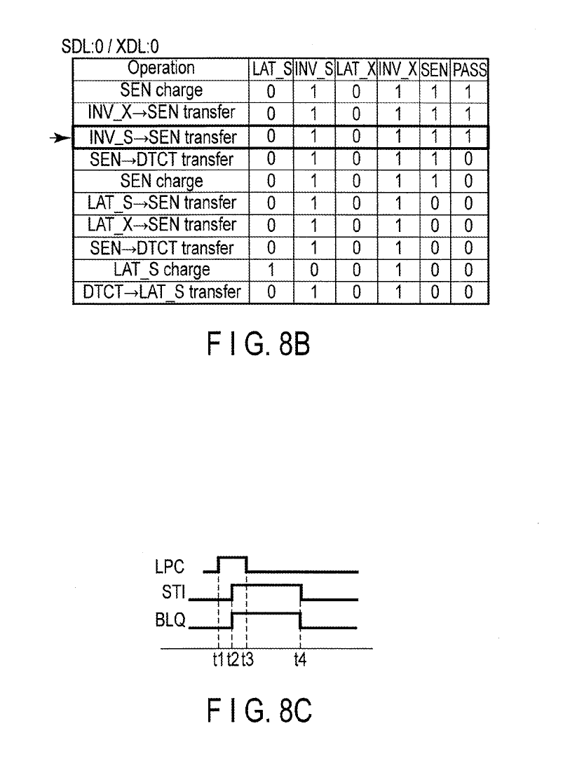

Step 3: Next, the stored data (inverted data, /B) of SDL is transferred to SEN as shown in FIG. 8A. Specifically, the wiring LBUS is charged by setting the signal LPC to the “H” level at time t1 as shown in FIG. 8C, and each of the signal STI and the signal BLQ is next set to the “H” level at time t2 and time t3. Therefore, as shown in FIG. 8B, the value of /B is transferred to SEN, for example, in the case of /B=“1”, the potential of SEN maintains the “H” level “1”.

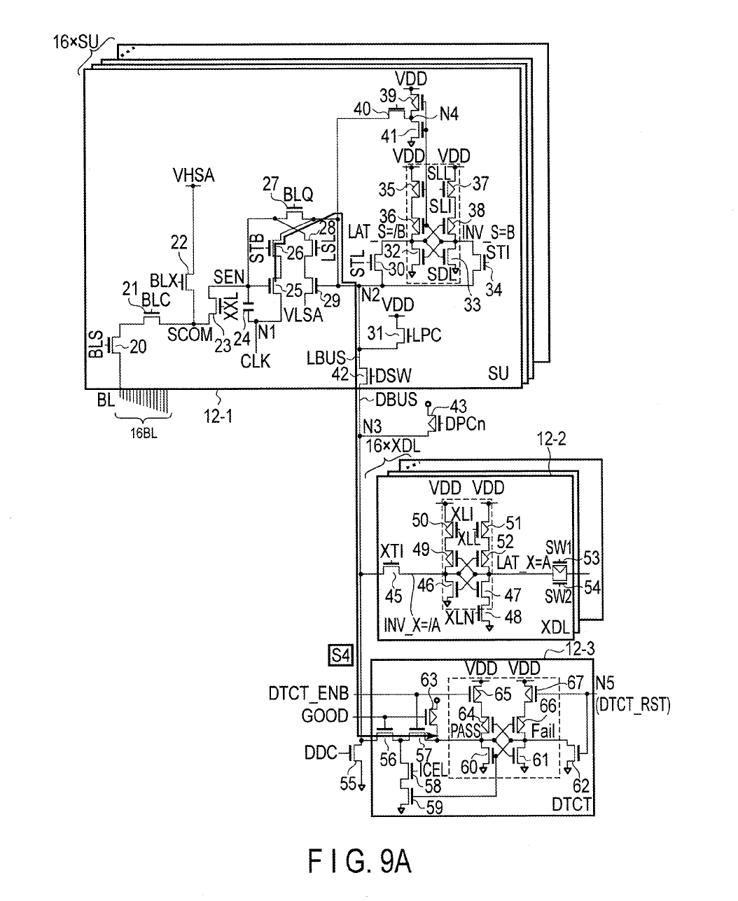

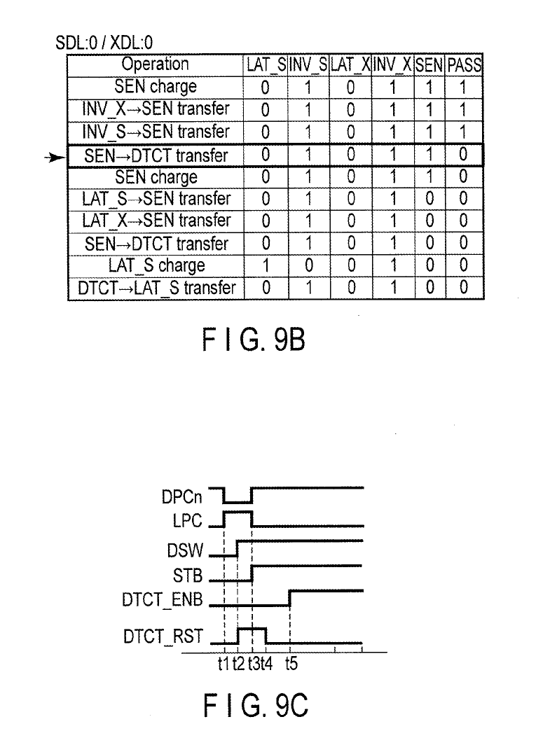

Step 4: Next, the value (inverted data) of SEN is transferred to the detector 12-3 as shown in FIG. 9A. Specifically, as shown in FIG. 9C, the wiring LBUS and the wiring DBUS are charged by setting a signal DPCn to the “L” level and setting a signal LPC to the “H” level at time t1, and next setting DSW to the “H” level at time t2. Further, FAIL is reset by setting DTCT_RST to the “H” level and setting the MOS transistor 62 to an on state. Thereafter, a value corresponding to a holding level of SEN is transferred to the detector 12-3 by setting a signal STB to the “H” level and setting time DTCT_ENB to the “H” level at time t3. The signal GOOD is normally set to the “H” level. Accordingly, as shown in FIG. 9B, PASS is set to “H”=> “L” level (“0”), for example, as long as a node of SEN is at the “H” level (“1”) (at this time, clock CLK=“L”).

The OR operation is carried out by the operations from the step 1 to the step 4. In other words, the value of SEN is set to the “H” level in the step 1, the value of SEN is thereafter set to the value corresponding to /A, and the value of /B is next transferred to SEN in the step 3. In other words, the value of SEN is set to the value obtained by the AND operation of /A and /B based on the operations up to the step 3. Further, the inverted data to the value of SEN is stored in the detector 12-3 by transferring the value corresponding to the holding level of SEN to PASS of the detector 12-3 in the step 4. In other words, this is expressed by the following expression (1).

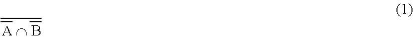

According to the De Morgan theorem, the expression (1) is equivalent to the OR operation. Further, a description after the step 5 will be further continued.

Step 5: SEN is charged. Since a charging method is the same as the step 1, a description thereof will be omitted.

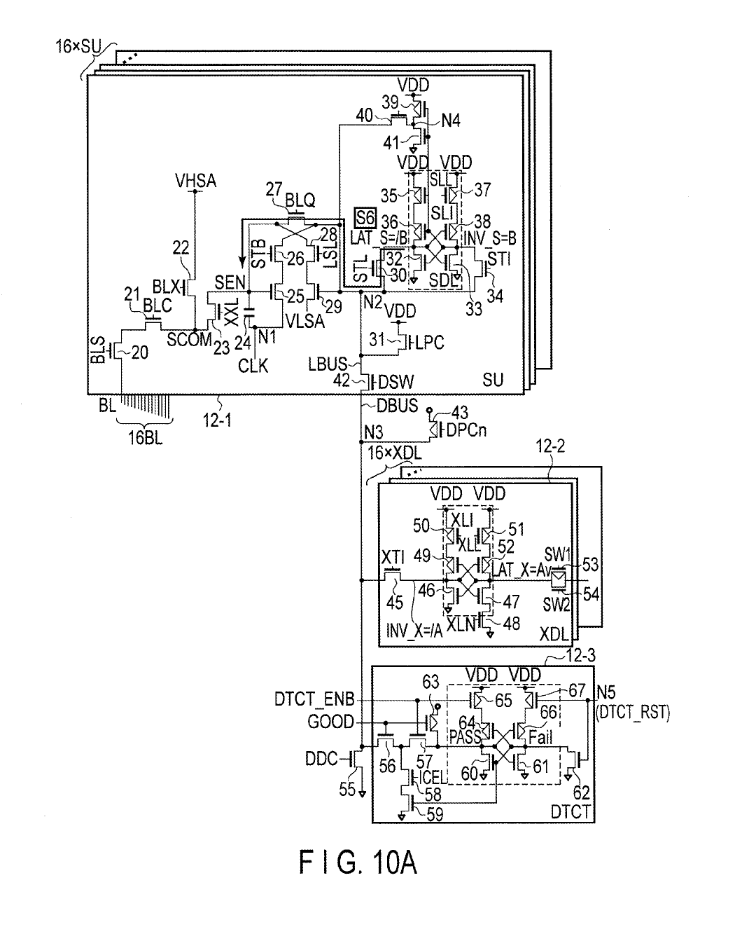

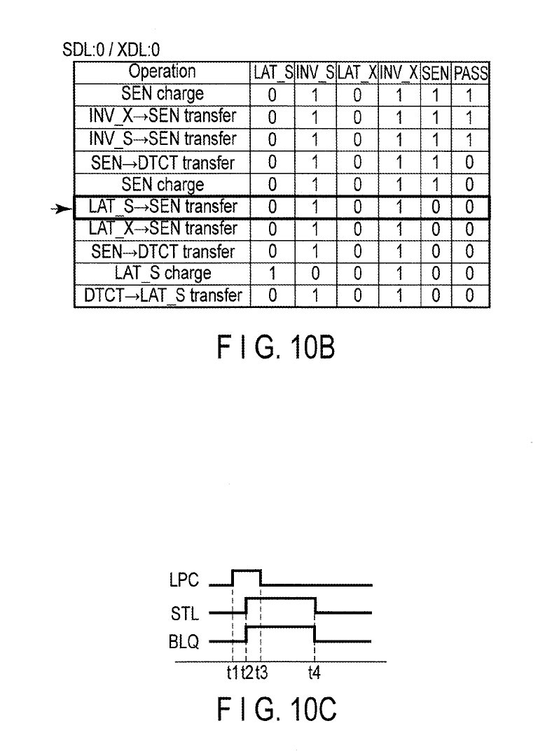

Step 6: Next, the stored data (B) of the latch unit 12-1 is transferred to SEN as shown in FIG. 10A. Specifically, after the wiring LBUS is charged by setting the signal LPC to the “H” level at time t1 as shown in FIG. 10C, and each of the signal STI and the signal BLQ is set to the “H” level at time t2. Accordingly, the value of LAT_S is transferred to SEN. Therefore, the potential of SEN is set to the “L” level (“0”), for example, in the case of B=“0” as shown in FIG. 10B.

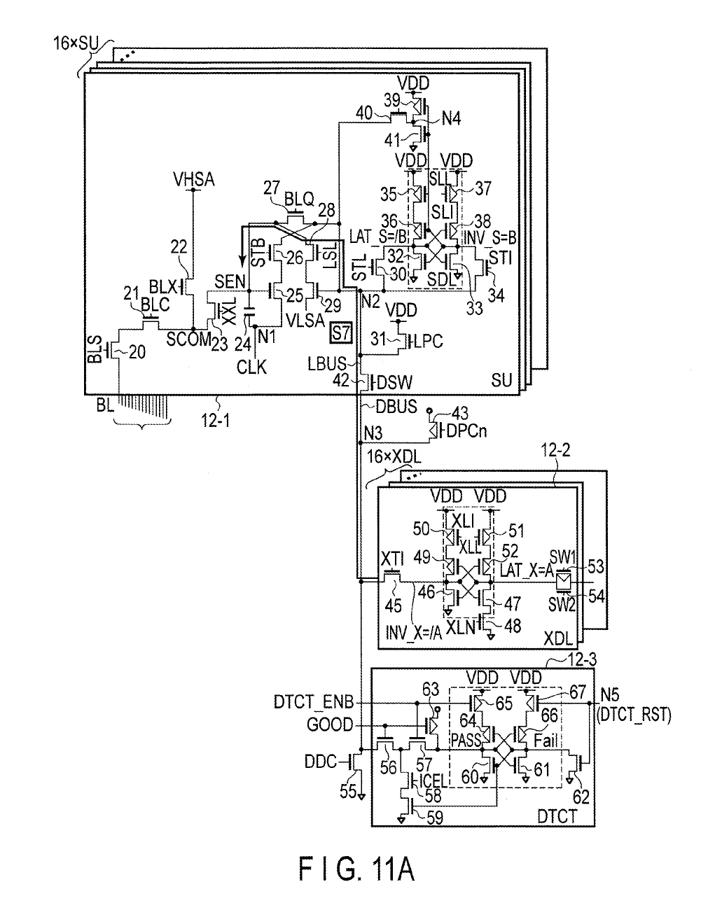

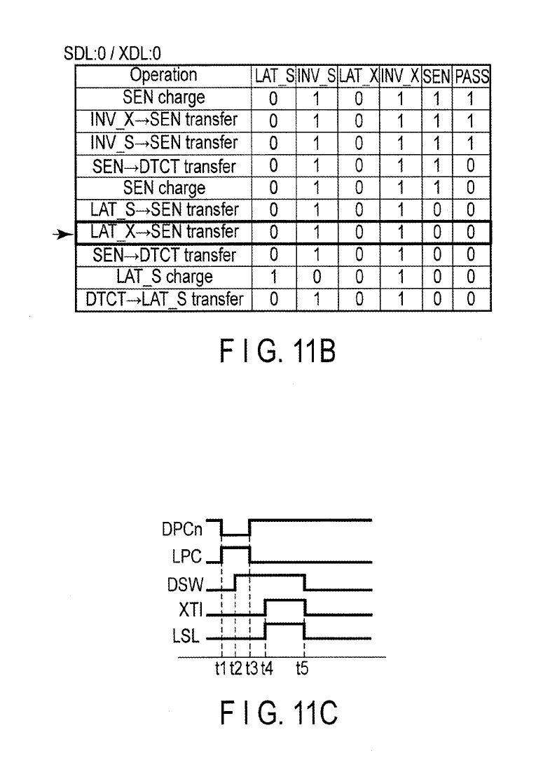

Step 7: Next, the stored data (A) of the latch unit 12-1 is transferred to SEN as shown in FIG. 11A. Specifically, each of the wiring LBUS and the wiring DBUS is charged by setting the signal DPCn to the “L” level at time t1, setting the signal LPC to the “H” level and next setting the signal DSW to the “H” level at time t2 as shown in FIG. 11C.

Thereafter, each of the signal XTI and the signal LSL to the “H” level at time t4. Accordingly, as shown in FIG. 11B, since /A is at the “H” level, for example, in the case of A=“0”, the potential of SEN is set to the ground level, that is, the “L” level (“0”).

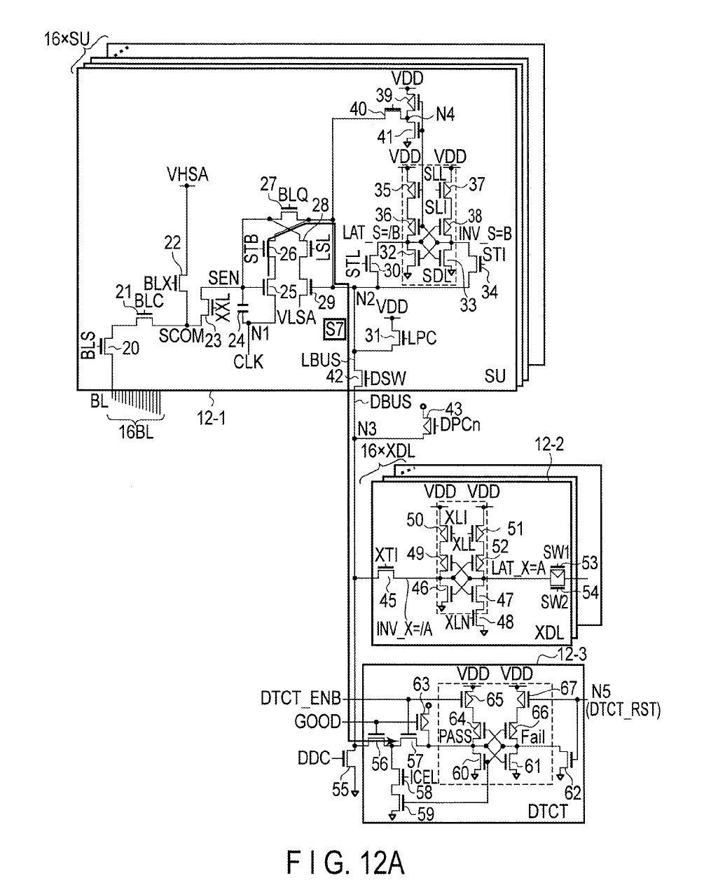

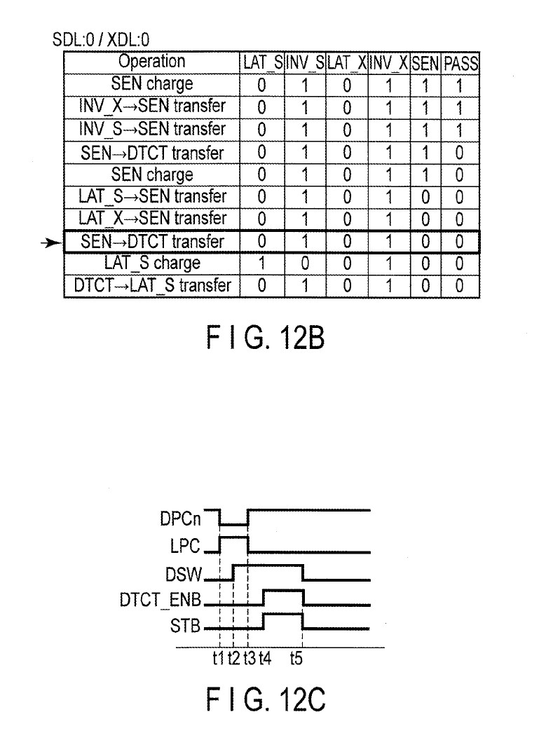

Step 8: Next, the value of SEN is transferred to the detector 12-3 as shown in FIG. 12A. Specifically, as shown in FIG. 12A, the wiring LBUS and the wiring DBUS are charged by setting the signal DPCn to the “L” level and the signal LPC to the “H” level at time t1, and next setting the signal DSW to the “H” level at time t2. Next, each of the signal STB and the signal DTCT_ENB is set to the “H” level and the value corresponding to SEN is transferred to the detector 12-3 at time t4. Accordingly, as shown in FIG. 12B, since the MOS transistor 25 maintains the off state, for example, in the case of SEN=“L” level, the value of PASS maintains the last value. In other words, PASS is set to the “L” level (“0”). This is because of the XOR operation in the case that each of A and B is “0”.

The NAND operation is carried out based on the operations from the step 5 to the step 8. In other words, the value of SEN is set to the value obtained by the AND operation of A and B based on the operations from the step 5 to the step 7. Next, in a step 8, the inverted data of SEN is stored in the detector 12-3 by transferring the value corresponding to the holding level of SEN to PASS of the detector 12-3. This is equivalent to the NAND operation of A and B. In other words, the operations from the step 5 to the step 8 are expressed by the following expression (2).

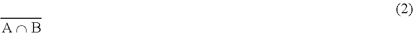

Further, as mentioned above, the value obtained by the expression (1) is stored in the detector 12-3 based on the operations from the step 1 to the step 4, and the AND operations of the expression (1) and the expression (2) are thereafter carried out by transferring the value obtained by the expression (2) to the detector 12-3. In other words, the operations are expressed by the following expression (3).

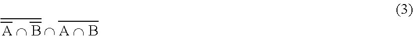

The expression (3) is equivalent to the expression expressing the XOR, that is, the following expression (4).

A⊕B (4)

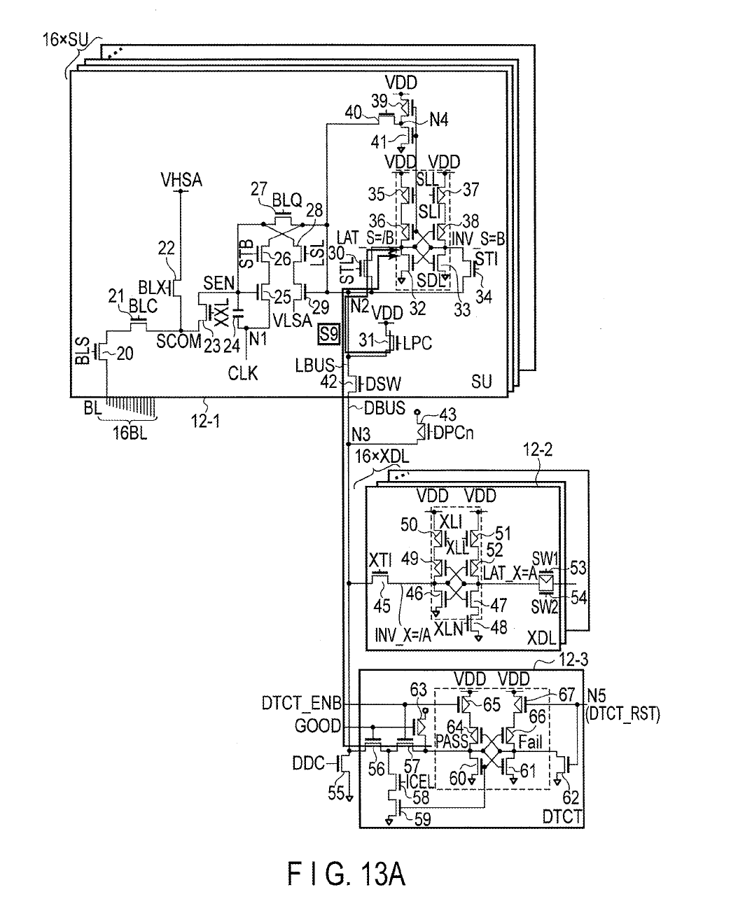

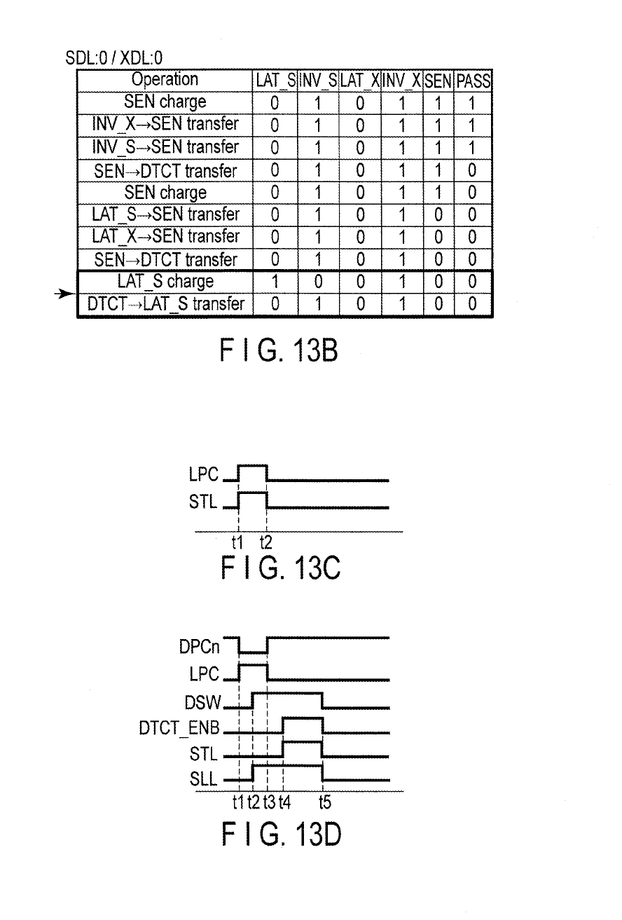

Thereafter, the value obtained by the expression (3) is transferred to SDC (steps S9 and S10). A description will be given of this state with reference to FIGS. 13A to 13C. In other words, as shown in FIGS. 13A and 13C, after LAT_S is charged by setting each of the signal LPC and the signal STL to the “H” level at time t1 (LAT_S=“H” level (“1”), refer to FIG. 13B), the wiring LBUS and the wiring DBUS are charged by the signal DPCn, the signal LPC and the signal DSW, and the held data of the detector 12-3 is stored in SDC by setting each of the signal DTCT_ENB and the signal STL to the “H” level.sd

Further, in the present embodiment, the description is given, for example, of the case that the value A is set to “0”, and the expected value is set to “0”, however, combinations of “0” and “1”, “1” and “0”, and “1” and “1” may be employed. For example, in the case that the values A and B are any of patterns “0” and “1” or “1” and “0”, the potential level of PASS is set to the “H” level (“1”), and in the case that the values A and B are “1” and “1”, the potential level of PASS is set to the “L” level (“0”). In other words, any of “0” and “1” is stored as the expected value in the latch unit 12-2, and the XOR operation is carried out with the read data. As a result, in the case that the potential level of PASS is at the “H” level, it may be determined as a read error. On the contrary, in the case that the potential level of PASS is at the “L” level, it may be determined as a correct read.

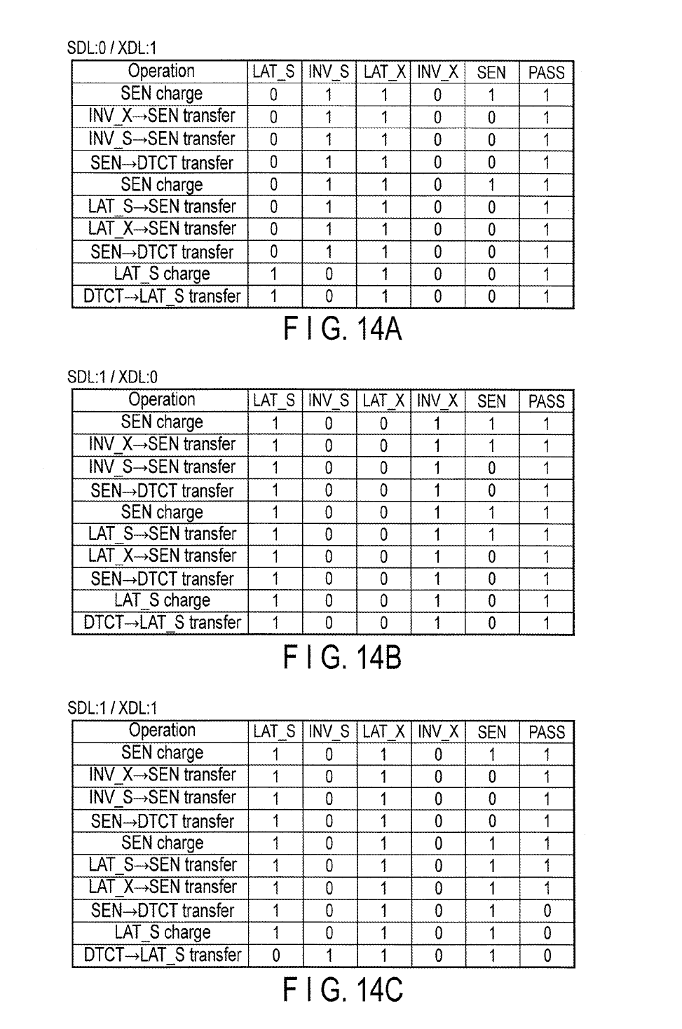

This state is shown in FIGS. 14A to 14C.

FIGS. 14A to 14C are conceptual diagrams showing a potential level of each of the nodes at a time of changing the values A and B stored in SDL and XDL.

### <Effect According to First Embodiment>

In the semiconductor memory storage apparatus according to the first embodiment, the following effects (1) and (2) may be obtained.

(1) The operation time may be shortened while maintaining a size of a circuit area.

In order to describe the effect (1), a description will be given by exemplifying a comparative example. The comparative example involves a sense amplifier (structure 1) which may read 2-bit (4-value) multivalued data. In this case, since it is necessary for the sense amplifier to hold 2-bit data, for example, four latches (SDL, XDL, UDL and UDL) are mounted in the sense amplifier. Accordingly, in the case of the sense amplifier reading 4-value data, the XOR operation could be carried out in the sense amplifier (three latch circuits are necessary at minimum for the XOR operation).

Here, if the XOR operation is intended to be executed by the sense amplifier (structure 2) corresponding to 1-bit (2-value) reading, the XOR operation could not be carried out due to the low number of latches (only two of SLD and XDL).

Therefore, for example, the stored data held by SDL and XDL was transferred to a test machine connected to an external portion, and the XOR operation was carried out by the test machine. Specifically, the read data was determined as to whether or not it constituted an error by using the data reading A, and any of the expected values (1 or 0) for the XOR operation with A for B alternately, in the expression (4). Since it is necessary to calculate by using both the expected value 1 and the expected value 0 as mentioned above, it takes more time to issue commands for the calculations (two commands for operation in the structure 2).

On the contrary, in the semiconductor memory storage apparatus according to the Present embodiment, the time for the XOR operation may be shortened in comparison with the sense amplifier corresponding to the structure 2 which is given as one example, while achieving the XOR operation without adding any latch such as UDL and LDL like the sense amplifier reading 4-value data, as mentioned above.

In other words, the present embodiment includes a structure which may operate the detector 12-3 used for verifying at the reading time. Specifically, as described in FIG. 4, the sequencer 14 includes the control unit 150-1 and the signal control circuit 150-2.

Further, the control unit 150-1 operates the detector 12-3 for holding the data at the reading time. In other words, the control unit 150-1 makes the detector 12-4 function as the latch carrying out the XOR operation at the reading time. Therefore, even in the sense amplifier 12 according to the present embodiment, the XOR operation may be achieved without increasing the number of latches.

Further, since it is not necessary to compute each of the expected values 0 and 1 in the sense amplifier 12 according to the present invention, which is different from the structure 2, only one command for instructing the XOR operation is necessary, and the time required for the XOR operation may be reduced as a whole.

In the present embodiment the XOR operation is carried out by using the expected value which is held as the system information from a certain block BLK, however, the method is not limited to this.

As a different method, there is a method of receiving the expected value from the host which is not illustrated but is mentioned above, and storing the expected value in the latch unit 12-2 via the page buffer 13. Since the remaining operations according to the XOR operation are the same as the above description, a description thereof will be omitted.

### Second Embodiment

Next, a description will be given of a semiconductor memory storage apparatus according to a second embodiment. In the first embodiment, whether or not the read error exists is determined in relation to the data which is read by using SDL, XDL and the detector 12-3. On the contrary, in the semiconductor memory storage apparatus according to the second embodiment, an ECC correction is carried out in relation to the data which is erroneously read, by using SDL and XDL.

### 1. ECC Controller 71

An ECC controller 71 according to the present embodiment writes flag “1” in XDL within the corresponding sense amplifier 12, if any read error exists in a certain bit line. Specifically, for example, in the case that the data read by a sense unit 12-1 ₅ has any error among the sense units 12-1 ₁ to 12-1 ₁₆, the ECC controller 71 generates flag “1”, and writes the flag in XDL within the sense unit 12-1 ₅ via the page buffer 13.

### 2. Correcting Operation

Next, a description will be given of a correcting operation by using the XOR operation. Hereinafter, the correcting operation is controlled by the sequencer 15. As mentioned above, in the case that the value XDL is “1” in relation to the read data, the value obtained as a result of the XOR operation is inverted. In the correcting operation described below, this characteristic is used.

### 2.1 <SDL=1>

For example, there is considered a case that the data stored in SDL is “1” as a result of the erroneous read. In this case, the data is corrected to “0” by the correcting operation.

Specifically, as mentioned above, the operations from the step 1 to the step 8 are carried out in relation to the “1” data of XDL transferred from the ECC controller 71 and the stored data (“1”) of SDL.

Then, according to the expression (3), the read data is inverted, and the value stored in the detector 12-3 is set to “0”. Next, the data is transferred to SDC. On the basis of the above correcting operation, the data erroneously read as “1” is corrected to “0” data.

### 2.2 <SDL=0>

For example, there is considered a case that the data stored in SDL is “0” as a result of the erroneous read. In this case, the data is corrected to “1” by the correcting operation.

Specifically, as mentioned above, the operations from the step 1 to the step 8 are carried out in relation to the “1” data of XDL transferred from the ECC controller 71 and the stored data (“0”) of SDL.

Then, according to the expression (3), the read data is inverted, and the value stored in the detector 12-3 is set to “1”. Next, the data is transferred to SDC. On the basis of the above correcting operation, the data erroneously read as “0” is corrected to “1” data.

As is known from the expression (3), “0” data is not stored in XDL in the correcting operation. Because the data is not inverted even by carrying out the XOR operation by using “0” data, the correcting process may not be carried out.

In the above correcting operation, the description is given by exemplifying the sense unit 12-1 ₁ to the sense unit 12-1 ₁₆ which are connected to sixteen bit lines BL; however, an actual correcting process is carried out by 1 page unit.

### <Effect According to Second Embodiment>

In the semiconductor memory storage apparatus according to the present embodiment, the following effect (3) may be obtained in addition to the effects (1) and (2) mentioned above.

(3) The data for 1 page may be entirely corrected.

In other words, the structure according to the present embodiment includes a structure which carries out the XOR operation within the sense amplifier 12. Therefore, the ECC correcting process may be executed by using the XOR operation.

Since the data after the ECC correction is stored in SDL within each of the sense amplifiers 12, the bit line after the correcting process may be read entirely for 1 page, at a time of reading in the page buffer 13.

The sense amplifiers 12 of the first and second semiconductor memory storage apparatuses are include the structure for simultaneously reading to all the bit lines BL (current sense type); however, the sense amplifiers 12 may be realized even by a sense amplifier 12 (voltage sense type) structured such that the adjacent bit lines BL are set to a pair and the reading operation is carried out in relation to any one bit line BL. Specifically, the voltage sense type sense amplifier 12 may be structured such that XDL and SDL may alternately transfer data.

### Third Embodiment

Next, a description will be given of a semiconductor memory storage apparatus according to a third embodiment. The present embodiment is different from the first and second embodiments in a point that a number of steps until acquiring results of XOR operation is reduced.

As a specific method for reducing the number of the steps until finishing the XOR operation, the processes of the steps S6, S7 and S9 in the first and second embodiments are omitted, and the XOR operation is executed between SEN and SDL.

At this time, data of SDL is held (evacuated) in a detector 12-3. Accordingly, the previous ten steps are shortened to six steps.

In the present embodiment, the XOR operation is carried out by executing an operation expression shown in the expression (3). Further, a description will be given only of different points in a structure from the first and second embodiments.

### 1. <Structure Example>

### 1.1 <Control Unit 150-1>

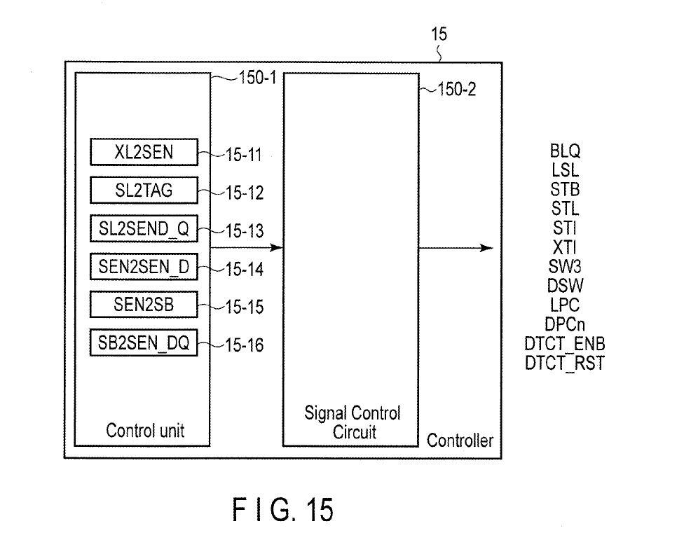

As shown in FIG. 15, a control unit 150-1 according to the present embodiment further includes XL2SEN15-11 and SL2TAG15-12.

H2SEN15-1 to SEN2TAGS15-10 described in the first embodiment are omitted here.

XL2SEN15-11 has a function of transferring a voltage level of a latch circuit 12-2 to SEN. Specifically, after charging LBUS and DBUS, the control unit 150-1 controls so as to set signals XTI and LSL to the “H” level, in relation to a signal control circuit 150-2.

SL2TAG15-12 has a function of transferring stored data of SDL to a data detector 12-3. In other words, the controller 15-1 controls so as to set signals STI, DTCT_RST and DTCT_ENB to the “H” level, in relation to the signal control circuit 150-2.

### 2. <XOR Operation>

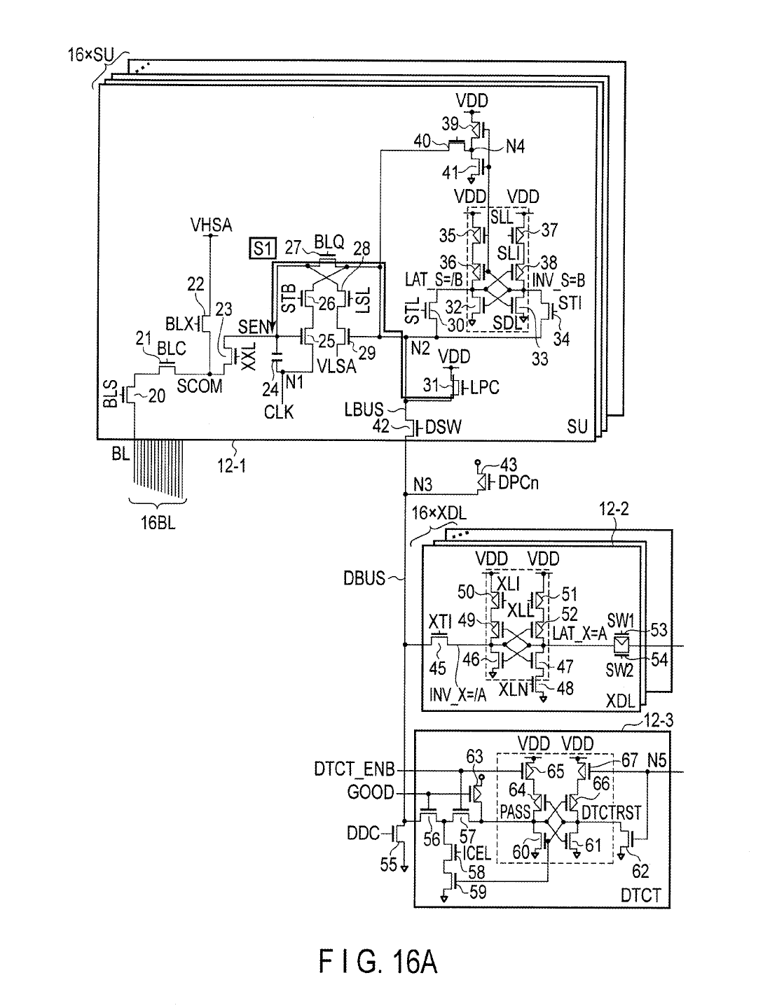

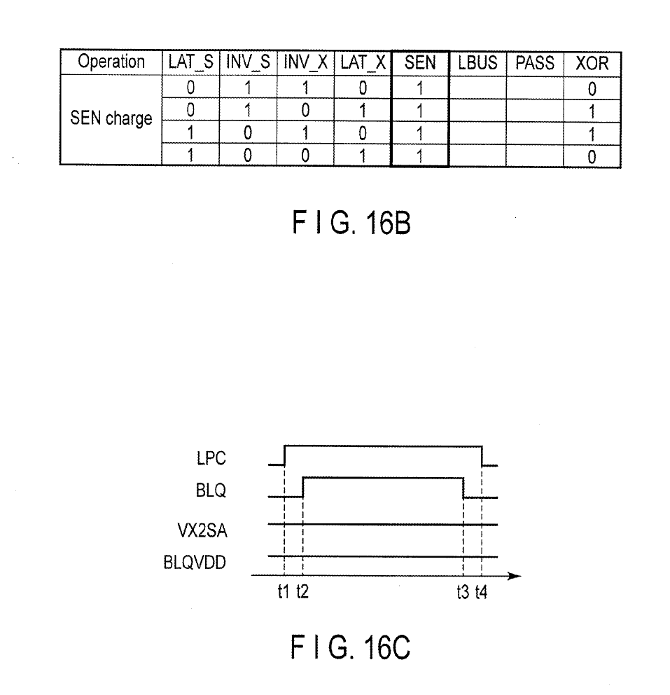

Next, a description will be given of an operation of the XOR operation about the data read by a sense amplifier 12 with reference to FIGS. 16A to 21A, 16B to 21B and 16C to 21C. A value (any value of “1” and “0”) in a vertical axis in each of nodes of FIGS. 16B to 21B is shown in a number of cases, and “1” means a potential of “H”, and “0” means a potential of “L”.

Further, the name of a function portion within the control unit 150-1 is attached to an outlet of each of steps executing the XOR operation.

### 2.1 <SEN Charge: H2SEN15-1>

First of all, as shown in FIG. 16A, a potential of SEN is charged to voltage VDD as shown in FIG. 16A. In other words, as shown in FIG. 16C, the voltage VDD is transferred to SEN via MOS transistors 31 and 27 by setting signals LPC and BLQ to “H”. Accordingly, a value of SEN is set to “H” (described as “1” in FIG. 16B) as shown in FIG. 16B.

### 2.2 <XLD=> SEN Transfer: XL2SEN15-11>

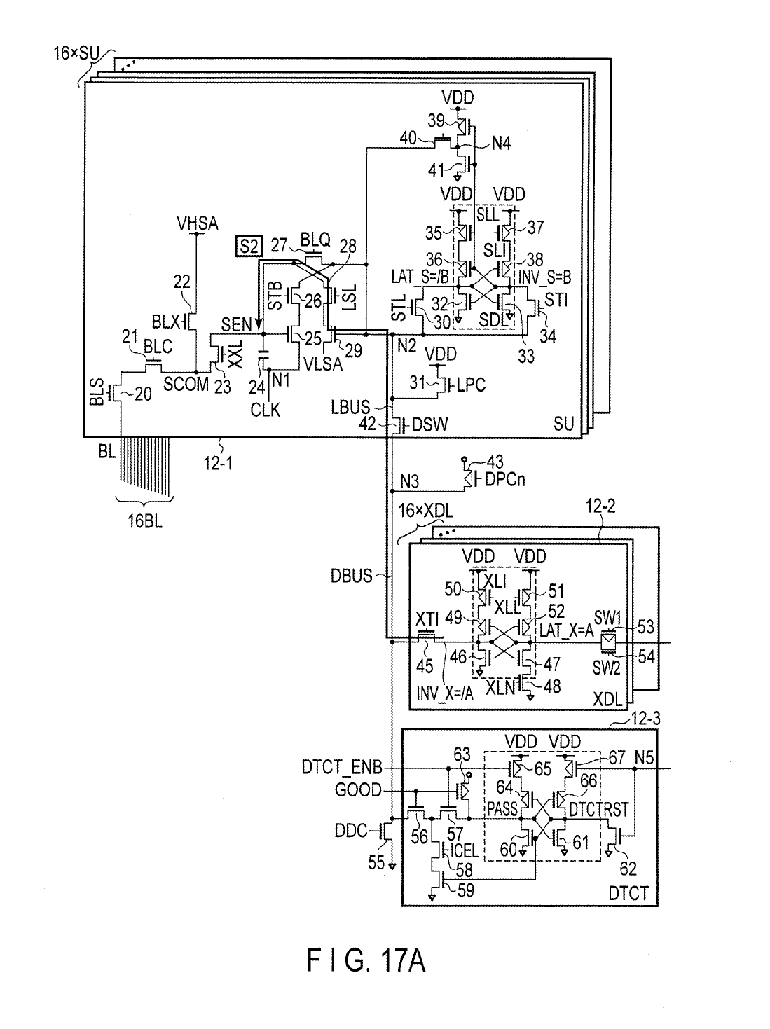

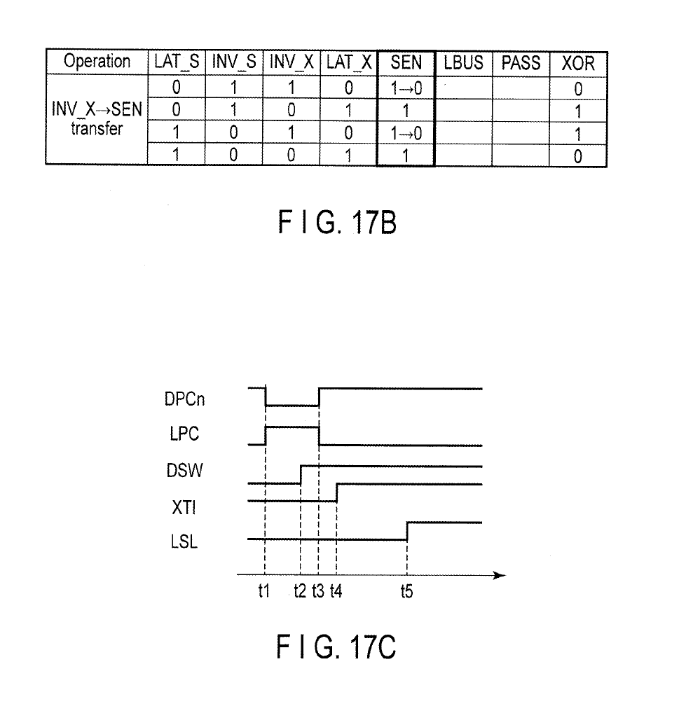

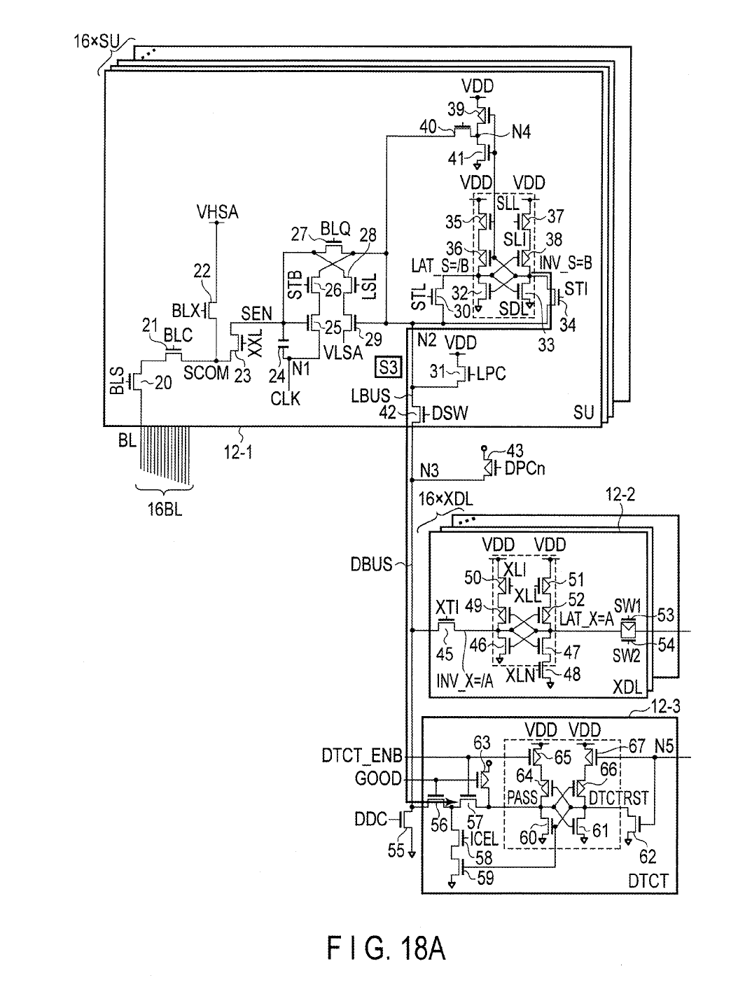

Next, as shown in FIG. 17A, LAT_X(/INV_X) is transferred to SEN. In other words, as shown in FIG. 17C, the control unit 150-1 sets a signal DPCn to “L” and sets signal LPC and DSW to “H”, in relation to the signal control circuit 150-2, thereby charting LBUS and DBUS and thereafter setting each of signals XTI and LSL to “H”.

Accordingly, in correspondence to a value of LAT_X, the MOS transistor 29 takes an on state or an off state. In other words, if the MOS transistor 29 is set to the on state, the value of SEN is set to the ground potential, that is, “L” (described as “1=> 0” in FIG. 17B).

### 2.3 <SDL=> DTCT Transfer: SL2TAG15-12>

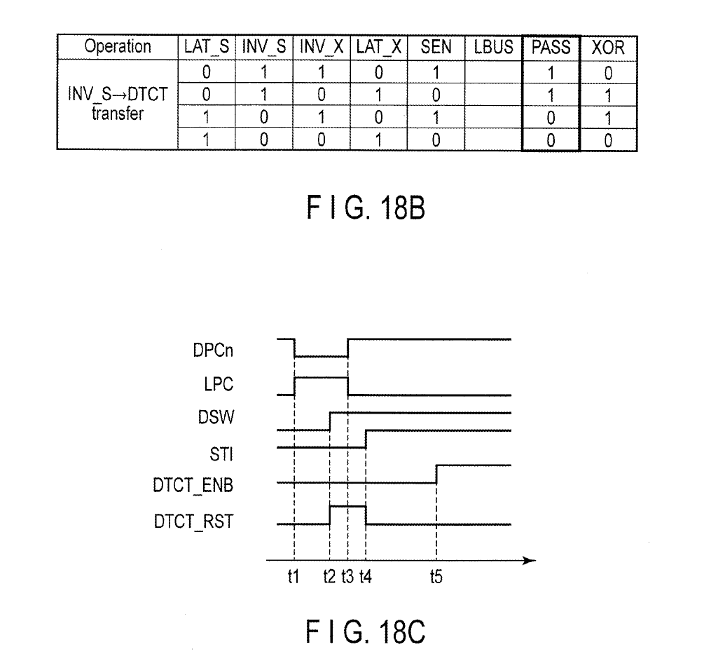

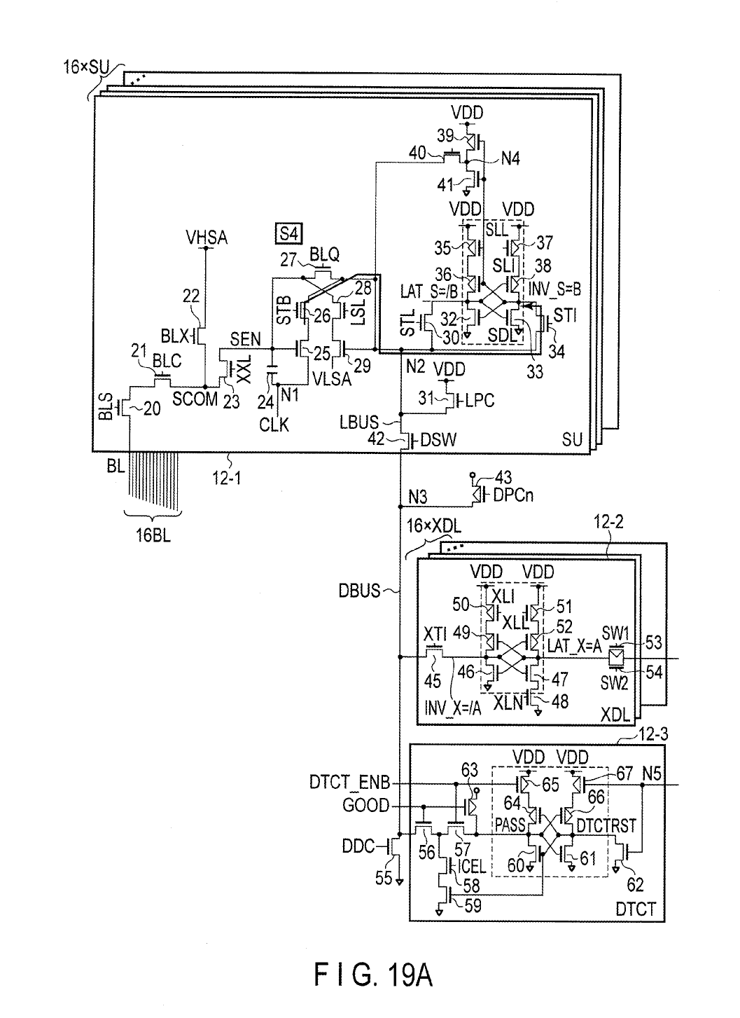

Next, as shown in FIG. 18A, inverted data (INV_S) of LAT_S is transferred to a detector 12-3.

Specifically, the detector 12-3 is reset while charting LBUS and DBUS by first of all setting the signal DPCn to “L” and setting the signals LPC and DSW to “H” as shown in FIG. 18C.

Thereafter, the inverted data of LAT_S is transferred to a node PASS via MOS transistors 34, 42 and 56 by further setting the signals STI and DTCT_ENB to “H”.

Therefore, in the case of LAT_S=“0” as shown in FIG. 18B, PASS=“1” is set.

### 2.4 <SEN=> SDL Transfer (AND Operation of /LAT_X and LAT_S): SEN2SL15-3>

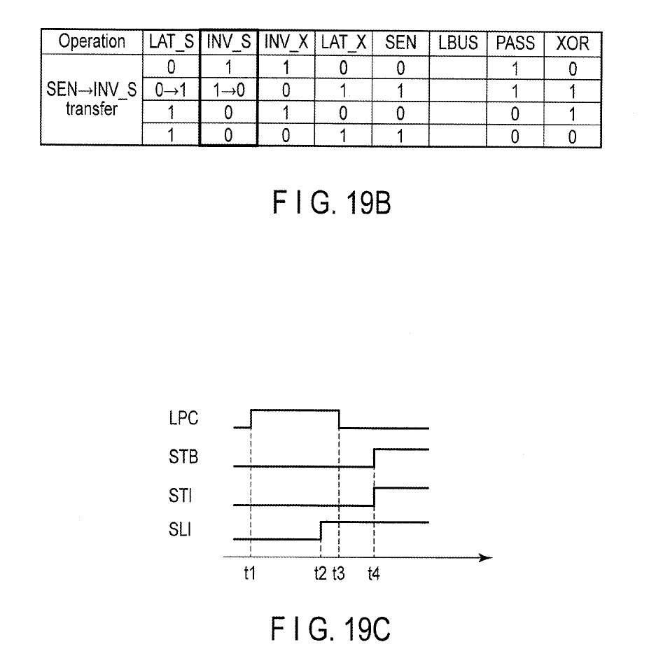

As shown in FIG. 19A, inverted data (/LAT_X) of LA_T X in SEN is transferred to SDL. In other words, the value of SEN is transferred to INV_S by setting the signal LPC to “H” as shown in FIG. 19C, charging LBUS and thereafter setting the signals STB and STI to “H”.

The value of INV_S changes in correspondence to the value of SEN, for example, in the case of SEN=“1” as shown in FIG. 19B, INV_S is switched, i.e., INV_S=“1=> 0”. Accordingly, AND operation of /LAT_X and /LAT_S is executed.

### 2.5 <DTCT=> SEN Transfer (AND Operation of LAT_S and LAT_X): DTCTB2SEN15-7>

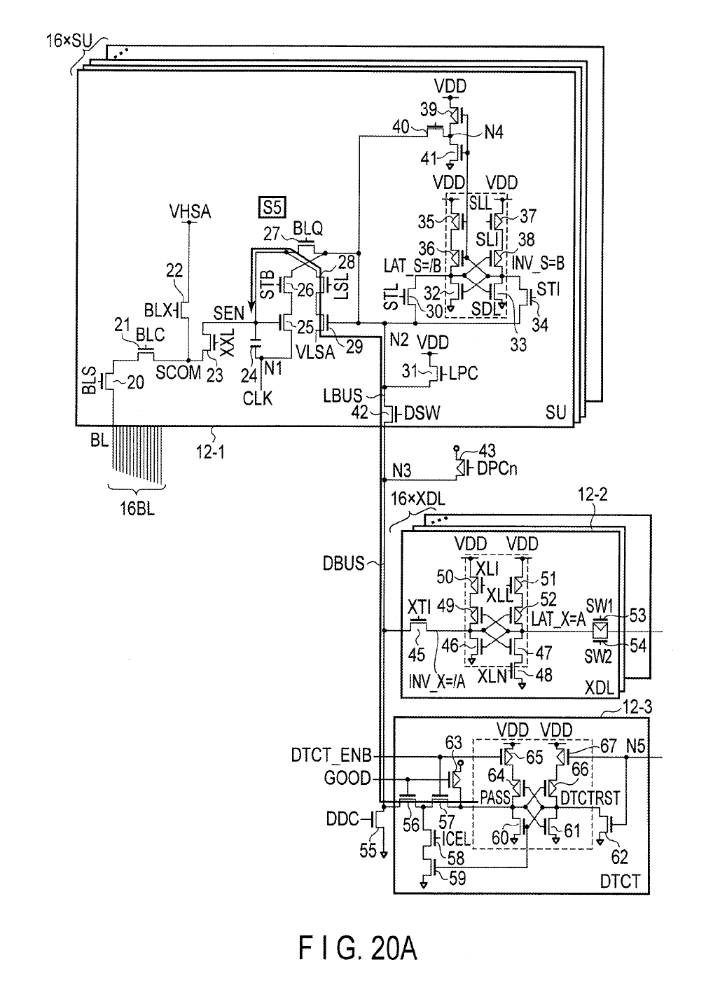

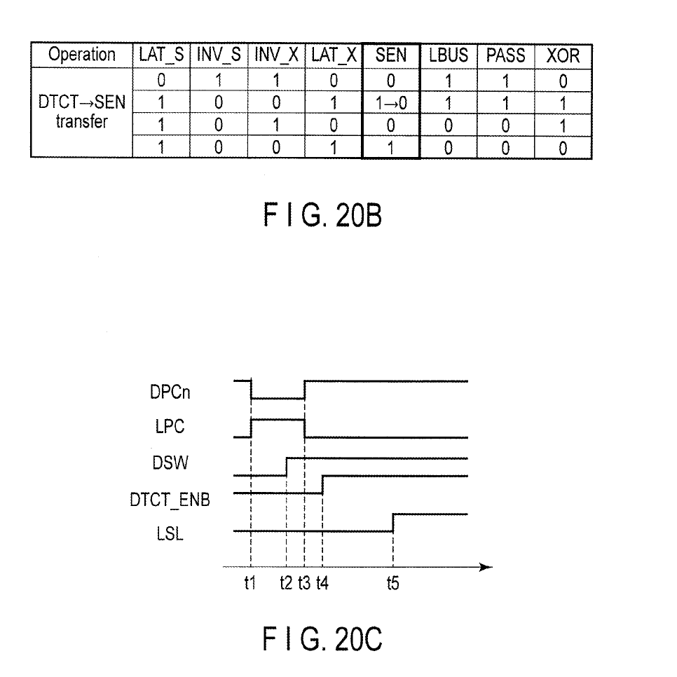

As shown in FIG. 20A, /LAT_S in the node PASS is transferred to SEN (SEN holds LAT_X here). In other words, AND operation of LAT_S and LAT_X is executed by the operation.

As the operation, as shown in FIG. 20C, LBUS and DBUS are charged by first of all setting the signal DPCn to “L” and setting the signals LPC and DSW to “H”. Thereafter, the value of the node PASS is transferred to SEN via the MOS transistors 57, 56, 42, 29 and 28 by setting the signals DTCT_ENB and LSL to “H”.

Therefore, if the value of the node PASS is “1”, for example, as shown in FIG. 20B, the MOS transistor 29 is set to an on state. Accordingly, the value of SEN comes to the ground potential, that is, “0”.

On the contrary, if the value of SEN is “0”, the MOS transistor 29 is off, and the value of SEN does not change.

A signal GOOD is a signal indication as to whether or not the corresponding bit line BL has any bad, as mentioned above, and signal GOOD=“H” is established in the case that the bit line BL does not have any bad.

### 2.6 <SEN=> SDL Transfer (AND Operation of Inverted Data in 2.4 and Inverted Data in 2.5): SEN2SB15-15>

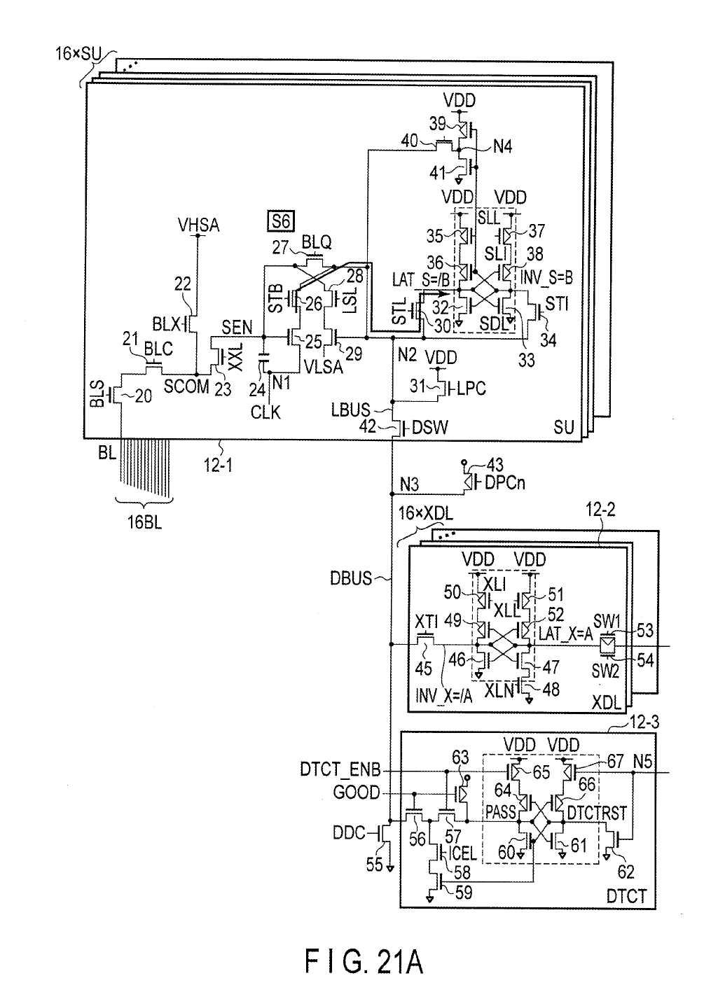

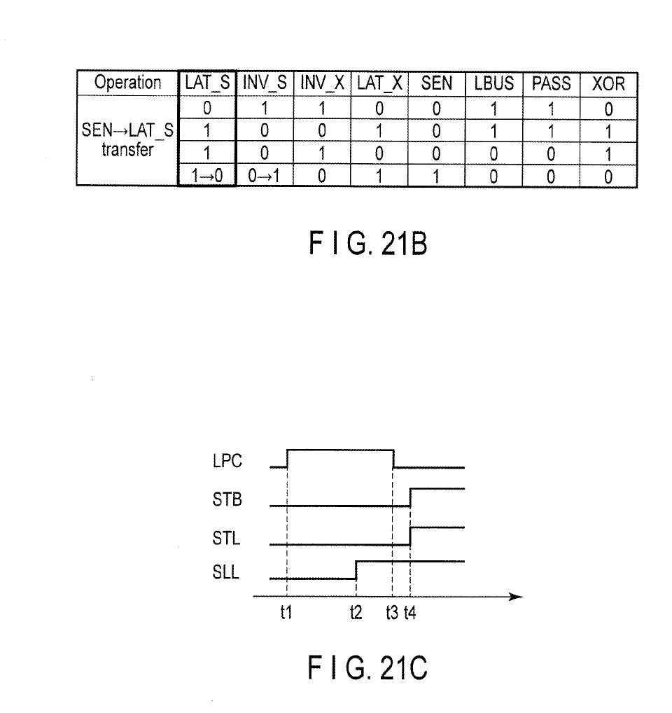

As shown in FIG. 21A, the inverted data of SEN is transferred to SDL (LAT_S side).

In other words, as shown in FIG. 21C, LBUS is charged by setting the signal LPC to “H”, and the inverted data of SEN is next transferred to LAT_S by setting each of the signals STB and STL to “H”. Accordingly, the XOR operation is executed.

Therefore, for example, if the value of SEN is “1” as shown in FIG. 21B, as a result of execution of XOR operation, LAT_S comes to the ground potential, that is “0”, and the value of LAT_S comes to “0”, “1”, “1” and “0” from the above.

### <Effect According to Third Embodiment>

In the semiconductor memory storage apparatus according to the present embodiment, a operation speed may be improved above that realized by effects (1) and (2) obtained by the first and second embodiments.

This is because the processes of the steps S6, S7 and S9 in the first and second embodiments are omitted, and the XOR operation is finished between SEN and SDL as mentioned above.

Further, the step S9 is a step for transferring data of the detector 12-3 to SDL, however, a reset operation of SDL is necessary for carrying out the transfer.

In other words, four steps may be totally omitted, and a high speed operation may be realized.

### Fourth Embodiment

Next, a description will be given of a semiconductor memory device according to a fourth embodiment. The present embodiment is also the same as the third embodiment in a point that an XOR operation is finished by six steps, however, is different from the third embodiment in a point that an evacuation end of SDL data is set to SEN of an adjacent sense unit SU12-1.

### <Conceptual Diagram>

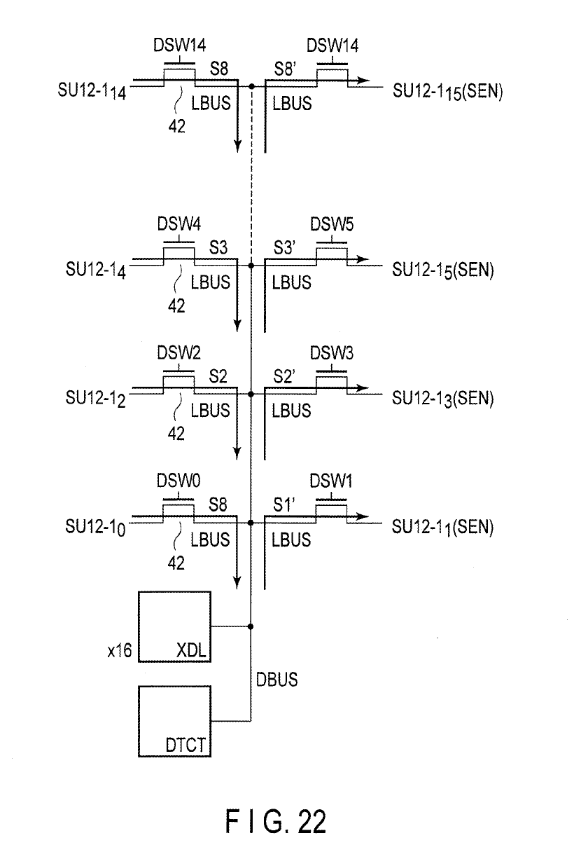

To provide more detail, a conceptual diagram of data evacuation is shown in FIG. 22. FIG. 22 is a conceptual diagram simply showing the SU12-1, the latch unit 12-2 and the detector 12-3 which are shown in FIG. 6.

As shown in FIG. 22, one DBUS is connected to SU12-1₀ to SU12-1₁₅. Further, corresponding sixteen latch units 12-2 and one detector 12-3 are respectively connected to DBUS.

Since it is necessary to use DBUS for SDL=> adjacent SEN data transfer, the SDL data is first of all evacuated to the adjacent SEN in the order of step S1=> step S1′=> step S2=> step S2′, . . . , step S15=> step S15′ as shown in FIG. 22, as one example of the data transferring method.

Thereafter, the XOR operation is carried out in these SU12-1₀, SU12-1₂, SU12-1₄, . . . , and SU12-1₁₄.

Next, with regard to the corresponding SU12-1₁, SU12-1₃, SU12-1₅, . . . , and SU12-1₁₅, a predetermined XOR operation is executed after going through the same step (evacuation of SDL data to the adjacent SEN).

### 2. <Structure Example>

### 1.1 <Control Unit 150-1>

The control unit 150-1 shown in FIG. 15 further includes SL2SEND_DQ15-13, SEN2SEN_D15-14, SEN2SB15-15 and SB2SENDQ15-16.

SL2SEND_DQ15-13 actuates the adjacent even and add sense units SU12-1 as one set, at a time of carrying out one operation within the XOR operation. Specifically, SL2SEND_DQ15-13 has a function of transferring the stored data of SDL to SEN within the adjacent sense unit SU12-1 via DBUS after transferring the stored data of SDL.

Accordingly, the control unit 150-1 controls both the even and odd sense units SU12-1 with regard to the signals LPC and DSW, in relation to the signal control circuit 150-2.

Further, with regard to the signals STL and BLQ, the control unit 150-1 carries out a complementary control in the even and odd sense units SU12-1. Specifically, for example, in the case that the signal BLQ in the odd sense unit SU12-1 is set to the “H” level, the control unit 150-1 controls so as to set the signal STL in the corresponding even sense unit SU12-1 to the “H” level.

SEN2SEN_D15-14 actuates the adjacent even and odd sense units SU12-1 as one set at a time of carrying out one operation within the XOR operation. Specifically, the SEN2SEN_D15-14 has a function of transferring the SEN data to SEN within the adjacent sense unit SU12-1 via DBUS after temporarily transferring the data of SEN to DBUS.

As a specific method, SEN2SEN_D15-14 controls voltage levels of the signals LPC and DSW in both the even and odd sense units SU12-1. For example, SEN2SEN_D15-14 sets each of the signals LPC and DSW in the even and odd sense units SU12-1 to the “H” level, and connects LBUS and DBUS.

Conversely, with regard to the signals LSL and STB, SEN2SEN_D15-14 carries out a complementary control in the even and odd sense units SU12-1.

Specifically, for example, in the case that the signal BLQ in the odd sense unit SU12-1 is set to be at the “H” level, SEN2SEN_D15-14 controls so as to set the signal LSL in the corresponding even sense unit SU12-1 to the “H” level.

SEN2SB_15-15 has a function of transferring the value of SEN to SDL. Specifically, SEN2SB15-15 controls so as to transfer the signals LPC, STB, STL and SLL to the “H” level in relation to the signal control circuit 150-2.

SB2SEN_DQ15-16 actuates the adjacent even and odd sense units SU12-1 as one set at a time of carrying out one operation within the XOR operation. Specifically, the SB2SEN_DQ15-16 has a function of transferring the SDL data to SEN within the adjacent sense unit SU12-1 via DBUS after temporarily transferring the data stored in SDL to DBUS.

Accordingly, SB2SEN_DQ15-16 controls the voltage levels of the signals LPC and DSW in the even and odd sense unit SU12-1, in the same manner as SEN2SEN_D15-14.

Further, in the signals STL and BLQ, for example, in the case that the signal BLQ in the odd sense unit SU12-1 is set to “H”, SB2SEN_DQ15-16 controls so as to set the signal STL in the corresponding even sense unit SU12-1 to the “H” level.

### 3. <XOR Operation>

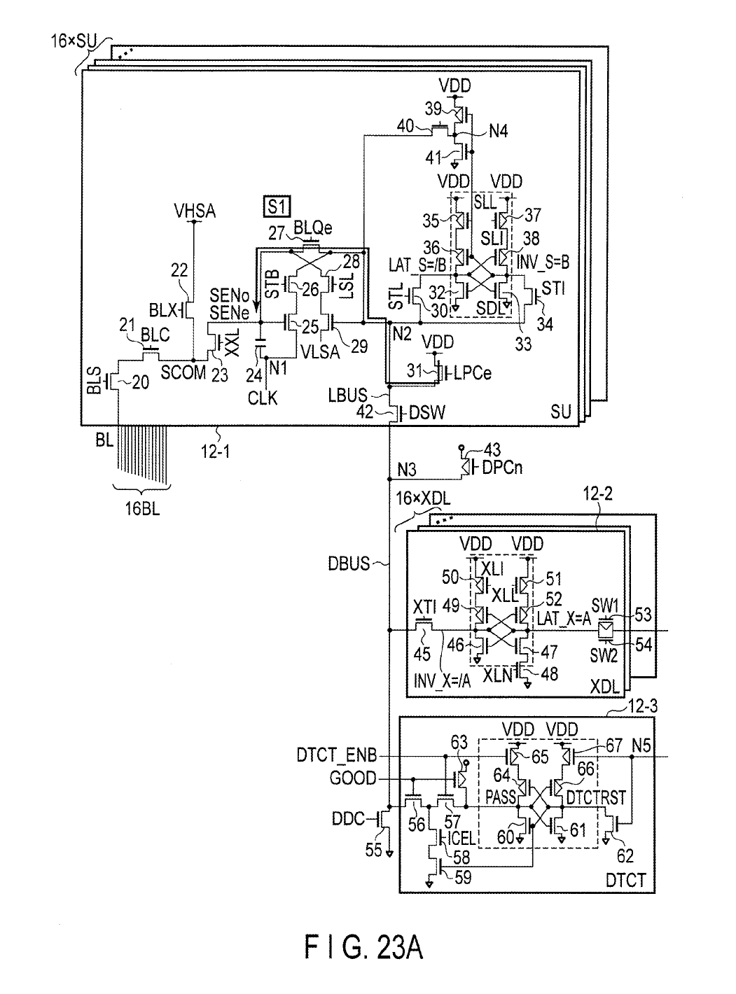

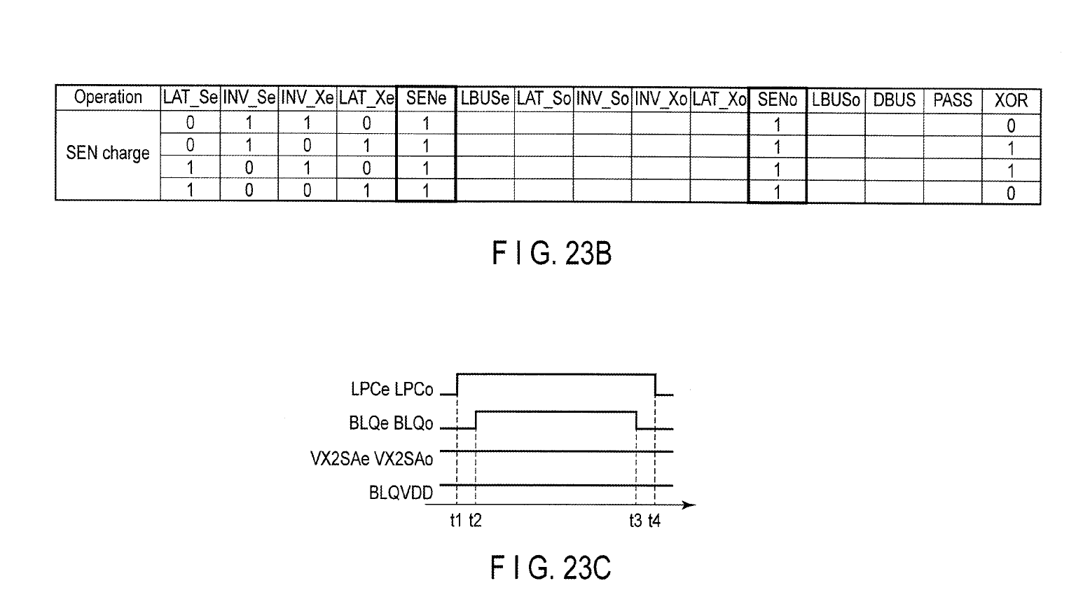

Next, a description will be given of the XOR operation about the data read out by the sense amplifier 12 with reference to FIGS. 23A to 28A, 23B to 28B and 23C to 28C.

Respective nodes shown in FIGS. 23B to 28B indicate the even sense units SU12-1 in SU12-1₀, SU12-1₂, SU12-1₄, . . . , and SU12-1₁₄, and the odd sense units SU12-1 in SU12-1₁, SU12-1₃, SU12-1₅, . . . , and SU12-1₁₅.

Further, due to limitations of space, the single sense unit SU12-1 is shown in FIGS. 23A to 28A, however, both the even sense units SU12-1 and the odd sense units SU12-1 are shown by describing a sign “e” or “o” indicating even number or odd number as the occasion demands in each of the nodes.

### 3.1 <SEN Charge: H2SEN15-1>

First of all, as shown in FIG. 23A, each of SENe and SENo is charged. In other words, the voltage VDD is transferred to SEN via MOS transistors 31 and 27 by setting each of the signals LPCe and LPCo, and the signals BLQe and BLQo to “H” as shown in FIG. 23C. Accordingly, values of SENe and SENo come to “1” as shown in FIG. 23B.

### 3.2 <XDL=> SENe Transfer: SL2SEN15-11>

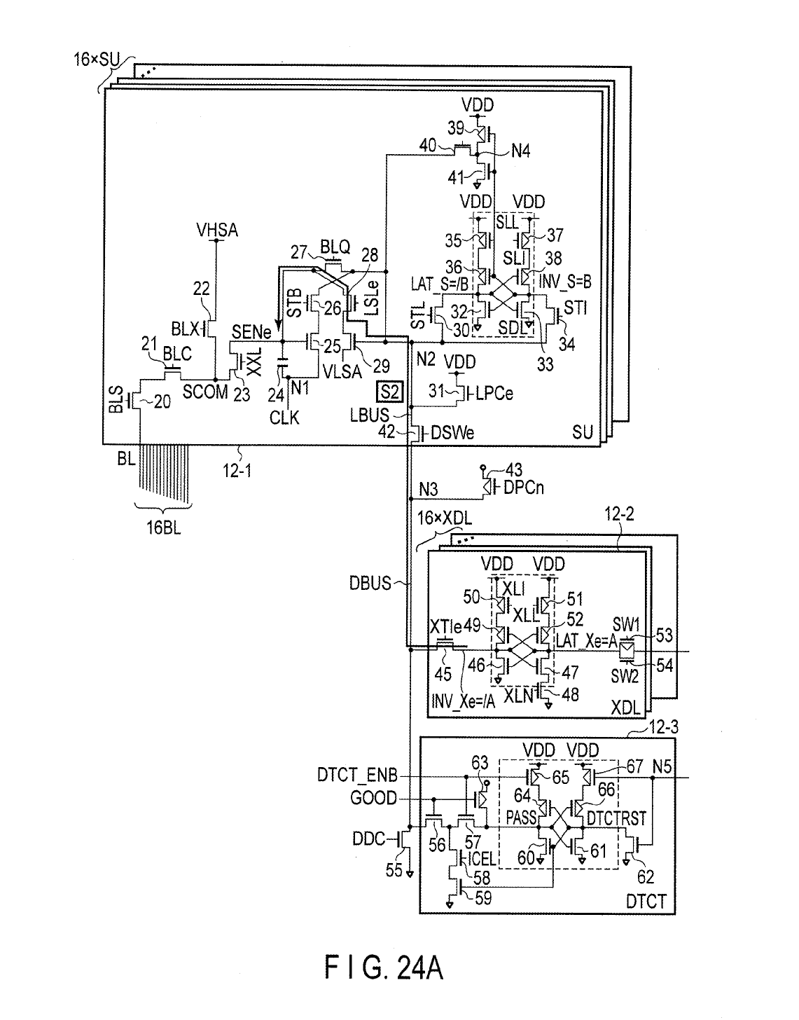

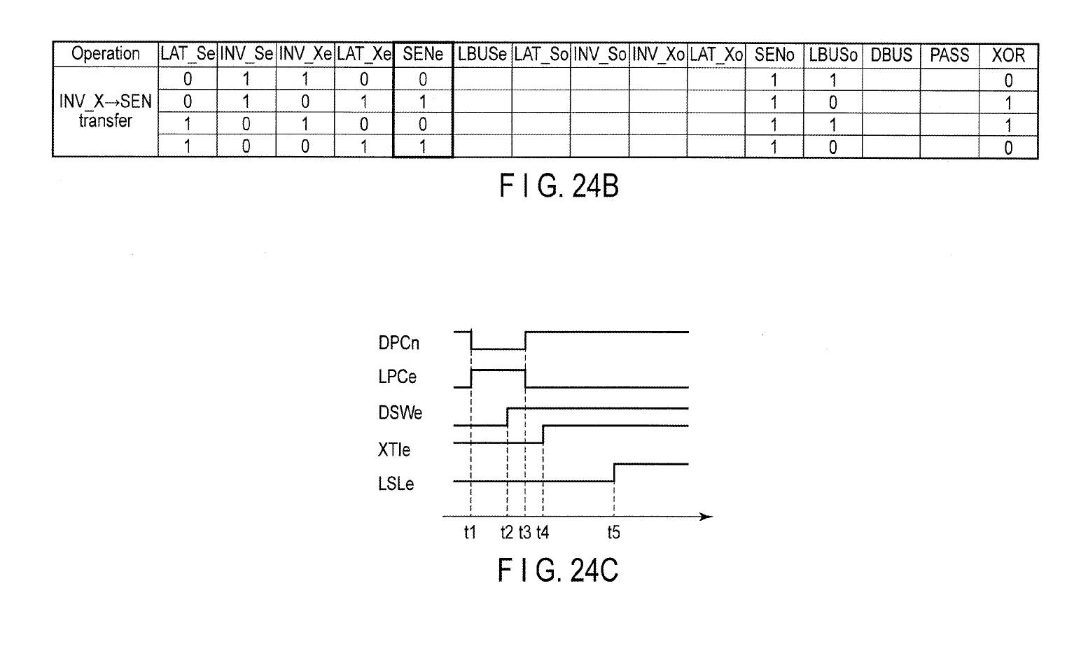

Next, as shown in FIG. 24A, the XDL data (LAT_X) is transferred to SENe in the even sense unit SU12-1. In other words, each of signals XTIe and LSLe is set to “H” after charting LBUS and DBUS, by setting a signal DPCn to “L” and setting signals LPCe and DSWe to “H”, as shown in FIG. 24C.

Accordingly, the MOS transistor 29 takes an on state or an off state in correspondence with the value of LAT_X. In other words, if the MOS transistor 29 is set to the on state under the value of LAT_X being “0”, SENe is set to the ground potential, that is, “L” (described as “0” in FIG. 24B).

Since the MOS transistor 29 is off in the case that the value of LAT_X is “1”, SENe does not change.

### 3.3 <SDLe=> SENo Transfer: SL2SEND_DQ15-13>

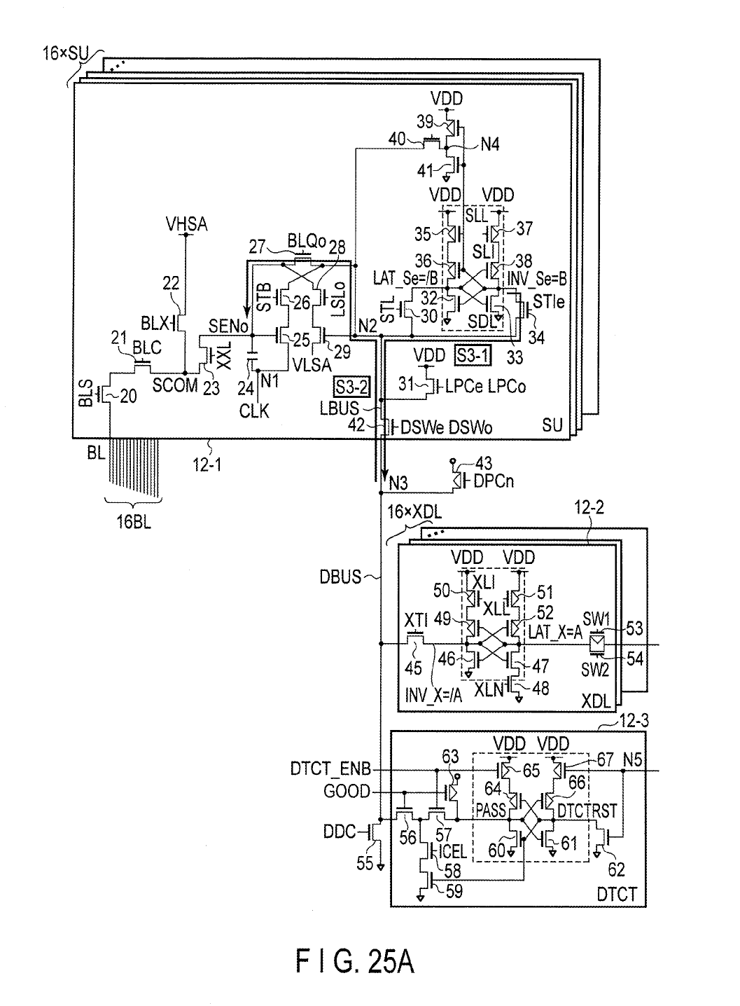

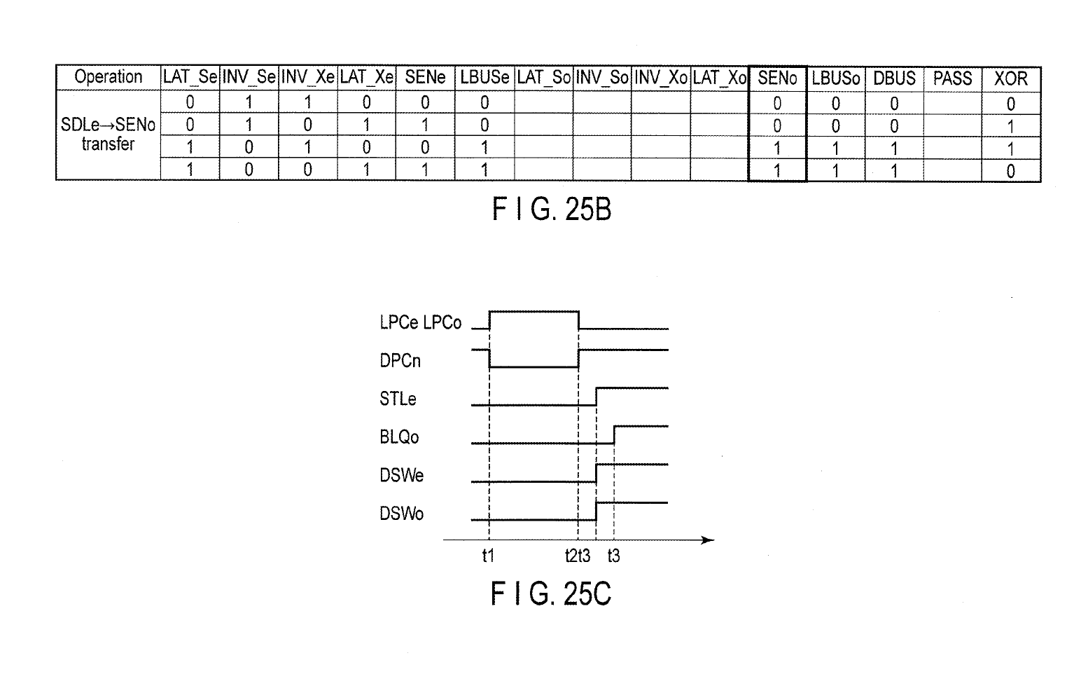

Next, as shown in FIG. 25A, the value of SDLe is transferred to SENo. In other words, as shown in FIG. 25C, that is, each of the signals LPCe and LPCo, and the signal DPCn is set to “H”, and LBUS and DBUS are charged, at time t1.

Next, the signals STLe and DSWe are set to “H” at time t3, and the value of SDLe is once transferred to DBUS.

Further, the signal DSWo is set to “H” at the same time t3, and the even LBUS and the odd LBUS are connected via DBUS. Therefore, the previous value of SDLe is transferred to the odd LBUS.

Thereafter, the value of SDLe is transferred to SENo via the node N2 and the MOS transistor 27, by setting the signal BLQo to “H” at time 4.

Accordingly, the value of INV_Se is evacuated to SENo as shown in FIG. 25B.

### 3.4 <SENe=> SDLe Transfer (AND Operation of /LAT_X and /LAT_S): SEN2SL15-3>

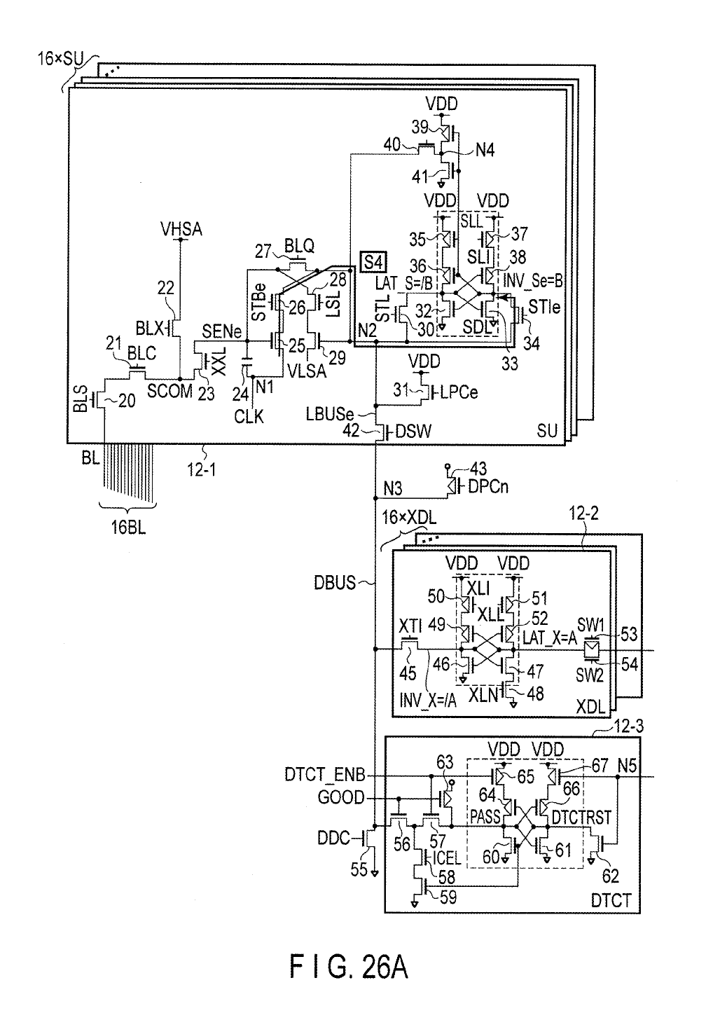

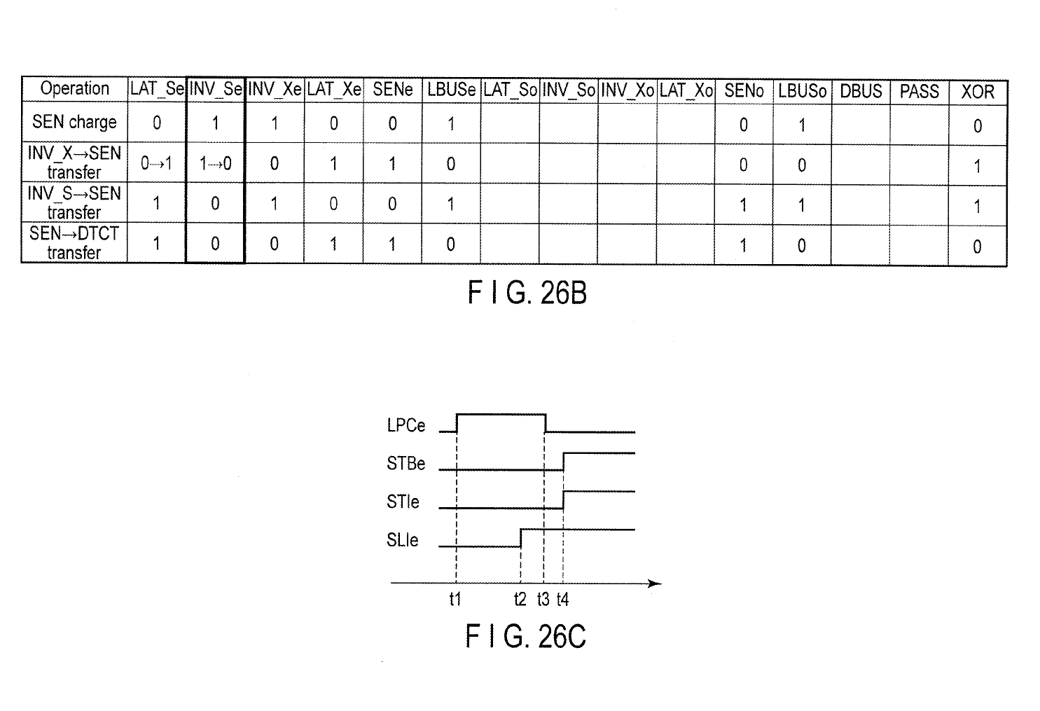

Since the value of SDLe is evacuated to the adjacent sense unit SU12-1 in the item 3.3, the XOR operation is started thereafter within the even sense unit SU12-1. In other words, the value of SENe is transferred to SDLe as shown in FIG. 26A.

Specifically, the value corresponding to SENe is transferred to SDLe, by setting the signal LPCe to “H” at time t1 as shown in FIG. 26C, charging LBUS, and thereafter setting each of the signals STBe and STIe to “H” after switching the signal SLIe to “H” at time t2.

Therefore, in the case that SENe is “1” as shown in FIG. 26B, the MOS transistor is turned on and INV_Se is set to the ground potential as a result. Therefore, INV_Se is transferred to “0”. N1 is the ground potential at this time.

### 3.5 <SENo=> SENe Transfer (AND Operation of LAT_S and LAT_X>

Next, the stored data of SDL which is temporarily evacuated in SENo is transferred to SENe within the sense unit SU12-1 under operation.

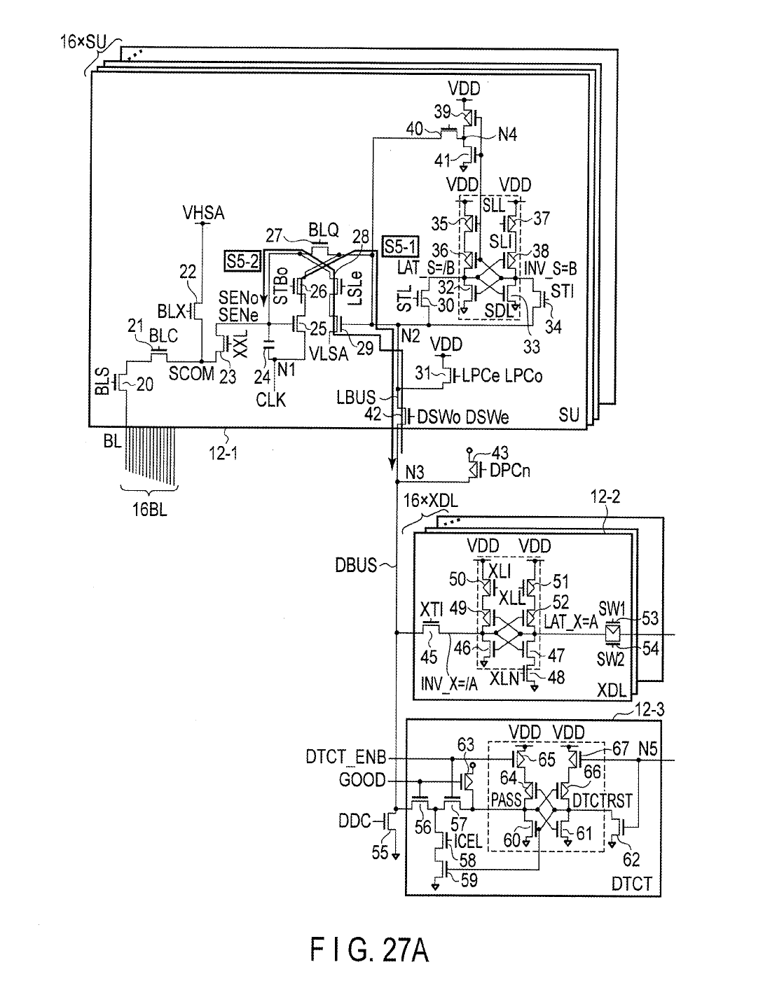

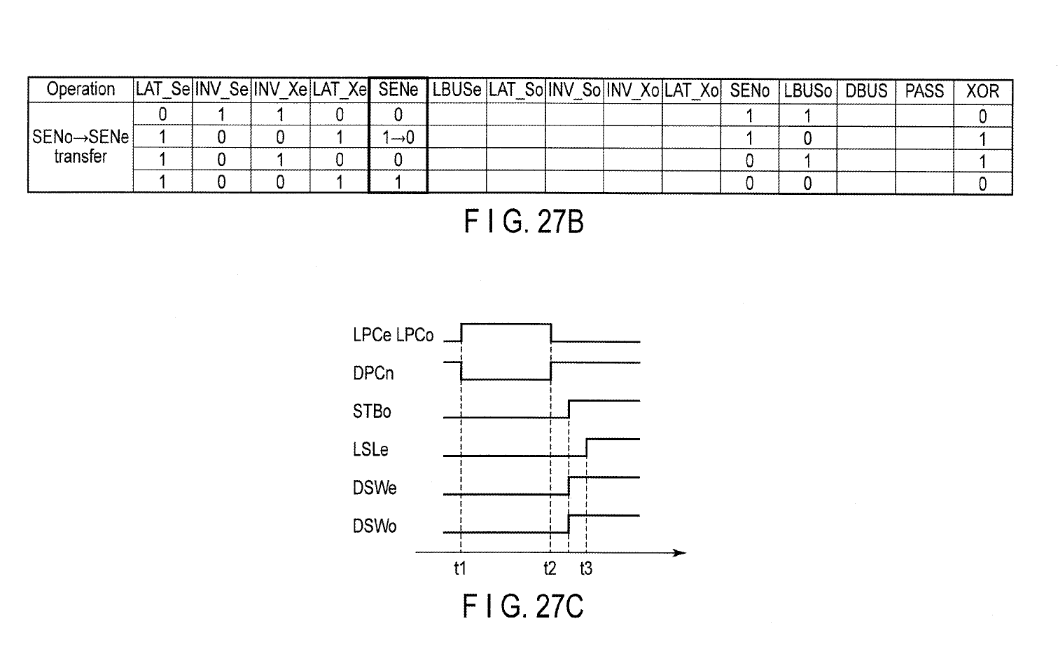

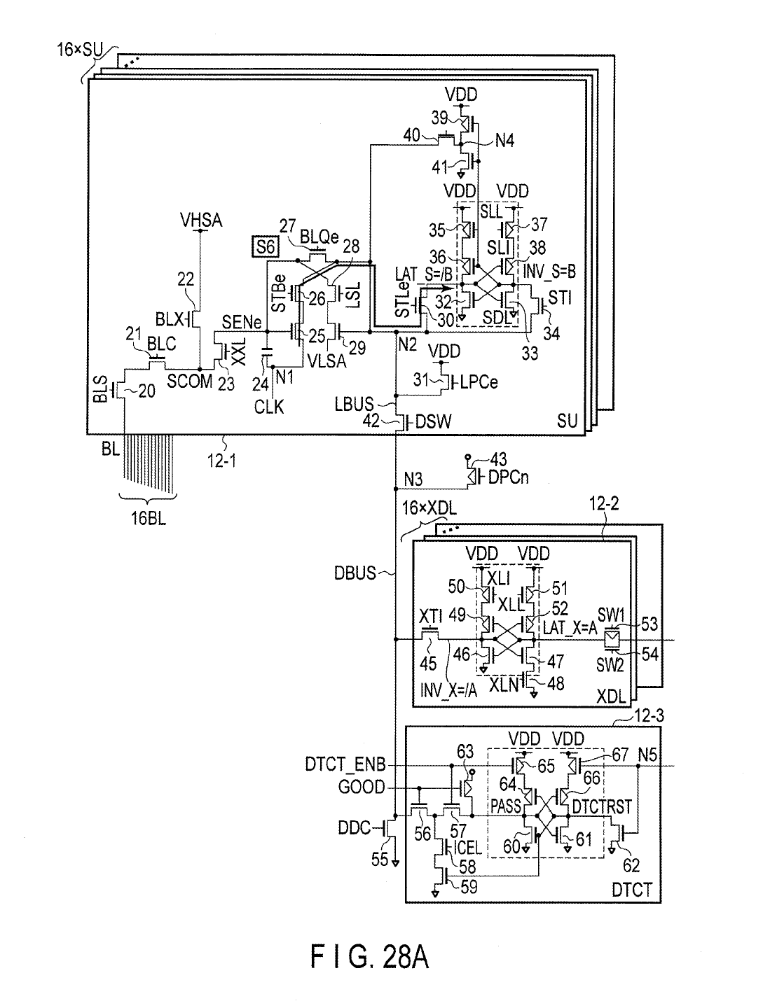

As shown in FIG. 27A, a value corresponding to SENo is temporarily transferred to DBUS via LBUS in the odd side (S5-1 in FIG. 27R).

Thereafter, the value of DBUS is transferred to SENe via DBUS and LBUS in the even side.

In other words, the signals LPCe and LPCo are set to “H” and LBUS is charged first of all at time t1 as shown in FIG. 27C.

Thereafter, each of the signals STBo and DSWo is set to “H” at time t3, and a value corresponding to SENo is temporarily transferred to DBUS.

Further, the value transferred to DBUS is taken in the sense unit 12-1 (LBUSe) in the even side by setting the signal DSWe to “H” at the same time t3.

Specifically, the signal LSLe is set to “H” at time t4. Accordingly, a value corresponding to LBUSe is transferred to SENe (S5-2 in FIG. 27A).

Therefore, for example, in the case that SENo is “0” as shown in FIG. 27B, DBUS is set to “1” as a result of a step S5-1. Accordingly, if a step S5-2 is next executed, SENe is transferred to the ground potential, that is, “0” via the MOS transistors 29 and 28.

### 3.6 <SENe=> SDL Transfer (AND Operation of Inverted Data of 3.4 and Inverted Data of 3.5>

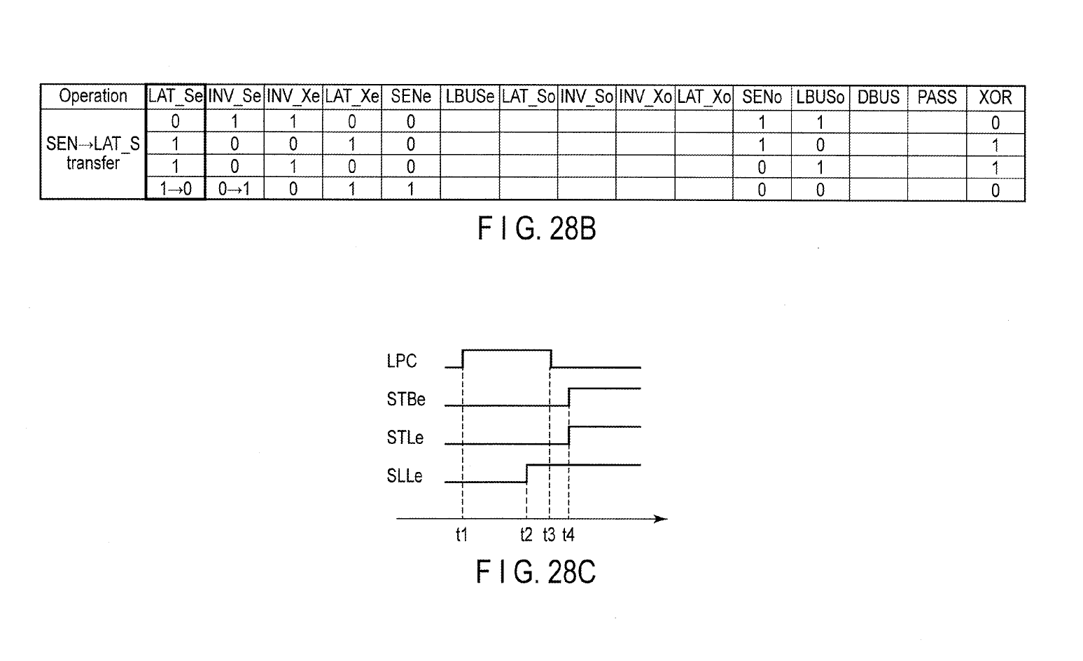

Next, the value of SENe is transferred to SDL as shown in FIG. 28A (step S6 in FIG. 28A).

In other words, a value corresponding to SENe is transferred to LAT_Se by charting LBUS by setting the signal LPCe to “H” at time t1 as shown in FIG. 28C, and thereafter setting the signals STBe and STLE to “H” at time t4. Accordingly, an XOR operation is executed.

Therefore, for example, in the case that SENe is “1” as shown in FIG. 28B, as a result of execution of the XOR operation, LAT_Se is set to the ground potential via a node N2, the MOS transistors 26 and 25 and the node N1, and is transferred to “0” from the previous “1”.

As a result, the value of LAT_S comes to “0”, “1”, “1” and “0” from the above. As a result of the steps S1 to S6, the value of LAT_Se comes to a value obtained by execution of the XOR operation.

### <Effect According to the Present Embodiment>

Even in the semiconductor memory storage apparatus according to the present embodiment, the number of the steps required for the XOR operation may be reduced in the same manner as the third embodiment, and a high processing speed may be realized.

The present embodiment is different from the third embodiment in a point that the evacuation end of the SDL data is set to the capacitor element 24 of the adjacent sense unit 12-1; however, is in common with the third embodiment in the point that the XOR operation is realized by the capacitor element 24 and SDL. Accordingly, the operation requires only six steps, higher operation than the effect obtained by the items (1) and (2) may be realized, and a high speed processing may be realized as a whole for the reading operation.

### Fifth Embodiment

Next, a description will be given of a semiconductor memory storage apparatus according to a fifth embodiment. The present embodiment is the same as the third embodiment in the point that the XOR operation is finished by six steps; however, is different from the third embodiment in the point that the evacuation end of the SDL data is set to the bit line BL.

### 1. <XOR Operation>

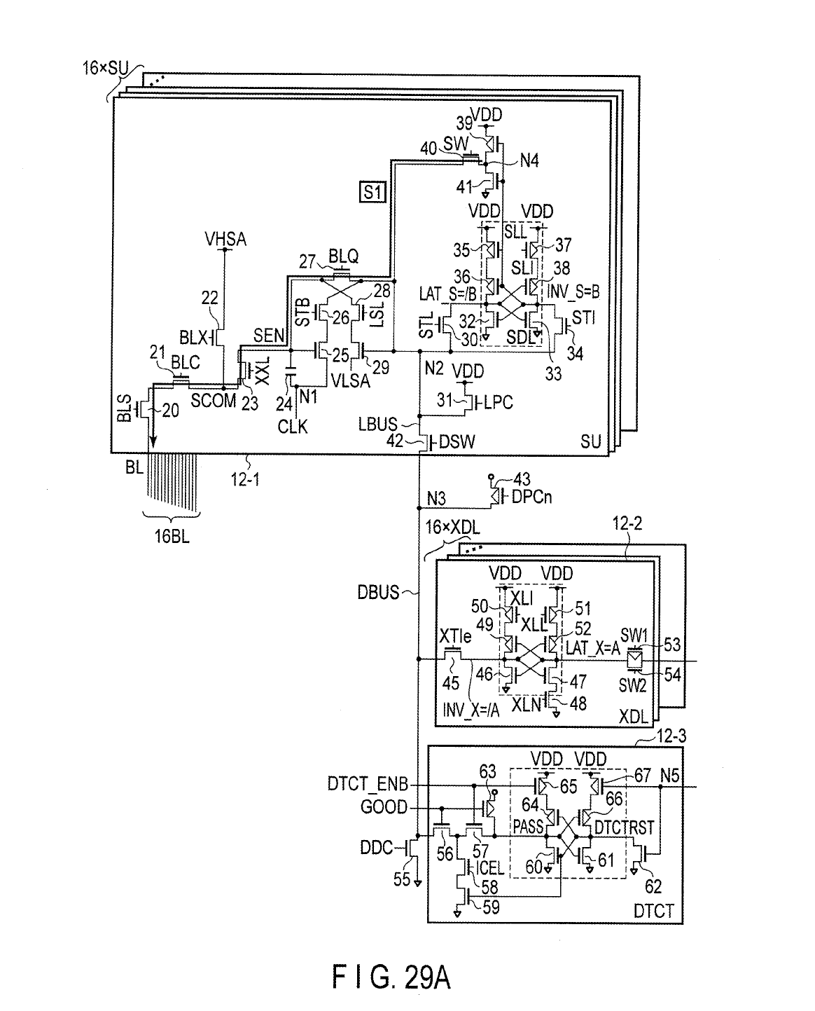

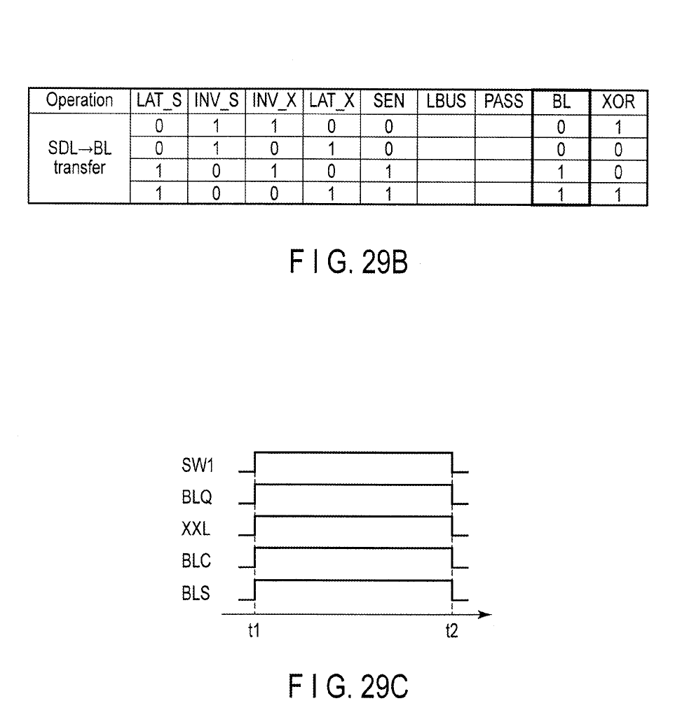

Next, a description will be given of an XOR operation about data read by a sense amplifier 12 with reference to FIGS. 29A to 34A, 29B to 34B and 29C to 34C.

### 1.1 <SDL=> BL Transfer>

As shown in a step S1 in FIG. 29A, SDL data is transferred to a bit line BL via MOS transistors 39 and 27, SEN, and MOS transistors 23, 21 and 20.

In other words, a potential of a node N4 is transferred to the bit line BL by setting each of SW1, a signal BLQ, a signal XXL, a signal BLC and a signal BLS to “H” at time t1 as shown in FIG. 29C.

Therefore, for example, if INV_S is “0” as shown in FIG. 29B, the MOS transistor 39 is turned on.

Accordingly, voltage VDD is transferred to the bit line BL and the potential of the bit line BL comes to “1”.

One end of the MOS transistor 39 may be directly connected to SCOM. In this case, control of the signal BLQ and the signal XXL is not necessary.

Further, the order of the following operation 1.2 (SEN charge) may be carried out ahead of the operation 1.1 (SDL=> BL transfer).

### 1.2 <SEN Charge: H2SEN15-1>

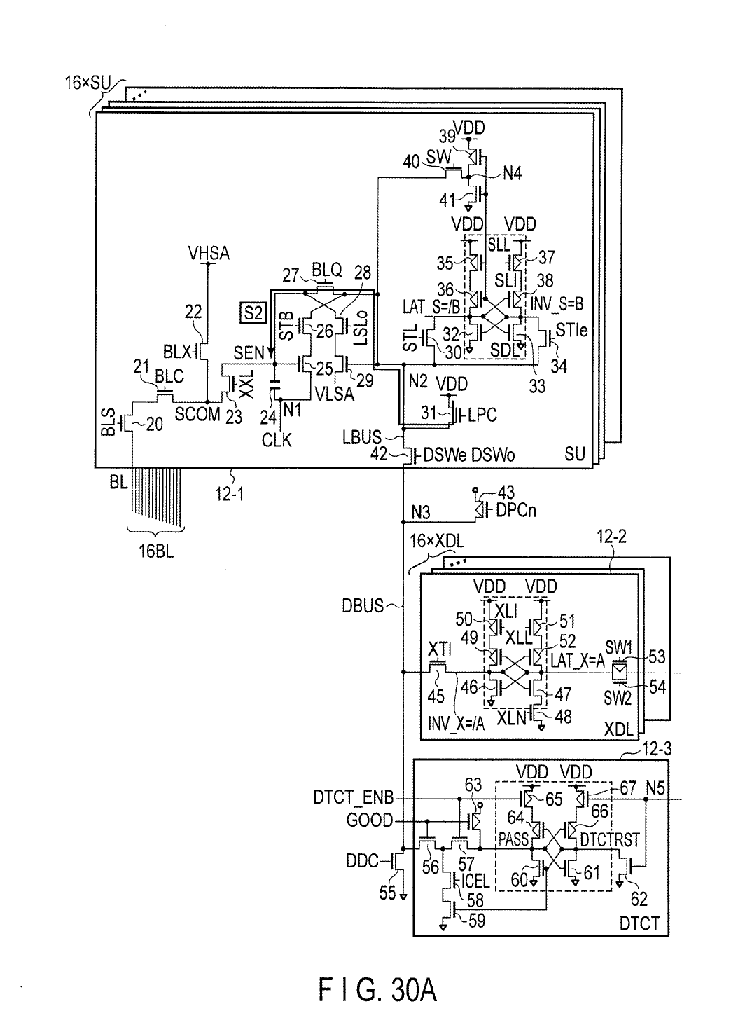

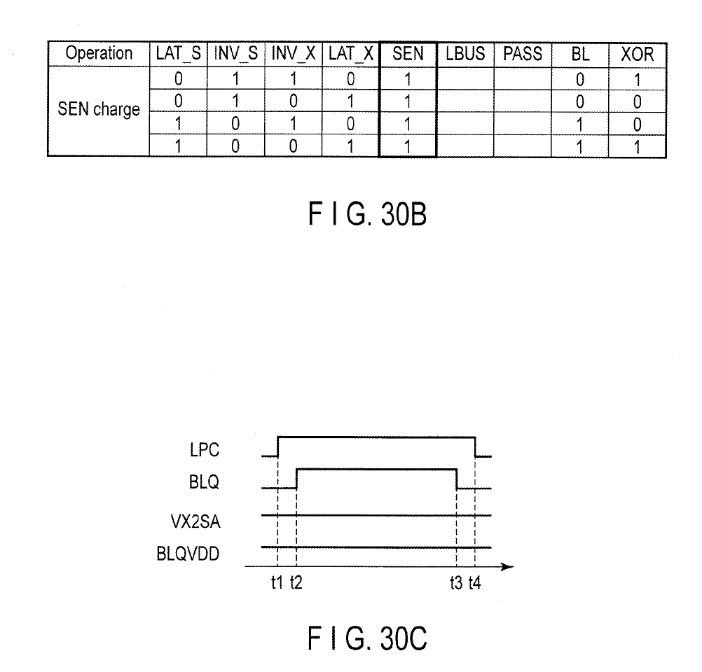

Next, SEN is charged as shown in FIGS. 30A to 30C. Since the operation is mentioned above, a description thereof will be omitted.

### 1.3 <XDL=> SEN Transfer: XL2SEN15-11>

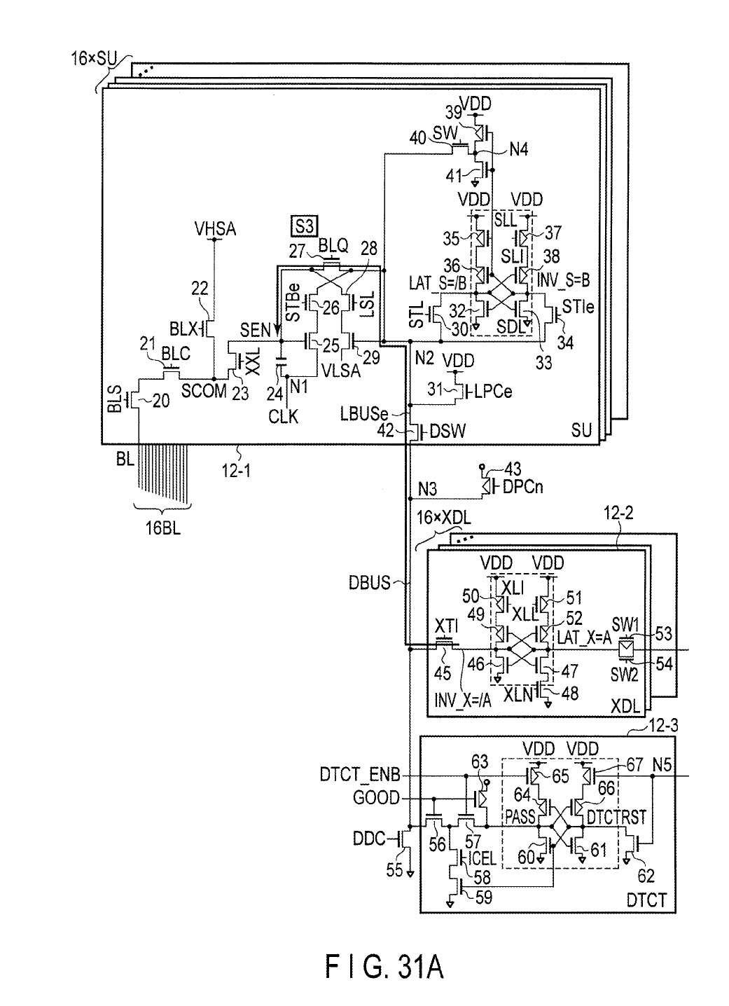

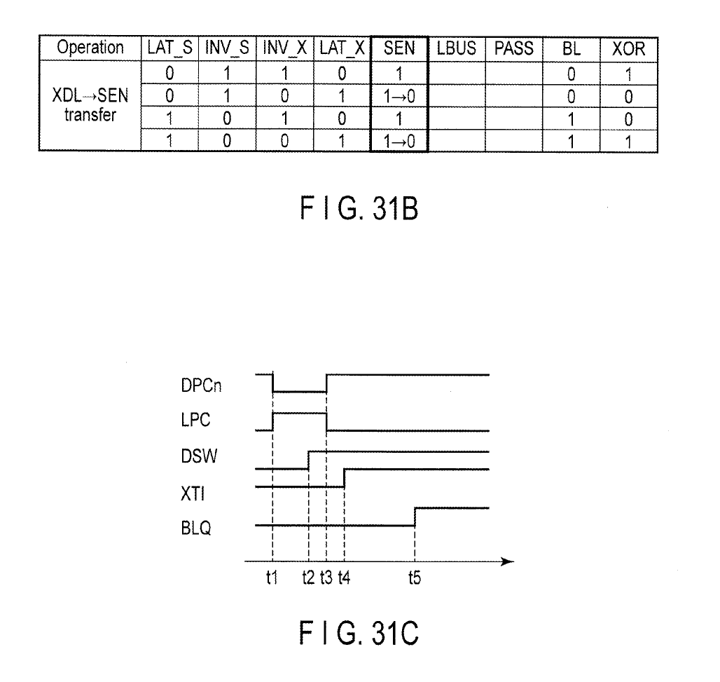

Next, as shown in a step S3 in FIG. 31A, stored data of a latch unit 12-2 is transferred to SEN.

In other words, LBUS and DBUS are charged by setting a signal DPCn to “L” and setting a signal LPC to “H” at time t1 as shown in FIG. 31B, and next setting a signal DSW to “H” at time t2.

Next, after a signal XTI is set to “H” at time t4, a signal BLQ is set to “H” at time t5. Accordingly, inverted data of LAT_X is transferred to SEN.

In other words, as shown in FIG. 31C, for example, if the inverted data of LAT_X is “1”, SEN is not transferred while maintaining “1”; however, if the inverted data is “0”, SEN is transferred to “0” from “1”.

### 1.4<SEN=> SDL Transfer (AND Operation of /LAT_X and /LAT_S): SEN2SL15-3>

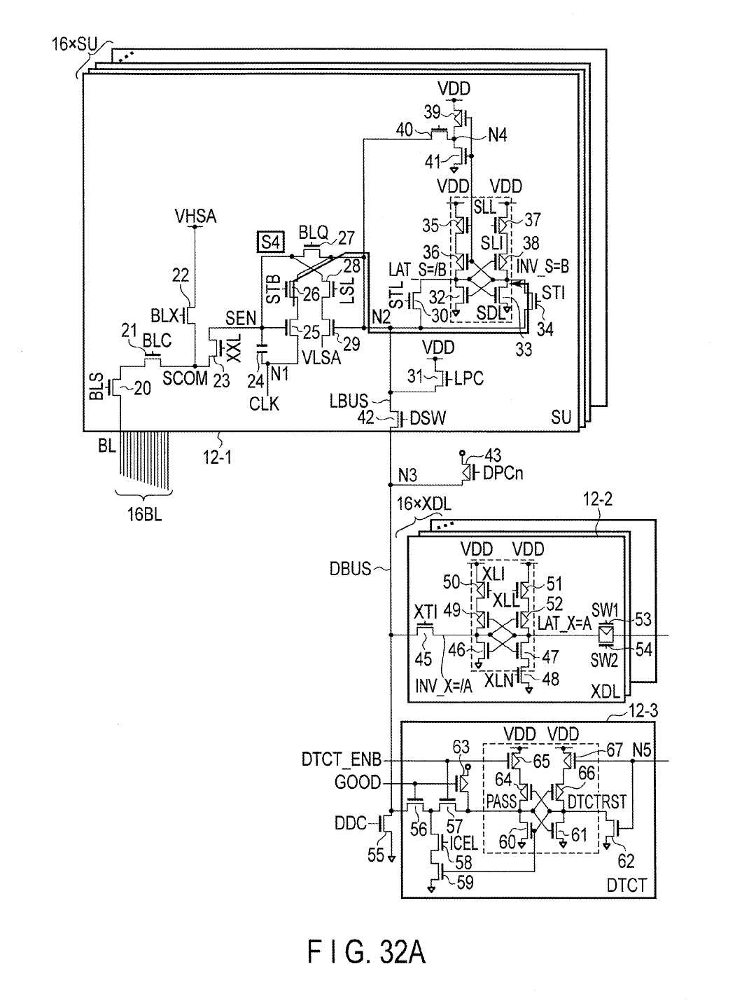

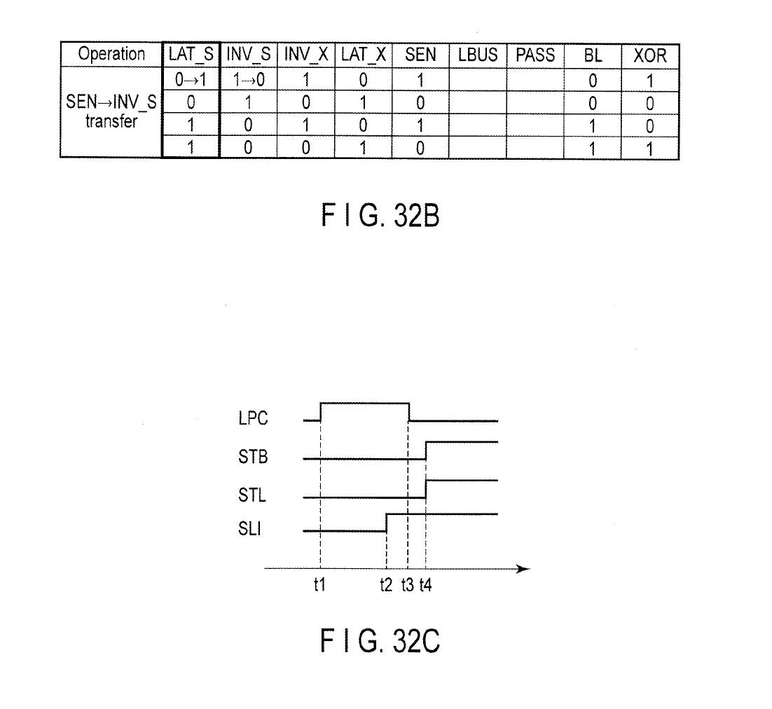

Next, as shown in FIGS. 32A to 32C, the value of SEN is transferred to a latch unit 12-2. Since the operation is mentioned above, a description thereof will be omitted.

### 1.5 <BL SEN (Sense Operation) (AND Operation of LAT_X and LAT_S): DTCTB2SEN15-7>

Next, a sense operation is executed. Here, a description will be given by paying attention to an operation of the sense unit 12-1.

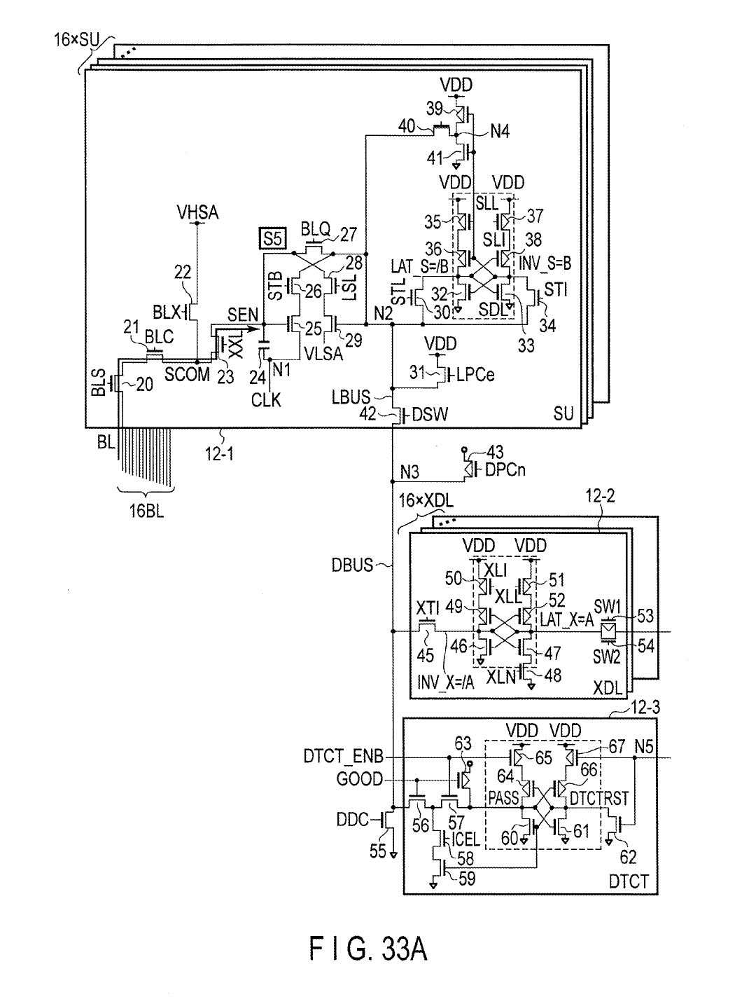

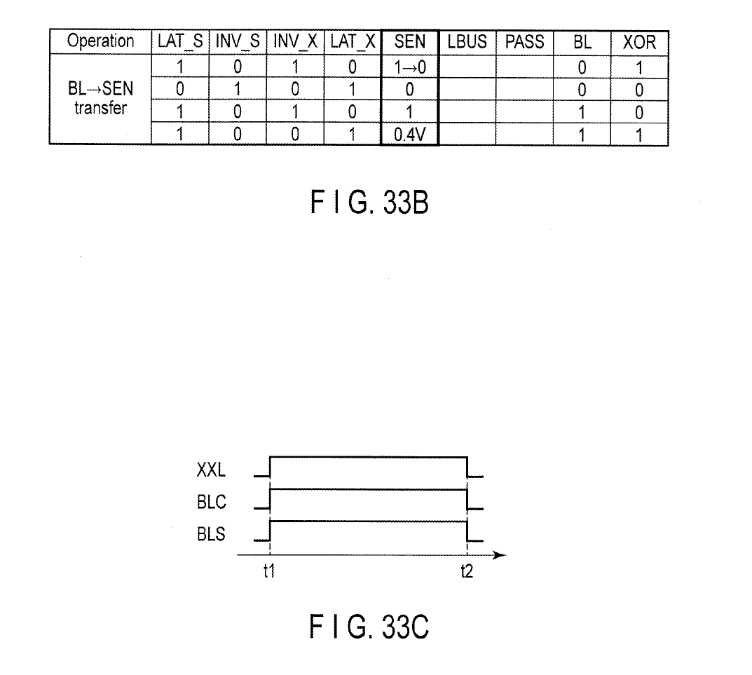

As shown in a step S5 in FIG. 33A, a potential of the bit line BL is sensed, and is determined to be any of “1” and “0” in correspondence with the transfer of the SEN potential.

As a specific operation of the step S5, each of the signals BLS, BLC and XXL is set to “H” at the time t1, and the bit line BL and SEN are electrically connected.

As shown in FIG. 33B, the transfer of SEN is changed, for example, in correspondence with a voltage level of the bit line BL, and if the voltage level of the bit line BL is “0”, SEN is set to “0”.

Further, as shown in FIG. 33B, if the voltage level of the bit line BL is “1”, and SEN is also “1”, the value of SEN stays at “1” without generation of charge share; however, in the case that SEN is “0”, SEN rises up to about 0.4 V as a result of the charge share.

However, a clock CLK equal to or more than 0.4 V is input to the capacitor element 24 in the node N1 at the same time as the charge share. Accordingly, even if SEN rises up to 0.4 V as a result of the charge share, the value of SEN is assumed to be equal to or less than 0 V, that is, the voltage level is assumed to be “L”, by transferring the voltage level of the clock CLK to “L”. Therefore, the MOS transistor 25 is not turned on, and there is no problem with the operation.

Even if the clock CLK is not input to the capacitor element 24, the voltage level about 0.4 V is assumed to be “L”. Therefore, the MOS transistor 25 is not turned on.

### 1.6 <SEN=> SDL Transfer (AND Operation of Inverted Data in 2.4 and Inverted Data in 2.5>

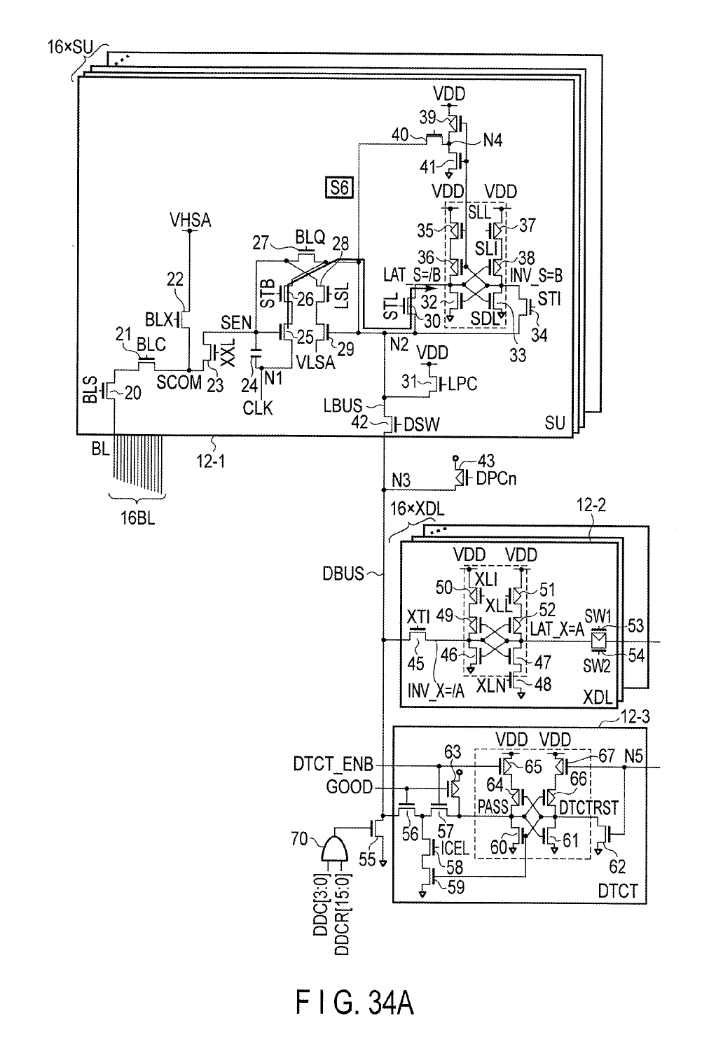

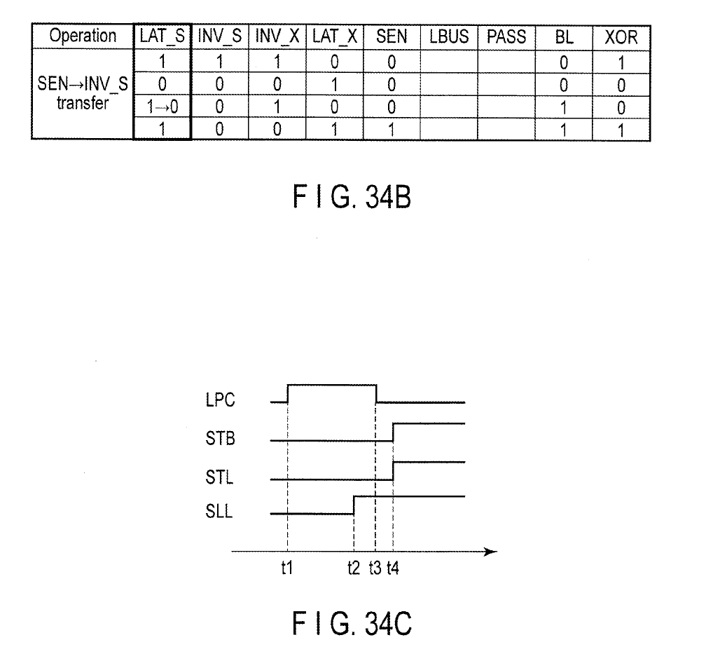

Finally, as shown in FIGS. 34A to 34C, the value of SEN is transferred to SDL. Since the operation is mentioned above, a description thereof will be omitted.

### <Effect According to the Present Embodiment>

In the semiconductor memory storage apparatus according to the present embodiment, the number of the steps required for the XOR operation may be reduced in the same manner as the third and fourth embodiments, and a high speed processing speed may be realized.

The present embodiment is different from the third and fourth embodiments in a point that the evacuation end of the SDL data is set to the bit line BL; however, is in common with the third and fourth embodiments in a point that the XOR operation is realized by SEN and SDL. Accordingly, the operation requires only six steps, and a higher speed operation than the effects obtained by the items (1) and (2) may be realized, and a high speed process may be realized as a whole for the reading operation.

### Sixth Embodiment

Next, a description will be given of a semiconductor memory storage apparatus according to a sixth embodiment. The third to fifth embodiments determine based on the result of the XOR operation whether or not the read data has any erroneous read; however, the sixth embodiment carries out the XOR operation by read data and SEED value (any value of “1” and “0”) in a sense amplifier 12, and returns (decodes) the randomized read data to the original data.

In the present embodiment the SEED value is used for a voltage level of a signal DSW in place of the storage of the SEED data in the latch unit 12-2. In other words, “H” or “L” of the signal DSW changes in correspondence with the SEED value, the voltage level of the signal DSW is “H” in the case that the SEED value is “1”, and the voltage level of the signal DSW is “L” in the case that the SEED value is “0”.

As mentioned above, the sixth embodiment aims at shortening the time for decoding the randomized data by using no latch unit 12-2 at a time of the XOR operation.

Since the latch unit 12-2 has a function to transfer the data read out of the memory cell array to an external device, a time loss is caused if the latch unit 12-2 doubles as the function of the XOR operation. In order to avoid the time loss, the present embodiment aims at shortening the reading time by doing away with the XOR operation using the latch unit 12-2.

In the XOR operation described below, steps of the XOR operation are differentiated by a difference of a structure of the sense unit 12-1 (whether SCOM or LBUS a connection end of one end of a current path of a MOS transistor 40 is).

Therefore, a description will be divided into a case (first case) that one end of the current path of a MOS transistor 39 is connected to SCOM and a case (second case) that one end of the MOS transistor 39 is connected to LBU. A description of the same structures as the embodiments will be omitted.

### 1. <Structure>

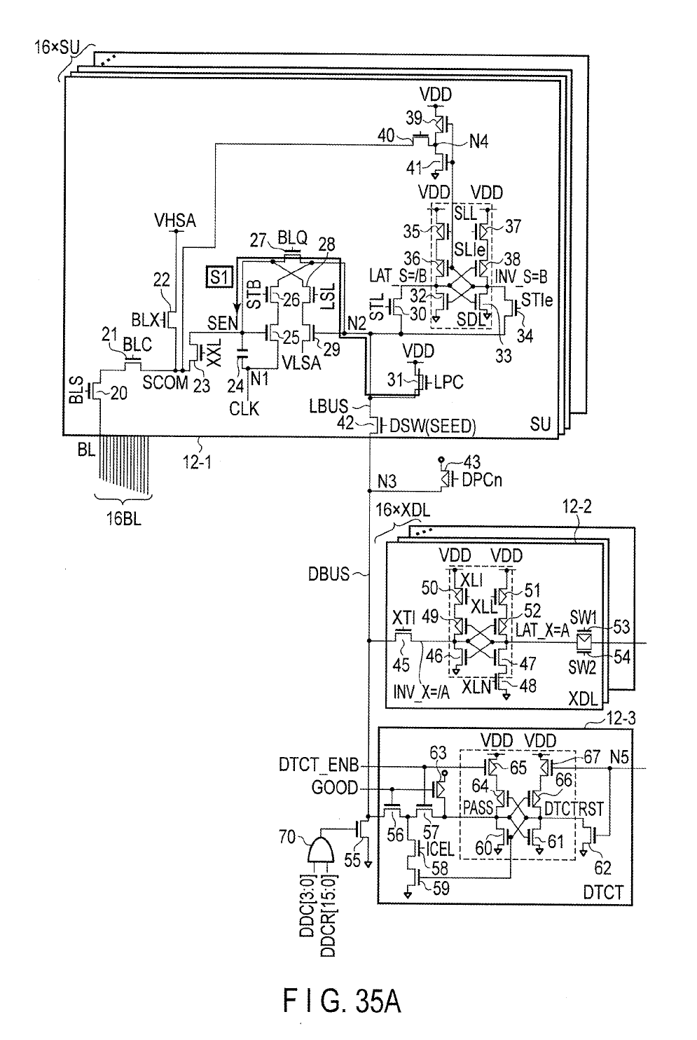

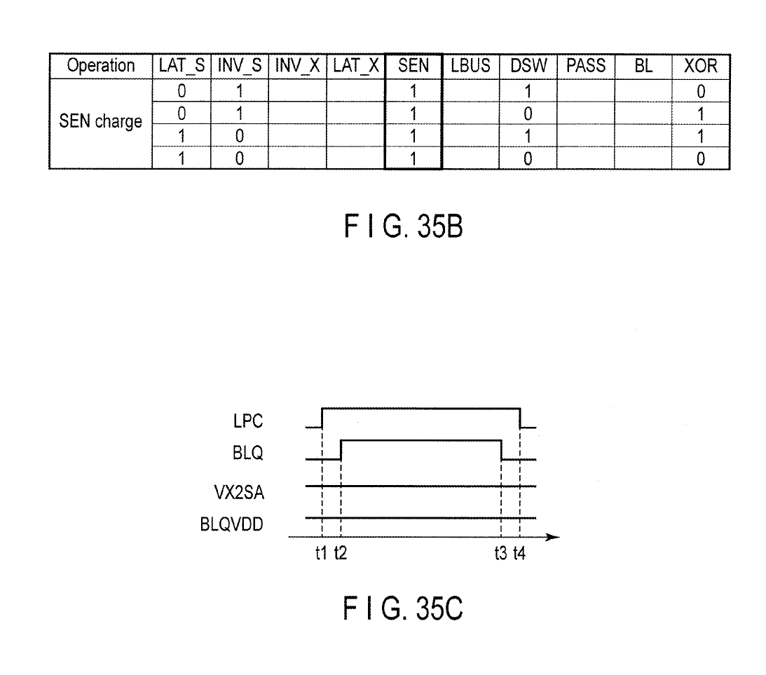

As shown in FIG. 35, the sense amplifier 12 according to the sixth embodiment further includes an AND circuit 70. The AND circuit 70 AND computes DDC [3:0], that is, a 4-bit address signal, and DDCR [15:0], that is, a 16-bit address signal, and supplies results of operation to a MOS transistor 55.

Here, DDC [3:0] and DDCR [15:0] are addresses changing in correspondence with SEED, and if the signal DSW is “H”, and the result of operation buy the AND circuit 70 is “H” in the corresponding sense unit SU12-1, SEN is set to the ground potential via a node N2 and a MOS transistor 27.

In other words, this case becomes equivalent to the transfer of “0” as the SEED value to SEN. The MOS transistor in this case is assumed to be an on state.

### 2. <XOR Operation (First Case)>

### 2.1 <SEN Charge: H2SEN15-1>

First of all, SEN is charged as shown in FIGS. 35A to 35C. Since the operation is mentioned above, a description thereof will be omitted.

The SEED values supplied to DSW exist in correspondence with the number of cases, and are “1”, “0”, “1” and “0” from the above.

### 2.2 <SEED=> SEN Transfer>

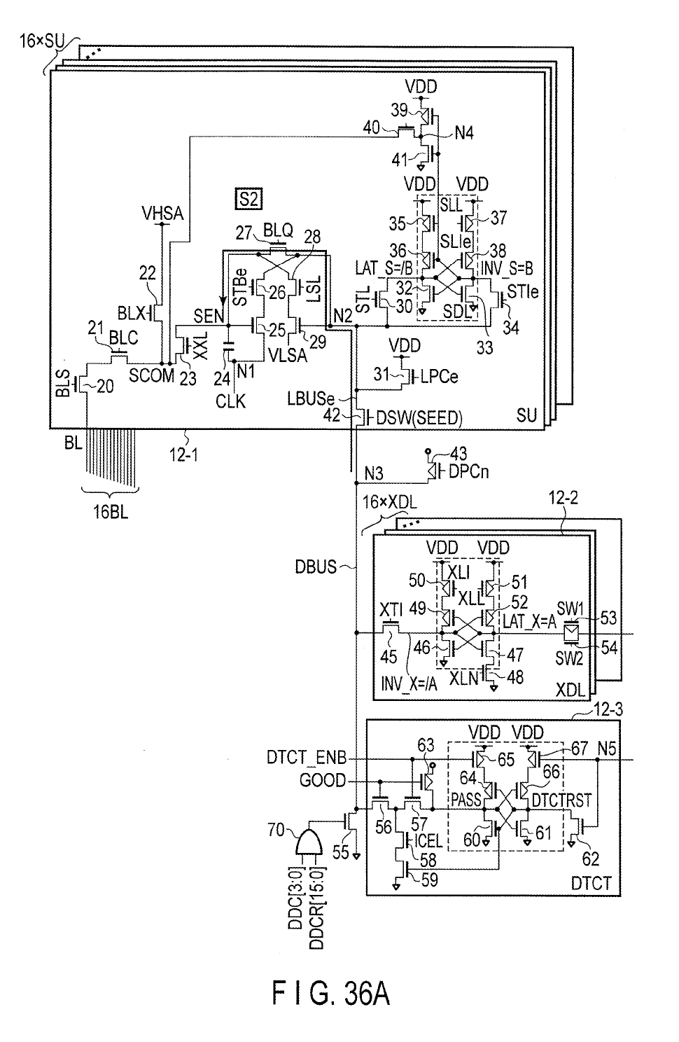

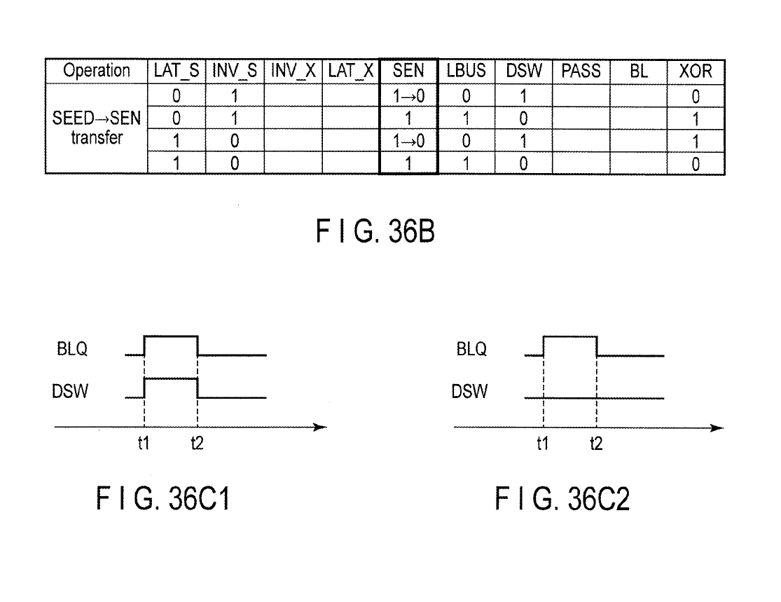

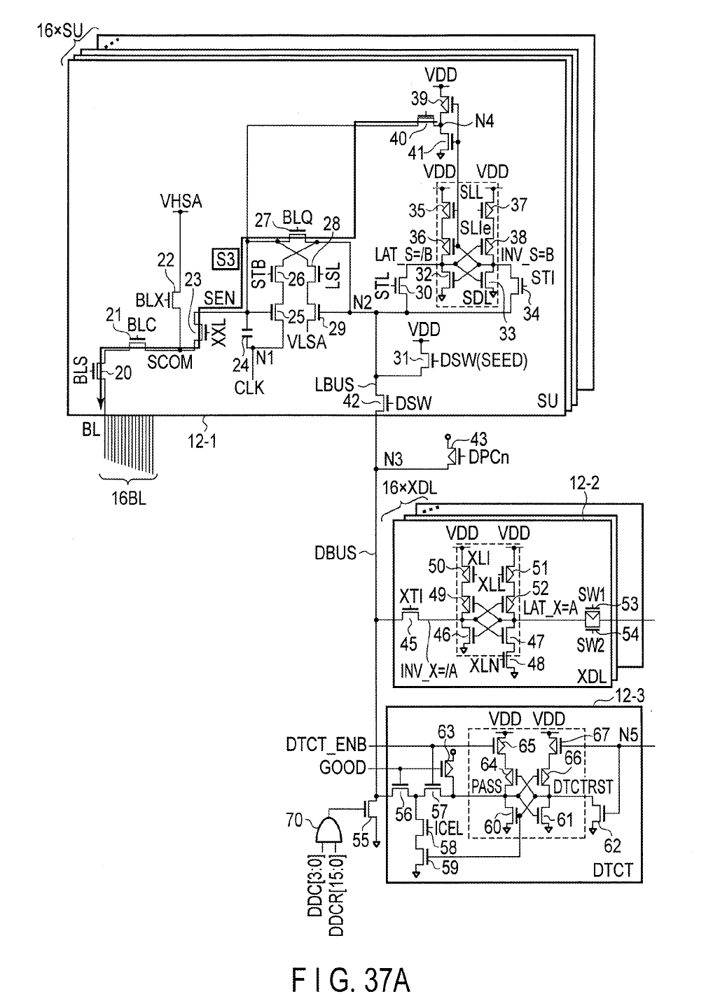

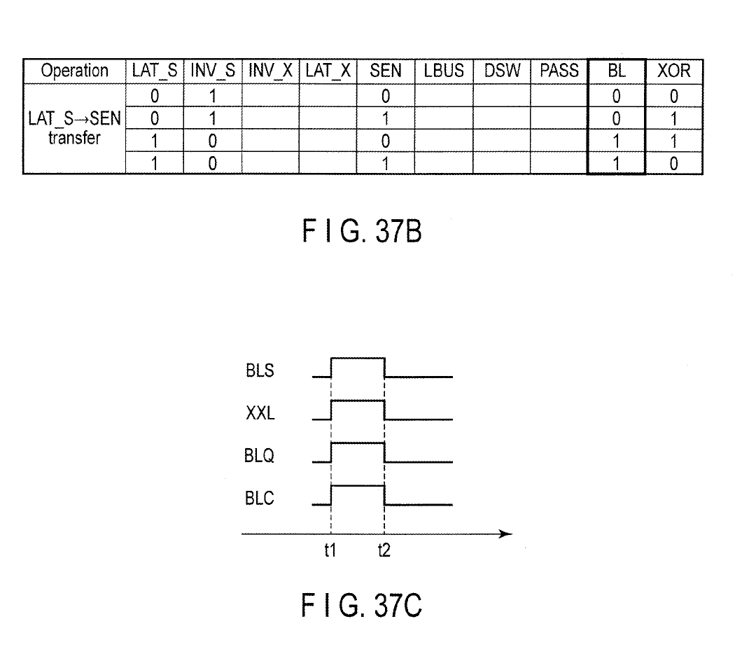

Next, the SEED value is transferred to SEN according to the method mentioned above in FIG. 36A.

In other words, the signal BLQ is set to the “H” level as shown in FIG. 36C, and the SEED value is transferred to SEN. As mentioned above, if the signal DSW is “H” according to the SEED value, and the result of operation of the AND circuit is “H”, SEN is set to the ground potential. In other words, “0” is transferred as the SEED value to SEN.

On the contrary, if the signal DSW is the “L” level according to the SEED value, and the result of operation of the AND circuit 70 is “L”, SEN is maintained at “1”. In other words, “1” is assumed to be transferred as the SEED value.

### 2.3 <SDL=> BL Transfer>

Next, the SDL data is transferred to the bit line BL as shown in FIGS. 36A to 36C. Since the operation is mentioned above, a description thereof will be omitted.

### 2.4 <SEN=> SDL (AND Operation of /LAT_X and /LAT_S): SEN2SL15-3>

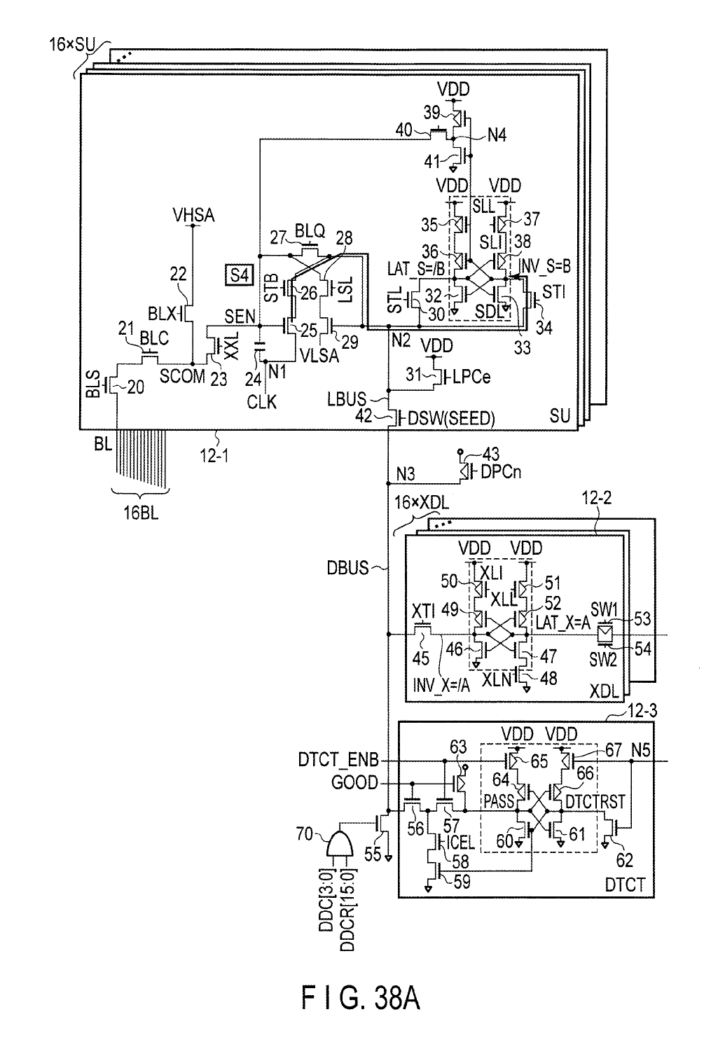

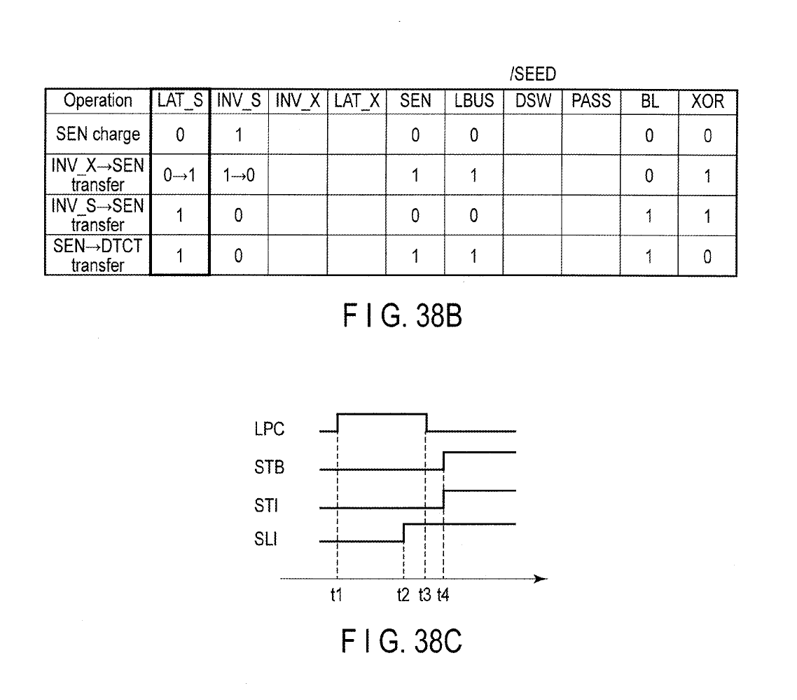

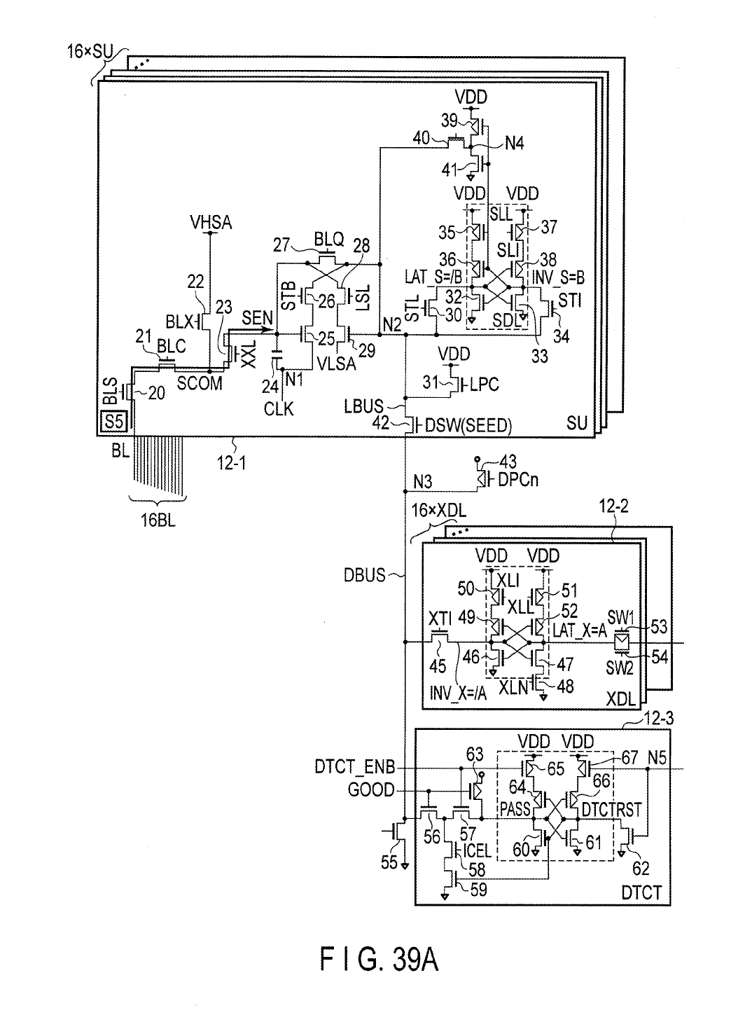

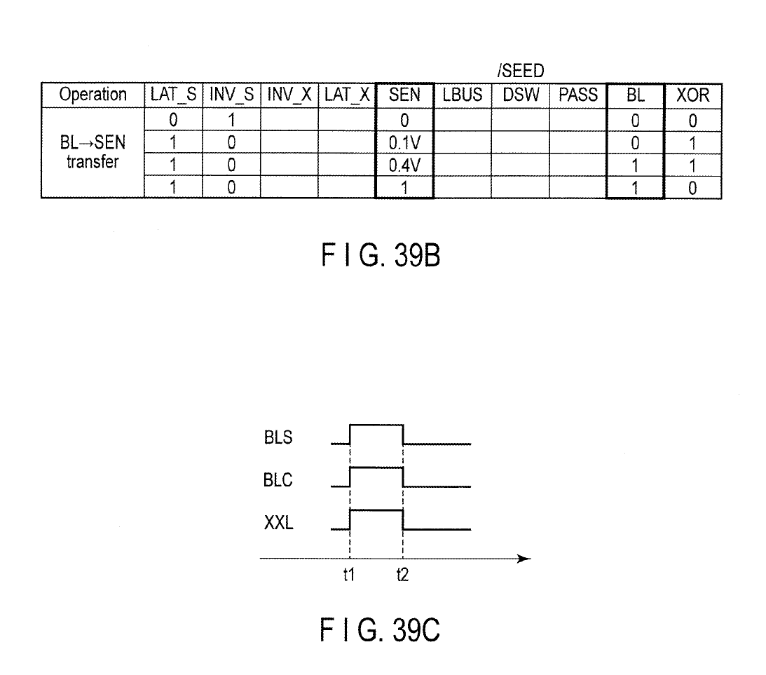

Next, the value of SEN is transferred to SDL as shown in FIGS. 38A to 380. Since the operation is mentioned above, a description thereof will be omitted.

### 2.5 <BL=> SEN (Sense Operation) (AND Operation of LAT_X and LAT_S): DTCTB2SEN15-7>

Next, the sense operation is executed. Since the operation is mentioned above, a description thereof will be omitted.

### 2.6 <SEN=> SDL (AND Operation of Inverted Data in 2.4 and Inverted Data in 2.5): SEN2SB15-15>

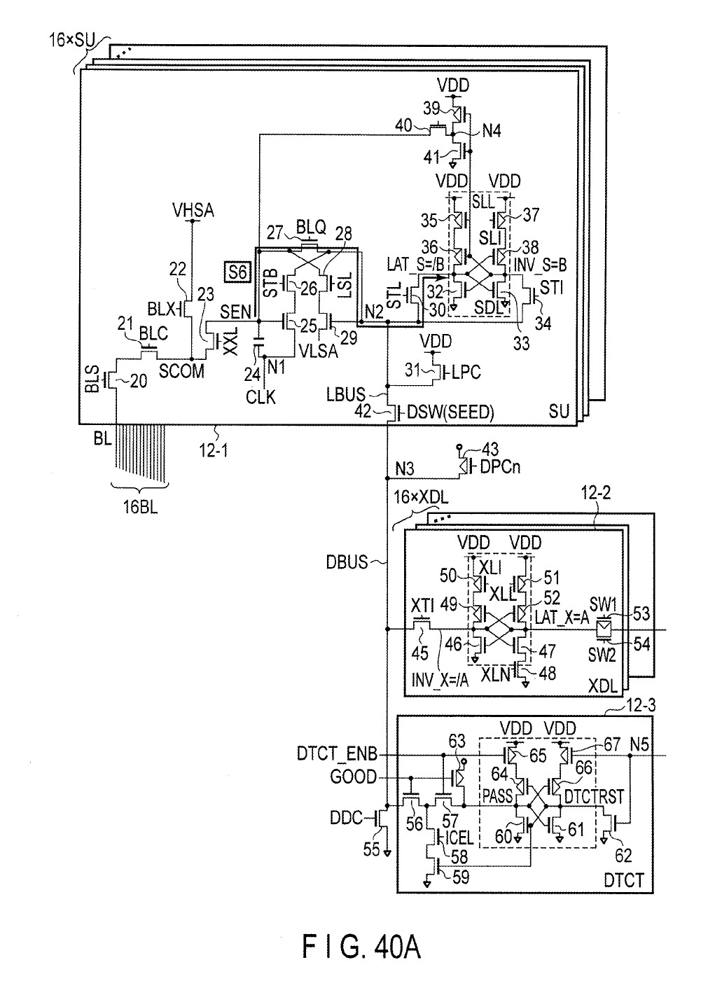

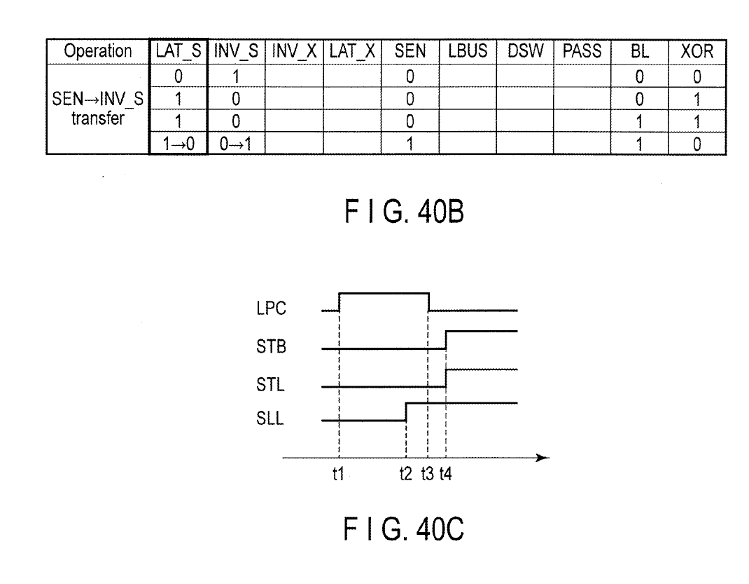

Finally, the value of SEN is transferred to SDL as shown in FIGS. 40A to 40C.

### 3. <XOR Operation (Second Case)>

The XOR operation (second case) described next is a case that one end of the current path of the MOS transistor 40 is connected to LBUS.

In this case, each of the steps according to the above (first case) is computed in the order of (1) 2.3=> (2) 2.1=> (3) 2.2. This is because the value of the node SEN reserved just before breaks in the operation for transferring the SDL data to the bit line BL. Since the operations after (3) are the same as the operations of the above (first case), a description thereof will be omitted.

In this structure, since the SEED value is able to not be entirely loaded, it is necessary to load the SEED value in each of the even and odd sense units 12-1.

### <Effect According to the Present Embodiment>

In the semiconductor memory storage apparatus according to the present embodiment, the time for decoding the randomized data may be shortened.

In other words, as mentioned above, in the semiconductor memory storage apparatus according to the present embodiment, the SEED value is used for the voltage level of the signal DSW in place of the storage of the SEED value in the latch unit 12-2, at a time of decoding the randomized data.

Accordingly, in the case that the SEED data is stored in the latch unit 12-2 and the XOR operation is carried out, the SEED data for the XOR operation has been taken in the latch unit 12-2 after waiting for the discharge of the data to be next transferred to the external device (the read data which is in advance read out of the memory cell array 10).

In this case, since time for waiting for the discharge of the previous read data stored in the latch unit 12-2 is generated even if the data reading time from the memory cell array 10 is fast, a loss is generated in the read time as a whole.

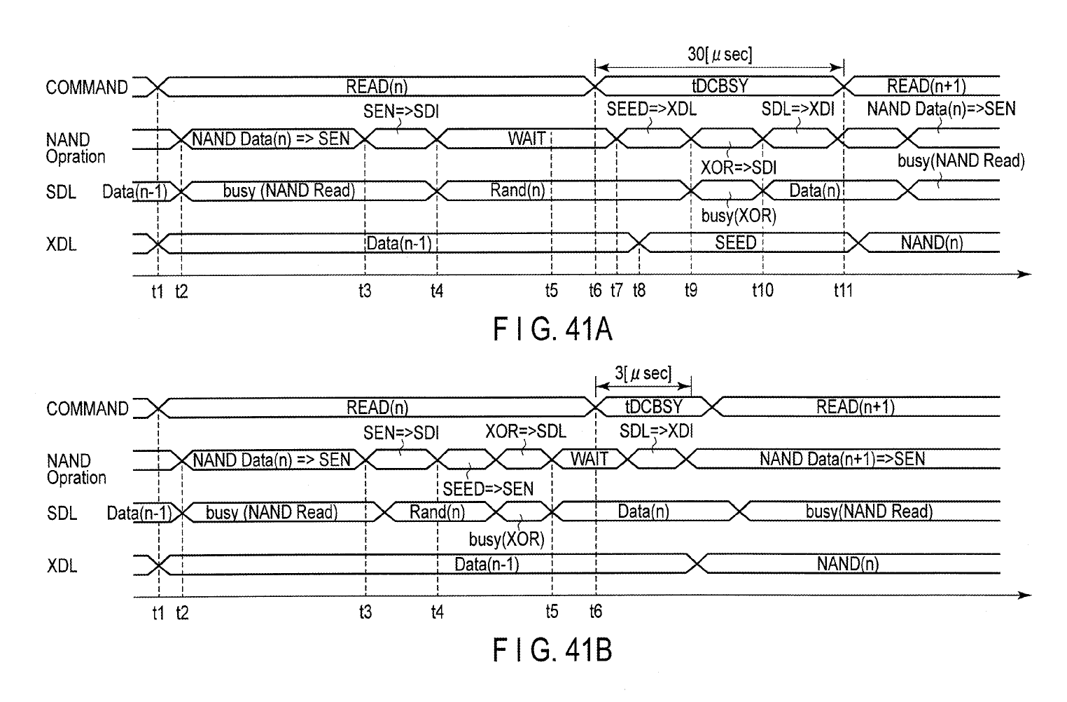

A description will be given of the appearance by comparing a comparative example with the semiconductor memory device according to the present embodiment, with reference to FIGS. 41A and 41B.

FIGS. 41A and 41B are time charts showing the appearance that the data read out of the memory cell array is stored in the latch unit 12-2 in correspondence to the command issued by the sequencer 15, and the appearance that the read data is XOR computed.

FIG. 41A is the time chart (comparative example) in the case that the latch unit 12-2 is used for the XOR operation, and FIG. 41B is the time chart (present embodiment) in the case that the latch unit 12-2 is not used for the XOR operation.

Vertical axes of the time charts employ the command issued by the sequencer 15, all the operations of the memory cell array 10 and the sense amplifier 12, SDL, and the latch unit 12-2 (XDL in the drawing) in this order from the above, and a horizontal axis employs time t.

As shown in FIGS. 41A and 41B, when the sequencer 15 issues READ (n) command at time t1, the read data from the memory cell array 10 is detected by SEN at time t2.

Next, the read data is transferred to the SDL from SEN at time t3. The operations above (until t4) are the same in both FIGS. 41A and 41B.

However, as shown in FIG. 41A, the sense unit SU12-1 comes to a “WAIT” state at time t4 to time t6.

This is because the data which is stored in the latch unit 12-2 and is read in advance is discharged to the external device during period between time t1 and time t8.

Accordingly, in the comparative example shown in FIG. 41A, the XOR operation is carried out after time t8. In other words, according to the tDCBSY1 command issued by the sequencer 15b at time t6, the SEED data is stored in the latch unit 12-2 (time t8, FIG. 41A), results of the XOR operation are thereafter stored in SDL at time t9 (read data has been decoded at this time point), and the read data is next output from the latch unit 12-2 via the latch unit 12-2 from SDL in correspondence to the command at time t10 (described as time t11 and NAND(n) in FIG. 41A).

In the comparative example, it takes about 30 μsec from time t6 at which tDCBSY1 command is issued, to time t11 at which the decoded data is discharged to the external device via the latch unit 12-2.

Conversely, in the semiconductor memory device according to the present embodiment, the XOR operation is executed by SEN and SDL at times t4 to t5 while discharging the read data stored in XOR (time t1 to time t9, Data (n−1) in FIG. 41B) as shown in FIG. 41B.

In other words, the XOR operation is executed behind while discharging the data which has been stored in the latch unit 12-2 and has been read in advance to the external device.

Accordingly, the time may be shortened and the high-speed processing may be realized as a whole for the reading operation. Therefore, as shown in FIG. 41, since the XOR operation is finished after time t5, it takes only 3μ for the period of tDCBSY1 (time t6 to time t9) to command the discharge to the external device via the detector 12-3.

Further, in the structure according to the XOR operation (first case), the operation in the item 2.3 does not pass through the node SEN. In other words, the SEED value may be set simultaneously (entirely) in the even and odd sense units 12-1. Accordingly, the time for the XOR operation may be shortened. It takes a long time to carry out the operation for transferring the SEED value to the node SEN.

As mentioned above, in the semiconductor memory device according to the present embodiment, the time for decoding the data at a time of the reading operation may be shortened, and the reading operation may be speeded up.

Each embodiment is applicable to a three dimensional multilayered NAND flash memory. Furthermore, a structure of the memory cell array is not limited as above description.

A memory cell array formation may be disclosed in U.S. patent application Ser. No. 12/532,030 filed on Mar. 23, 2009. U.S. patent application Ser. No. 12/532,030, the entire contents of which are incorporated by reference herein.

Furthermore A memory cell array formation may be disclosed in U.S. patent application Ser. No. 12/679,991 filed on Mar. 25, 2010. U.S. patent application Ser. No. 12/679,991, the entire contents of which are incorporated by reference herein.

Furthermore A memory cell array formation may be disclosed in U.S. patent application Ser. No. 12/406,524 filed on Mar. 18, 2009. U.S. patent application Ser. No. 12/406,524, the entire contents of which are incorporated by reference herein.

Furthermore A memory cell array formation may be disclosed in U.S. patent application Ser. No. 12/407,403 filed on Mar. 19, 2009. U.S. patent application Ser. No. 12/407,403, the entire contents of which are incorporated by reference herein.

Semiconductor memory storage (sequencer 15) operates the XOR operation, while Semiconductor memory storage (sequencer 15) outputs “H”-level busy signal to external (host or NAND controller).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory storage apparatus comprising:
a memory cell array including a memory cell;
a sense amplifier configured to include a first latch and a second latch, the first latch and the second latch being capable of storing a data read out from the memory cell; and
a controller configured to perform a first operation, a second operation, and a third operation, the controller performing the first operation and the second operation by using the data read out from the memory cell and data supplied from outside, the controller outputting a first result in the first operation, the controller outputting a second result in the second operation, thereafter performing a third operation based on a first result and a second result,
wherein in the first operation, the controller transfers an inverted data in the first latch to the first node and transfers the data in the second latch,
in the second operation, the controller transfers the data in the first latch to the first node and transfers an inverted data in the second latch.

2. The apparatus of claim 1, wherein the sense amplifier includes n number of sense units, and
the controller sequentially performs the third operation to the sense units.

3. The apparatus of claim 2, wherein the memory cell array has a first area including system information,
the data read from the memory cell array includes a first data and an expected value, the first data being input to and output from the outside via the sense amplifier, and the expected value being a value stored in the first area and read out from the memory cell, and
the first operation and the second operation by the sense amplifier uses the first data and the expected value.

4. The apparatus of claim 3, further comprising:
an ECC controller configured to make the second latch store the second data if any erroneous read exists in the data by determining whether or not the data is erroneously read at the reading time,
wherein the controller performs the third operation by the data stored in the first latch and the second data.

5. The apparatus of claim 1, wherein the detector may transfer the result obtained by the third operation to the first latch.

6. The apparatus of claim 2, wherein the detector may transfer the result obtained by the third operation to the first latch.

7. The apparatus of claim 2, wherein
The sense units include a first sense unit and a second sense unit adjacent to the first sense unit,
the first sense unit and the second sense unit each includes a first MOS transistor, the first MOS transistor transferring the data output to and input from the outside,
the first node of the first sense unit electrically connects to the first latch through the first MOS transistor.

8. The apparatus of claim 7, wherein
the controller turns on the first MOS transistor and transfers the data held by the first latch to the first node in the second sense unit, while the controller outputs H-level busy signal to the outside.

9. An operation method of a semiconductor memory storage apparatus including a memory cell array comprising:
reading data from a memory cell in the memory cell array, and storing the data in a first latch;
storing an expected value to the second latch, the expected value being stored a first area in the memory array and being a value expected to be read from the memory cell;
transferring first data obtained by inverting the expected value to a detector via a first node, thereafter transferring second data obtained by inverting the data to the detector via the second node, and setting a value of the detector to third data;
transferring a value corresponded to the third data to a third latch via the first node; and
setting a value of the detector to fourth data, thereafter transferring the expected value to detector via the first node, by transferring the expected value to the first node and transferring a value corresponding to a potential level of the first node to the detector.

10. The method of claim 9, wherein,
the detector, the first latch and the second latch are included in respective sense amplifiers which read the data from the memory cell, and
transfer to the third latch from the first latch and the second latch is sequentially performed to each of the sense amplifiers.

11. The method of claim 9, further comprising:
determining whether or not the data is erroneously read at the reading time, and storing fifth data in the second latch if any erroneous read exists in the data,
wherein a correction process is performed by the data which is stored in the first latch, and the fifth data.

12. The method of claim 10, further comprising:
determining whether or not the data is erroneously read at the reading time, and storing fifth data in the second latch if any erroneous read exists in the data,
wherein a correction process is performed by the data which is stored in the first latch, and the fifth data.

13. An operation method of semiconductor memory storage apparatus including a memory cell array comprising:
reading data from a memory cell in a memory cell array, and storing the read data in a first latch via a first node;
transferring an expected value being expected to be read from the memory cell, to the first node from a second latch in which the expected value is stored;
evacuating the read data stored in the first latch to an evacuation circuit;
performing a first operation by transferring the expected value stored in the first node to the first latch; and
performing a second operation by transferring the read data evacuated to the evacuation circuit to the first node holding the expected value.

14. The method of claim 13, wherein
to evacuate the read data stored in the first latch to the evacuation circuit is,
each of a first MOS transistor and a second MOS transistor which capable of connecting the first latch and the evacuation circuit is turned on, the first MOS transistor inputs and outputs the read data to and from the first latch, and the second MOS transistor is connected in series to the first MOS transistor.

15. The method of claim 14, wherein
to transfer of the expected value stored in the first node to the first latch is,
each of a third MOS transistor and the first MOS transistor which capable of connecting the first node and the first latch is turned on, and the third MOS transistor outputs inverted data of the first node to the first latch.

16. The method of claim 15, wherein
an execution of the second operation turns on a fourth MOS transistor which inputs and outputs the read data to and from the evacuation circuit, the second MOS transistor and a fifth MOS transistor which is connected at one end to the first node and may be grounded at the other end, the fourth MOS transistor, the second MOS transistor and the fifth MOS transistor being capable of connecting the evacuation circuit and the first node.

17. The method of claim 16, wherein
the third operation operates inverted data of the first result, and inverted data of the second result.

18. The method of claim 17, wherein
the third operation turns on a sixth MOS transistor which transfers the first result stored in the first node to the first latch, and a seventh MOS transistor which is connected in series to the sixth MOS transistor and inputs and outputs the inverted data to and from the first latch.

19. The method of claim 13, wherein
a plurality of sense amplifiers sensing the held data read out of the memory cell are arranged,
the first node and the first latch are provided in each of the sense amplifiers, and
the first evacuation circuit is the first node in the adjacent sense amplifier.

20. The method of claim 13, wherein
the first evacuation circuit is a bit line which may be electrically connected to the first node.
